(19) United States
(12) Patent Application Publication
(10) Pub. No.: US 2016/0155575 A1
(43) Pub. Date: Jun. 2, 2016

(54) METHINE DYES WITH LARGE ORGANIC COUNTER ANION FOR DYE SENSITIZED SOLAR CELLS

(71) Applicant: BASF SE, Ludwigshafen (DE)

(72) Inventors: Hitoshi YAMATO, Takarazuka-shi (JP); Shinji NAKAMICHI, Osaka-shi (JP); Ryuichi TAKAHASHI, Kobe-shi (JP); Hiroshi YAMAMOTO, Takarazuka (JP); Robert SEND, Karlsruhe (DE); Henrike WONNEBERGER, Mannheim (DE); Ingmar BRUDER, Neuleiningen (DE); Vytautas GETAUTIS, Kaunas (LT); Rakstys KASPARAS, Vilnius (LT); Tadas MALINAUSKAS, Kaunas (LT)

(73) Assignee: BASF SE, Ludwigshafen (DE)

(21) Appl. No.: 14/907,100

(22) PCT Filed: Jul. 22, 2004
(86) PCT No.: PCT/IB2014/063298

§ 371 Date: Jan. 22, 2016

(30) Foreign Application Priority Data
Jul. 25, 2013 (EP) 13178009.0

(51) Int. Cl. H01G 9/20; C09B 23/16; C09B 29/00; H01L 51/00

(52) U.S. Cl. CPC H01G 9/2059; H01G 9/2027; H01L 51/0072; H01L 51/0067; H01L 51/0054; H01L 51/0068; H01L 51/0086; H01L 51/0061; H01L 51/0058; H01L 51/0071; C09B 23/164; C09B 29/00; H01L 51/0069

(57) ABSTRACT

The present invention relates to an electrode layer comprising a porous film made of oxide semiconductor fine particles sensitized with a methine dye having a counter anion capable of absorbing electromagnetic radiation having a wavelength in the range of from 400 nm to 1000 nm. Moreover the present invention relates to a photoelectric conversion device comprising said electrode layer, a dye sensitized solar cell comprising said photoelectric conversion device, an organic electronic device comprising said photoelectric conversion device and to novel methine dyes having a counter anion capable of absorbing electromagnetic radiation having a wavelength in the range of from 400 nm to 1000 nm.

The present invention relates to an electrode layer comprising a porous film made of oxide semiconductor fine particles sensitized with a methine dye having a counter anion capable of absorbing electromagnetic radiation having a wavelength in the range of from 400 nm to 1000 nm. Moreover the present invention relates to a photoelectric conversion device comprising said electrode layer, a dye sensitized solar cell comprising said photoelectric conversion device, an organic electronic device comprising said photoelectric conversion device and to novel methine dyes having a counter anion capable of absorbing electromagnetic radiation having a wavelength in the range of from 400 nm to 1000 nm.

Dye-sensitized photoelectric conversion elements (dye sensitized solar cells, DSC) have attracted much attention in recent years. They have several advantages compared to silicon-based solar cells such as lower production and material costs because an inexpensive metal oxide semiconductor such as titanium dioxide can be used therefore without purification to a high purity. Other advantages include their flexibility, transparency and light weight. The overall performance of a photoelectric conversion device is characterized by several parameters such as the open circuit voltage (V_{oc}), the short circuit current (I_{sc}), the fill factor (FF) and the energy conversion efficiency η (“eta”) resulting therefrom. Thus, one approach to improve the energy conversion efficiency is to enhance the open circuit voltage and/or the short circuit current of the photoelectric conversion device by optimizing the dye used in the DSC.

The dyes have to meet several requirements among these are the stability, production costs and absorption properties, for example, the dye should absorb incident light of a broad wavelength range with a high absorption coefficient. Promising organic dyes used as sensitizers in DSCs are donor-π (“pi”)-acceptor systems, composed of donor, π (“pi”)-conjugated spacer, and acceptor/anchoring groups. However, the performance of these dyes is not always satisfactory.

CN 1534021 discloses photoelectric conversion devices comprising some methine dyes.

WO 2011/026797 and WO 2011/120908 relate to dye sensitised solar cells (DSC) wherein the dye is a methine dye with a pyridinium acceptor group.

WO 2009/109499 relates to a photoelectric conversion element where the dye is a methine dye with a pyridinium, quinolium or isoquinolinium acceptor group, the spacer connecting the donor and the acceptor group being an ethylene group carrying an electron withdrawing group.

JP 2006-294360 relates to a photoelectric conversion element where the dye is a methine dye of the formula (1)

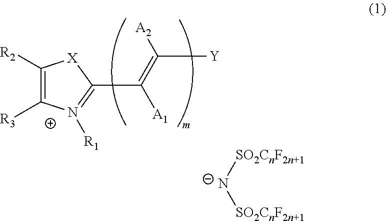

where m and n represent integers, R₁ represents an aromatic residual group, aliphatic hydrocarbon residual group or acyl group, R₂, R₃, A₁ and A₂ represent an aromatic residual group, aliphatic hydrocarbon residual group, hydroxyl group, phosphoric acid group, cyano group, hydrogen atom, halogen atom, nitro group, carboxyl group, carbamoyl group, alkoxycarbonyl group, arylcarbonyl group, or acyl group. R₂ and R₃ may be joined together to form a ring. X represents O, S, Se, CH₂, N—R₄, CR₅R₆ or —CR₇═CR₈—, R₄ represents an aromatic residual group, aliphatic hydrocarbon residual group or acyl group, R₅, R₆, R₇ and R₈ represent an aromatic residual group, aliphatic hydrocarbon residual group, hydroxyl group or the like, and Y represents an aromatic residual group or an organometallic complex residual group.

EP 1 990 373 relates to a photoelectric conversion device comprising a methine dye, in which a quinolinium acceptor group can be bonded to an ethylene group and the donor group is a di(optionally substituted fluorenyl)aminophenyl. The anionic counterion is i.a. bistrifluoromethylsulfonimide, C(SO₂CF₃)₃⁻, SbF₆⁻, BF₄⁻ or PF₆⁻.

There is still an ongoing need to further improve the performance of dye-sensitized photoelectric conversion devices, in particular their energy conversion efficiency η (“eta”).

It is therefore an object of the present invention to provide an electrode layer sensitized with a dye, a photoelectric conversion device having an enhanced energy conversion efficiency η (“eta”), a solar cell and an organic electronic device, in particular an organic light-emitting diode (OLED) or an organic field-effect transistor (OFET), comprising the device and new dyes.

Surprisingly, methine dyes having a counter anion capable of absorbing electromagnetic radiation having a wavelength in the range of from 400 nm to 1000 nm are particularly advantageous. They have excellent overall properties; in particular they have a particularly good dye absorption property on the electrode, giving high long-term DSC stability, high long-term performance and high energy conversion efficiency.

Therefore, in a first aspect, the present invention relates to an electrode layer comprising a porous film made of oxide semiconductor fine particles sensitized with a dye of formula (I),

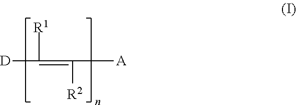

where
n is 1, 2, 3, 4, 5 or 6;
R¹ and R² are independently of each other selected from hydrogen, unsubstituted C₁-C₂₀-alkyl wherein alkyl is uninterrupted or interrupted by O, S, CO, NR¹⁴ or combinations thereof, substituted C₁-C₂₀-alkyl wherein alkyl is uninterrupted or interrupted by O, S, CO, NR¹⁴ or combinations thereof, unsubstituted C₁-C₂₀-cycloalkyl wherein alkyl is uninterrupted or interrupted by O, S, CO, NR¹⁴ or combinations thereof, substituted C₁-C₂₀-cycloalkyl wherein alkyl is uninterrupted or interrupted by O, S, CO, NR¹⁴ or combinations thereof, unsubstituted C₆-C₂₀-aryl, substituted C₆-C₂₀-aryl, unsubstituted C₆-C₂₀-heteroaryl, substituted C₆-C₂₀-heteroaryl; or
R¹ can additionally be a residue of formula D;
each D is independently selected from a residue of formulae D.1 and D.2

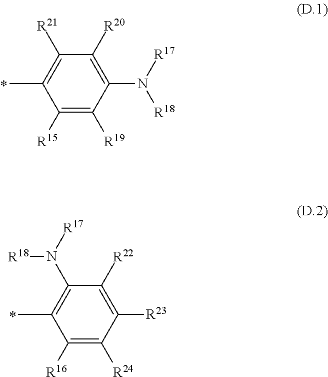

where
* [symbol] denotes the bond to the remaining compound of formula (I);
R¹⁷ and R¹⁸ are independently of each other selected from unsubstituted or substituted
C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof, where R¹⁴ is hydrogen, C₁-C₂₀-alkyl or C₆-C₁₀-aryl;
or
R¹⁷ and R¹⁸ form together with the nitrogen atom to which they are attached an unsubstituted or substituted 5-, 6- or 7-membered ring;
or
R¹⁷ and R²⁰ form together with the nitrogen atom to which R¹⁷ is attached and the carbon atoms of the benzene ring to which R²⁰ and N—R¹⁷ are attached an unsubstituted or substituted 5-, 6- or 7-membered ring;
or
R¹⁷ and R²² form together with the nitrogen atom to which R¹⁷ is attached and the carbon atoms of the benzene ring to which R²² and N—R¹⁷ are attached an unsubstituted or substituted 5-, 6- or 7-membered ring;
and/or
R¹⁸ and R¹⁹ form with the nitrogen atom to which R¹⁸ is attached and the carbon atoms of the benzene ring to which R¹⁹ and N—R¹⁸ are attached an unsubstituted or substituted 5-, 6- or 7-membered ring;
R¹⁵, R¹⁶, R¹⁹, R²⁰, R²¹, R²², R²³ and a R²⁴ are independently of each other selected from the group consisting of hydrogen, NR²⁵R²⁶, OR²⁵, SR²⁵, NR²⁵—NR²⁶R²⁷, NR²⁵—OR²⁶, O—CO—R²⁵, O—CO—OR²⁵, O—CO—NR²⁵R²⁶, NR²⁵—CO—R²⁶, NR²⁵—CO—OR²⁶, NR²⁵—CO—NR²⁶R²⁷, CO—R²⁵, CO—OR²⁵, CO—NR²⁵R²⁶, S—CO—R²⁵, CO—SR²⁵, CO—NR²⁵—NR²⁶R²⁷, CO—NR²⁵—OR²⁶, CO—O—CO—R²⁵, CO—O—CO—OR²⁵, CO—O—CO—NR²⁵R²⁶, CO—NR²⁵—CO—R²⁶, CO—NR²⁵—CO—OR²⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R²⁵, R²⁶ and R²⁷ are independently of each other selected from hydrogen, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
A is a residue of formulae A.1, A.2, A.3, A.4, A.5, A.6 and A.7

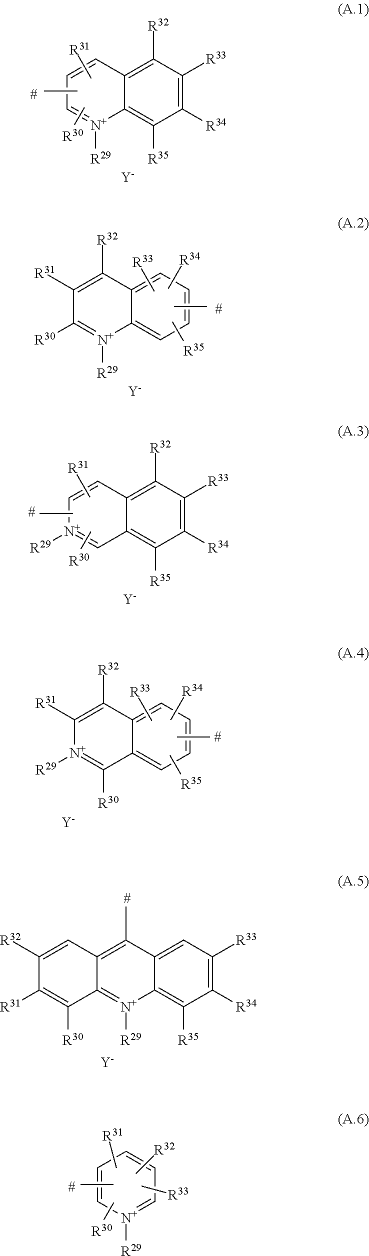

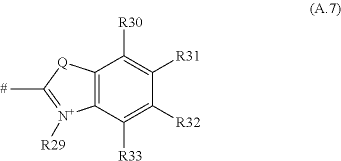

where
# [symbol] denotes the bond to the remaining compound of formula I
R²⁹ is a residue G, hydrogen, halogen, OR³⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R³⁰, R³¹, R³² and R³³ are independently of each other selected from a residue G, hydrogen, halogen, OR³⁶, NO₂, CN, COR′, COOR′, SO₂R′ and SO₃R′, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R′ is independently selected from the group consisting of unsubstituted aryl, substituted aryl, unsubstituted alkyl having 1 to 10 carbon atoms, substituted alkyl having 1 to 10 carbon atoms including substituents, unsubstituted cycloalkyl having 5 to 7 carbon atoms, and substituted cycloalkyl having 5 to 10 carbon atoms including substituents, wherein in said alkyl or cycloalkyl groups one oxygen atom or two nonadjacent oxygen atoms may be inserted between respective C atoms;
wherein optionally in (A.7) R³⁰ and R³¹ together with the carbon atoms to which they are attached or R³² and R³³ together with the carbon atoms to which they are attached form an unsubstituted or substituted 5-, 6- or 7-membered ring;
with the proviso that at least one of the residues R²⁹, R³⁰, R³¹, R³², R³³, R³⁴ and R³⁵ is a residue G,
where
R³⁶ is unsubstituted or substituted C₁-C₂₀-alkyl, unsubstituted or substituted C₆-C₂₀-aryl, unsubstituted or substituted heteroaryl, wherein alkyl is uninterrupted or interrupted by O, S, CO, NR¹⁴ or combinations thereof;
Q is —S—, —C(R³⁴)(R³⁵)—, —O—;
R³⁴ and R³⁵ are independently of each other selected from a residue G, hydrogen, halogen, OR³⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
G is selected from —R²⁸—COOH, —R²⁸—COO⁻Z⁺, —R²⁸—CO(C═O)OH, —R²⁸—CO(C═O)O⁻Z⁺, —R²⁸—S(═O)₂OH, —R²⁸—S(═O)₂O⁻Z⁺, —R²—O—S(═O)₂OH, —R²⁸—O—S(═O)₂O⁻Z⁺, —R²⁸—P(═O)(OH)₂, —R²⁸—P(═O)(O⁻Z⁺)₂, —R²⁸—P(═O)(OH)(O⁻Z⁺), —R²⁸—O—P(═O)(OH)₂, —R²⁸—O—P(═O)(O⁻Z⁺)₂, —R²⁸—O—P(═O)(OH)(O⁻Z⁺), —R²⁸—CO—NH—OH, —R²⁸—S(═O)₂NH—OH, —R²⁸—NR¹⁴—S(═O)₂OH and —R²⁸—NR¹⁴—S(═O)₂O⁻Z⁺;
where
R²⁸ is a direct bond, C₁-C₂₀-alkylene, C₂-C₄-alkenylene or C₆-C₁₀-arylene;
Z⁺ is an organic or inorganic cation equivalent; and
Y⁻ is an anion capable of absorbing electromagnetic radiation having a wavelength in the range of from 400 nm to 1000 nm.

Absorption of the anion Y⁻ may be determined by means of a solution spectrum of the respective compound of formula (I) as described in detail in the experimental section. The obtained spectra must be normalized to the peak of the cation to clarify the contribution of anion Y⁻. Preferably, the anion Y⁻ has its maximum light absorption λₘₐₓ (“lambda max”) in the wavelength region of from 400 nm to 1000 nm.

The invention moreover relates to a photoelectric conversion device comprising the electrode layer as defined above.

A further aspect of the present invention is the methine dye of the formula (I).

The invention also relates to the use of compounds of formula (I) in a photoelectric conversion device. Likewise, the invention also relates to a method of using compounds of formula (I) in a photoelectric conversion device.

The electrode layer and the devices of the present invention are associated with several advantages. For instance, the methine dyes having an anion capable of absorbing electromagnetic radiation having a wavelength in the range of from 400 nm to 1000 nm allow for high V_{OC}, J_{SC} and high FF that feature excellent energy conversion efficiencies η (“eta”) and are highly suitable for being used in solar cells.

The photo-electric power conversion efficiency η (“eta”) of the photoelectric conversion device according to the present invention, the respective current/voltage characteristic such as short-circuit current density J_{sc}, open-circuit voltage V_{oc} and fill factor FF may be determined with a Source Meter Model 2400 (Keithley Instruments Inc.) under the illumination of an artificial sunlight (AM 1.5, 100 mW/cm² intensity) generated by a solar simulator (Peccell Technologies, Inc) as described in detail in the experimental section.

When according to the present invention a denotation (e.g. D or G) occurs more than once (e.g. twice) in a compound, this denotation may be different groups or the same group unless otherwise stated.

The term “halogen” designates in each case, fluorine, bromine, chlorine or iodine, specifically fluorine.

The prefix Cₙ-Cₘ- indicates the respective number of carbons in the hydrocarbon unit.

In the context of the present invention, the term “alkyl” comprises straight-chain or branched alkyl groups having usually 1 to 20 carbon atoms. Examples of alkyl groups are especially methyl, ethyl, n-propyl, isopropyl, n-butyl, isobutyl, sec-butyl, tert-butyl, n-pentyl, neo-pentyl, n-hexyl, n-heptyl, n-octyl, n-nonyl, n-decyl, n-undecyl, n-dodecyl, n-tridecyl, n-tetradecyl, n-hexadecyl, n-octadecyl and n-eicosyl. The expression alkyl also comprises alkyl residues whose carbon chains may be interrupted by one or more, e.g. 1, 2, 3, 4, 5 or 6 groups which are selected from —O—, —S—, —NR¹⁴— and/or —C(═O)—, unless otherwise stated. R¹⁴ preferably is hydrogen or C₁-C₂₀-alkyl. It is to be understood that alkyl interrupted by —O—, —S—, —NR¹⁴— and/or —C(═O)— or combinations thereof comprises at least 2 carbon atoms.

Substituted alkyl groups may, depending on the length of the alkyl chain, have one or more (e.g. 1, 2, 3, 4, 5 or more than 5) identical or different substituents. Suitable substituents are e.g. C₄-C₂₀-cycloalkyl, C₅-C₂₀-cycloalkenyl, C₆-C₂₀-cycloalkynyl, heterocyclyl, halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and S(═O)₂O⁻Z⁺, where R²⁵, R²⁶, Z⁺ are as defined above.

The above remarks regarding alkyl also apply to the alkyl moiety in alkoxy.

The term “alkenyl” comprises straight-chain or branched hydrocarbon residues having two or more C atoms, e.g. 2 to 4, 2 to 6 or 2 to 12 or 2 to 20 carbon atoms and having at least one double bond, e.g. one or two, preferably having one double bond in any position. Examples are C₂-C₆-alkenyl such as ethenyl (vinyl), 1-propenyl, 2-propenyl, 1-methylethenyl, 1-butenyl, 2-butenyl, 3-butenyl, 1-methyl-1-propenyl, 2-methyl-1-propenyl, 1-methyl-2-propenyl, 2-methyl-2-propenyl, 1-pentenyl, 2-pentenyl, 3-pentenyl, 4-pentenyl, 1-methyl-1-butenyl, 2-methyl-1-butenyl, 3-methyl-1-butenyl, 1-methyl-2-butenyl, 2-methyl-2-butenyl, 3-methyl-2-butenyl, 1-methyl-3-butenyl, 2-methyl-3-butenyl, 3-methyl-3-butenyl, 1,1-dimethyl-2-propenyl, 1,2-dimethyl-1-propenyl, 1,2-dimethyl-2-propenyl, 1-ethyl-1-propenyl, 1-ethyl-2-propenyl, 1-hexenyl, 2-hexenyl, 3-hexenyl, 4-hexenyl, 5-hexenyl, 1-methyl-1-pentenyl, 2-methyl-1-pentenyl, 3-methyl-1-pentenyl, 4-methyl-1-pentenyl, 1-methyl-2-pentenyl, 2-methyl-2-pentenyl, 3-methyl-2-pentenyl, 4-methyl-2-pentenyl, 1-methyl-3-pentenyl, 2-methyl-3-pentenyl, 3-methyl-3-pentenyl, 4-methyl-3-pentenyl, 1-methyl-4-pentenyl, 2-methyl-4-pentenyl, 3-methyl-4-pentenyl, 4-methyl-4-pentenyl, 1,1-dimethyl-2-butenyl, 1,1-dimethyl-3-butenyl, 1,2-dimethyl-1-butenyl, 1,2-dimethyl-2-butenyl, 1,2-dimethyl-3-butenyl, 1,3-dimethyl-1-butenyl, 1,3-dimethyl-2-butenyl, 1,3-dimethyl-3-butenyl, 2,2-dimethyl-3-butenyl, 2,3-dimethyl-1-butenyl, 2,3-dimethyl-2-butenyl, 2,3-dimethyl-3-butenyl, 3,3-dimethyl-1-butenyl, 3,3-dimethyl-2-butenyl, 1-ethyl-1-butenyl, 1-ethyl-2-butenyl, 1-ethyl-3-butenyl, 2-ethyl-1-butenyl, 2-ethyl-2-butenyl, 2-ethyl-3-butenyl, 1,1,2-trimethyl-2-propenyl, 1-ethyl-1-methyl-2-propenyl, 1-ethyl-2-methyl-1-propenyl, 1-ethyl-2-methyl-2-propenyl. The expression alkenyl also comprises alkenyl residues whose carbon chains may be interrupted by one or more, e.g. 1, 2, 3, 4, 5 or 6 groups which are selected from —O—, —S—, —NR¹⁴— and/or —C(═O)—, unless otherwise stated. R¹⁴ preferably is hydrogen or C₁-C₂₀-alkyl. It is to be understood that alkenyl interrupted by —O—, —S—, —NR¹⁴— and/or —C(═O)— or combinations thereof comprises at least 3 carbon atoms. Substituted alkenyl groups may, depending on the length of the alkenyl chain, have one or more (e.g. 1, 2, 3, 4, 5 or more than 5) identical or different substituents. Suitable substituents are e.g. C₄-C₂₀-cycloalkyl, C₅-C₂₀-cycloalkenyl, C₆-C₂₀-cycloalkynyl, heterocyclyl, halogen, 5-R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and S(═O)₂O⁻Z⁺, where R²⁵, R²⁶, Z⁺ are as defined above.

The term “alkynyl” comprises straight-chain or branched hydrocarbon residues having two or more C atoms, e.g. 2 to 4, 2 to 6 or 2 to 12 or 2 to 20 carbon atoms and having at least one triple bond, e.g. one or two, preferably having one triple bond in any position, e.g. C₂-C₆-alkynyl such as ethynyl, 1-propynyl, 2-propynyl, 1-butynyl, 2-butynyl, 3-butynyl, 1-methyl-2-propynyl, 1-pentynyl, 2-pentynyl, 3-pentynyl, 4-pentynyl, 1-methyl-2-butynyl, 1-methyl-3-butynyl, 2-methyl-3-butynyl, 3-methyl-1-butynyl, 1,1-dimethyl-2-propynyl, 1-ethyl-2-propynyl, 1-hexynyl, 2-hexynyl, 3-hexynyl, 4-hexynyl, 5-hexynyl, 1-methyl-2-pentynyl, 1-methyl-3-pentynyl, 1-methyl-4-pentynyl, 2-methyl-3-pentynyl, 2-methyl-4-pentynyl, 3-methyl-1-pentynyl, 3-methyl-4-pentynyl, 4-methyl-1-pentynyl, 4-methyl-2-pentynyl, 1,1-dimethyl-2-butynyl, 1,1-dimethyl-3-butynyl, 1,2-dimethyl-3-butynyl, 2,2-dimethyl-3-butynyl, 3,3-dimethyl-1-butynyl, 1-ethyl-2-butynyl, 1-ethyl-3-butynyl, 2-ethyl-3-butynyl, 1-ethyl-1-methyl-2-propynyl. The expression alkynyl also comprises alkynyl residues whose carbon chains may be interrupted by one or more, e.g. 1, 2, 3, 4, 5 or 6 groups which are selected from —O—, —S—, —NR¹⁴— and/or —C(═O)—, unless otherwise stated. R¹⁴ preferably is hydrogen or C₁-C₂₀-alkyl. It is to be understood that alkynyl interrupted by —O—, —S—, —NR¹⁴— and/or —C(═O)— or combinations thereof comprises at least 3 carbon atoms. Substituted alkynyl groups may, depending on the length of the alkynyl chain, have one or more (e.g. 1, 2, 3, 4, 5 or more than 5) identical or different substituents. Suitable substituents are e.g. C₄-C₂₀-cycloalkyl, C₅-C₂₀-cycloalkenyl, C₆-C₂₀-cycloalkynyl, heterocyclyl, halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and S(═O)₂O⁻Z⁺, where R²⁵, R²⁶, Z⁺ are as defined above.

The term “C₁-C₂₀-alkylene” (or alkanediyl) refers to an alkyl residue having 1 to 20 carbon atoms as defined above, wherein one hydrogen atom of the alkyl residue is replaced by one further binding site, thus forming a bivalent residue. The hydrogen atom is not removed from the carbon atom carrying a binding site. Examples include methylene, ethylene, propylene (trimethylene), isopropylene, n-butylene (tetramethylene), sec-butylene, isobutylene, tert-butylene, 2-ethylbutylene, n-pentylene (pentamethylene), isopentylene, 1-methylpentylene, 1,3-dimethylbutylene, n-hexylene, 1-methylhexylene, n-heptylene, 2-methylheptylene, 1,1,3,3-tetramethylbutylene, 1-methylheptylene, 3-methylheptylene, n-octylene, 2-ethylhexylene, 1,1,3-trimethylhexylene, 1,1,3,3-tetramethylpentylene, nonylene, decylene, undecylene, 1-methylundecylene or dodecylene.

The term “C₁-C₂₀-alkylidene” refers to an alkyl residue having 1 to 20 carbon atoms as defined above, wherein one hydrogen atom of the alkyl residue is replaced by one further binding site, thus forming a bivalent residue. The hydrogen atom is removed from the carbon atom carrying a binding site. Accordingly, the free valences are part of a double bond.

The term “C₂-C₄-alkenylene” (or alkenediyl) as used herein in each case denotes a straight-chain or branched alkenyl residue having 2 to 4 carbon atoms as defined above, wherein one hydrogen atom at any position of the carbon backbone is replaced by one further binding site, thus forming a bivalent moiety. Examples include vinylene, propenylene, but-1-enylene or but-2-enylene.

The term “C₆-C₁₀-arylene” refers to an aryl group as defined below, wherein one hydrogen atom at any position of the aryl group is replaced by one further binding site, thus forming a bivalent residue. In case of polycyclic arylene, the bonding sites are either situated in the same ring or in different rings. Examples of arylene are phenylene such as 1,2-phenylene, 1,3-phenylene or 1,4-phenylene or naphthylene.

The term “C₇-C₂₀-aralkyl” refers to aryl-substituted alkyl. The aralkyl group has 7 to 20 carbon atoms, wherein aryl is as defined below, preferably phenyl or naphthyl, the alkyl moiety preferably is C₁-C₄-alkyl as defined above. Examples are 1-naphthylmethyl, 2-naphthylmethyl, benzyl, diphenylmethyl, 1-phenylethyl, 2-phenylethyl, 1-phenylpropyl, 2-phenyl-propyl, 3-phenylpropyl, 1-methyl-1-phenyl-ethyl, 4-phenylbutyl, 2,2-dimethyl-2-phenylethyl, especially benzyl.

The term “C₈-C₂₀-aralkenyl” refers to aryl-substituted alkenyl. The aralkenyl group has 8 to 20 carbon atoms, wherein aryl is as defined below, preferably phenyl or naphthyl, the alkenyl moiety preferably is C₂-C₄-alkenyl. Examples are styryl (2-phenylvinyl), 2,2-diphenylvinyl, triphenylvinyl, cinnamyl, 1-naphthylvinyl, 2-naphthylvinyl and fluoren-9-ylidenmethyl, especially 2,2-diphenylvinyl and triphenylvinyl.

The term “fluoren-9-ylidenemethyl” is

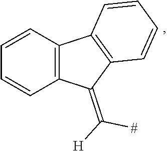

where # means the point of attachment to the remainder of the molecule.

The term “C₈-C₂₀-aralkynyl” refers to aryl-substituted alkynyl moieties. The aralkynyl group has 8 to 20 carbon atoms, wherein aryl preferably is phenyl or naphthyl, the alkynyl moiety preferably is C₂-C₄-alkynyl, e.g. 2-phenylethynyl.

The term “cycloalkyl” refers to a mono- or polycyclic, e.g. monocyclic, bicyclic or tricyclic, aliphatic residue having usually from 5 to 20, preferably 5 to 16, more preferably 3 to 12, or 3 to 8 carbon atoms. Examples of monocyclic rings are cyclopentyl, cyclohexyl, cycloheptyl or cyclooctyl, especially cyclopentyl and cyclohexyl. Examples of polycyclic rings are perhydroanthracyl, perhydronaphthyl, perhydrofluorenyl, perhydrochrysenyl, perhydropicenyl, adamantyl, bicyclo[1.1.1]pentyl, bicyclo[2.2.1]heptyl, bicyclo[4.2.2]decyl, bicyclo[2.2.2]octyl, bicyclo[3.3.0]octyl bicyclo[3.3.2]decyl, bicyclo[4.4.0]decyl, bicyclo[4.3.2]undecyl, bicyclo[4.3.3]dodecyl, bicyclo[3.3.3]undecyl, bicyclo[4.3.1]decyl, bicyclo[4.2.1]nonyl, bicyclo[3.3.1]nonyl, bicyclo[3.2.1]octyl and the like. Cycloalkyl may be interrupted by one or more CO groups, usually one or two groups. An example for cycloalkyl interrupted by 1 CO group is 3-oxobicyclo[2.2.1]heptyl. Substituted cycloalkyl groups may have one or more (e.g. 1, 2, 3, 4, 5 or more than 5) identical or different substituents. Suitable substituents are e.g. halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵, S(═O)₂O⁻Z⁺, C₁-C₂₀-alkyl, C₂-C₂₀-alkenyl, C₂-C₂₀-alkynyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, heterocyclyl, C₆-C₂₀-aryl, substituted C₆-C₂₀-aryl, unsubstituted or substituted maleic anhydridyl and unsubstituted or substituted maleimidyl, where R²⁵, R²⁶ and Z⁺ are as defined above.

The term “cycloalkenyl” refers to a mono- or polycyclic, e.g. monocyclic, bicyclic or tricyclic, aliphatic residue having usually from 5 to 20, preferably 5 to 16, more preferably 3 to 12, or 3 to 8 carbon atoms and at least one double bond, preferably one double bond at any position. Examples include cyclopentenyl, cyclohexenyl or the like. Cycloalkenyl may be interrupted by one or more CO groups, e.g. one or two CO groups. Substituted cycloalkenyl groups may have one or more (e.g. 1, 2, 3, 4, 5 or more than 5) identical or different substituents. Suitable substituents are e.g. halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵, S(═O)₂O⁻Z⁺, C₁-C₂₀-alkyl, C₂-C₂₀-alkenyl, C₂-C₂₀-alkynyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, heterocyclyl, C₆-C₂₀-aryl, substituted C₆-C₂₀-aryl, unsubstituted or substituted maleic anhydridyl and unsubstituted or substituted maleimidyl, where R²⁵, R²⁶ and Z⁺ are as defined above.

The term “heterocyclyl” (also referred to as heterocycloalkyl) as used herein includes in general 3-, 4-, 5-, 6-, 7- or 8-membered, in particular 5-, 6-, 7- or 8-membered monocyclic heterocyclic non-aromatic residues and 8-, 9- or 10-membered bicyclic heterocyclic non-aromatic residues, the mono- and bicyclic non-aromatic residues may be saturated or unsaturated. The mono- and bicyclic heterocyclic non-aromatic residues usually comprise besides carbon atom ring members 1, 2, 3 or 4 heteroatoms, in particular 1 or 2 heteroatoms selected from N, O and S as ring members, where S-atoms as ring members may be present as S, SO or SO₂. Heterocycloalkyl may be interrupted by one or more CO groups, e.g. one or two CO groups. When heterocyclyl is substituted by one or more identical or different residues, it is for example mono-, di-, tri-, tetra- or penta-substituted. Suitable substituents are e.g. halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵, S(═O)₂O⁻Z⁺, C₁-C₂₀-alkyl, C₂-C₂₀-alkenyl, C₂-C₂₀-alkynyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, heterocyclyl, C₆-C₂₀-aryl, substituted C₆-C₂₀-aryl, unsubstituted or substituted maleic anhydridyl and unsubstituted or substituted maleimidyl, where R²⁵, R²⁶ and Z⁺ are as defined above.

Examples of saturated or unsaturated 3-, 4-, 5-, 6-, 7- or 8-membered heterocyclic residues include saturated or unsaturated, non-aromatic heterocyclic rings, such as oxiranyl, oxetanyl, thietanyl, thietanyl-S-oxid (S oxothietanyl), thietanyl-S-dioxid (S-dioxothiethanyl), pyrrolidinyl, pyrazolinyl, imidazolinyl, pyrrolinyl, pyrazolinyl, imidazolinyl, tetrahydrofuranyl, dihydrofuranyl, 1,3-dioxolanyl, dioxolenyl, thiolanyl, S-oxothiolanyl, S-dioxothiolanyl, dihydrothienyl, S-oxodihydrothienyl, S-dioxodihydrothienyl, oxazolidinyl, isoxazolidinyl, oxazolinyl, isoxazolinyl, thiazolinyl, isothiazolinyl, thiazolidinyl, isothiazolidinyl, oxathiolanyl, piperidinyl, piperazinyl, pyranyl, dihydropyranyl, tetrahydropyranyl, 1,3- and 1,4-dioxanyl, thiopyranyl, S-oxothiopyranyl, S-dioxothiopyranyl, dihydrothiopyranyl, S-oxodihydrothiopyranyl, S-dioxodihydrothiopyranyl, tetrahydrothiopyranyl, S-oxotetrahydrothiopyranyl, S-dioxotetrahydrothiopyranyl, morpholinyl, thiomorpholinyl, S-oxothiomorpholinyl, S-dioxothiomorpholinyl, thiazinyl and the like. Examples of 5- to 6-membered heterocyclic residues comprising a fused benzene ring include dihydroindolyl, dihydroindolizynyl, dihydroisoindolyl, dihydroquinolinyl, dihydroisoquinolinyl, chromenyl and chromanyl. Examples for heterocyclic residues also comprising 1 or 2 carbonyl groups as ring members comprise pyrrolidin-2-onyl, pyrrolidin-2,5-dionyl, imidazolidin-2-onyl, oxazolidin-2-onyl, thiazolidin-2-onyl, 3-oxo-2-oxa-bicyclo[2.2.1]heptanyl and the like.

The term “C₆-C₂₀-aryl” refers to a mono-, bi- or tricyclic aromatic hydrocarbon residue having 6 to 20 carbon ring members such as phenyl, naphthyl, anthracenyl, phenanthrenyl, fluorenyl, pyrenyl, indenyl and the like, especially phenyl. Likewise preferably, C₆-C₂₀-aryl is naphthyl or pyrenyl. Substituted phenyl is substituted once, twice, three times, four times or five times. The substituents may be identical or different. Bi- or tricyclic aryl is usually substituted by 1, 2, 3, 4, 5, 6, 7 or 8 identical or different substituents, preferably 1, 2, 3 or 4. Suitable substituents include C₁-C₂₀-alkyl, C₂-C₂₀-alkenyl, C₂-C₂₀-alkynyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, halogen, S—R¹⁴, O—R¹⁴, CO—OR¹⁴, O—CO—R¹⁴, O—CO—R^{14″}, NR¹⁴R¹⁴′, CONR¹⁴R¹⁴′, NR¹⁴—CO—R¹⁴′, S(═O)₂OR¹⁴ and S(═O)₂O⁻Z⁺, where R¹⁴′ has one of the meanings given for R¹⁴ and where R¹⁴ is as defined above; and where R^{14″} is C₂-C₂₀-alkyl which is interrupted by one or more, e.g., 2, 3, 4, 5, 6, 7, 8, 9, 10 or more than 10 oxygen atoms. If C₂-C₂₀ alkyl is interrupted by oxygen atom(s), the total sum of the chain members of C₂-C₂₀ alkyl interrupted by oxygen atom(s) equal the numbers of carbon and oxygen atoms present in the chain.

The term “C₆-C₂₀-fluoroaryl” refers to a mono-, bi- or tricyclic aromatic hydrocarbon residue having 6 to 20 carbon ring members such as phenyl, naphthyl, anthracenyl, phenanthrenyl, fluorenyl, pyrenyl, indenyl and the like, especially phenyl, wherein some or all of the hydrogen atoms in these groups are replaced by fluorine.

The term “heteroaryl” (also referred to as hetaryl) includes in general 5- or 6-membered unsaturated monocyclic heterocyclic residues and 8-, 9- or 10-membered unsaturated bicyclic heterocyclic residues which are aromatic. Hetaryl usually comprise besides carbon atom(s) as ring member(s) 1, 2, 3 or 4 heteroatoms selected from N, O and S as ring members. Examples of 5- or 6-membered heteroaromatic residues include: 2-furyl, 3-furyl, 2-thienyl, 3-thienyl, 1-pyrrolyl, 2-pyrrolyl, 3-pyrrolyl, 1-pyrazolyl, 3-pyrazolyl, 4-pyrazolyl, 5-pyrazolyl, 2-oxazolyl, 4-oxazolyl, 5-oxazolyl, 2-thiazolyl, 4-thiazolyl, 5-thiazolyl, 3-isoxazolyl, 4-isoxazolyl or 5-isoxazolyl, 3-isothiazolyl, 4-isothiazolyl or 5-isothiazolyl, 1-imidazolyl, 2-imidazolyl, 4-imidazolyl, 2- or 5-[1,3,4]oxadiazolyl, 4- or 5-(1,2,3-oxadiazol)yl, 3- or 5-(1,2,4-oxadiazol)yl, 2- or 5-(1,3,4-thiadiazol)yl, 2- or 5-(1,3,4-thiadiazol)yl, 4- or 5-(1,2,3-thiadiazol)yl, 3- or 5-(1,2,4-thiadiazol)yl, 1H-, 2H- or 3H-1,2,3-triazol-4-yl, 1,3,4-triazol-2-yl, 2H-triazol-3-yl, 1H-, 2H-, or 4H-1,2,4-triazolyl, 1H- or 2H-tetrazolyl 2-pyridinyl, 3-pyridinyl, 4-pyridinyl, 3-pyridazinyl, 4-pyridazinyl, 2-pyrimidinyl, 4-pyrimidinyl, 5-pyrimidinyl and 2-pyrazinyl. When heteroaryl is substituted by one or more identical or different residues, it is for example mono-, di-, tri-, tetra- or penta-substituted.

The term “heteroaryl” also includes bicyclic 8- to 10-membered heteroaromatic residues comprising as ring members 1, 2 or 3 heteroatoms selected from N, O and S, wherein a 5- or 6-membered heteroaromatic ring is fused to a phenyl ring or to a 5- or 6-membered heteroaromatic residue. Examples of a 5- or 6-membered heteroaromatic ring fused to a phenyl ring or to a 5- or 6-membered heteroaromatic residue include benzofuranyl, benzothienyl, indolyl, indazolyl, benzimidazolyl, benzoxathiazolyl, benzoxadiazolyl, benzothiadiazolyl, benzoxazinyl, chinolinyl, isochinolinyl, purinyl, 1,8-naphthyridyl, pteridyl, pyrido[3,2-d]pyrimidyl or pyridoimidazolyl and the like. These fused hetaryl residues may be bonded to the remainder of the molecule via any ring atom of 5- or 6-membered heteroaromatic ring or via a carbon atom of the fused phenyl moiety.

The term “organic or inorganic cation equivalent” refers to a monovalent cation or that part of a polyvalent cation which corresponds to a single positive charge. The cation Z⁺ serves merely as counter cation for balancing negatively charged substituent groups of the sulfonate group, and can in principle be chosen at will. Preference is therefore given to using alkali metal ions, in particular Na⁺, K⁺, or Li⁺ ions, an equivalent of an earth alkaline metal cation, in particular magnesium ion equivalent (½ Mg²⁺) or calcium ion equivalent (½ Ca²⁺) or onium ions, e.g. ammonium, monoalkylammonium, dialkylammonium, trialkylammonium, tetraalkylammonium, phosphonium, tetraalkylphosphonium or tetraarylphosphonium ions.

The term “and/or” or “or/and” are meant to express that not only one of the defined alternatives (substituents) may be present, but also several of the defined alternatives (substituents) together, namely mixtures of different alternatives (substituents).

The term “at least” is meant to define one or more than one, for example one, two, three, preferably one to two.

The term “one or more identical or different residues” is meant to define one, two, three, four, five, six, seven, eight or more than eight identical or different residues.

The remarks made below as to preferred embodiments of the variables (substituents) and indices of the compounds of formula I are valid on their own as well as preferably in combination with each other.

The remarks made below concerning preferred embodiments of the variables (substituents) and indices further are valid concerning the electrode layer, devices and the use of the compound of the formula (I) according to the present invention.

A specific embodiment of the invention relates to an electrode layer sensitized with a compound of the formula (I), photoelectric conversion elements comprising said electrode layer, compounds of the formula (I), where

R¹⁷ and R¹⁸ are independently of each other selected from unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof, where R¹⁴ is hydrogen, C₁-C₂₀-alkyl or C₆-C₁₀-aryl;
or
R¹⁷ and R¹⁸, R¹⁷ and R²², R¹⁷ and R²⁰ and/or R¹⁸ and R¹⁹ form together an unsubstituted or substituted 5-, 6- or 7-membered ring.

Another specific embodiment of the invention relates to an electrode layer sensitized with a compound of the formula (I), photoelectric conversion elements comprising said electrode layer, compounds of the formula (I), where in the compound of the formula (I), D is the residue of the formulae (D.1) and (D.2),

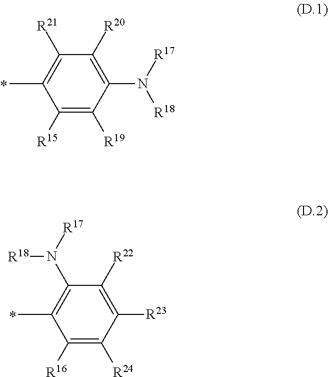

where
* denotes the point of attachment to the remainder of the molecule,
R¹⁷ and R¹⁸ are independently selected from C₁-C₂₀-alkyl, C₂-C₂₀-alkenyl, C₂-C₂₀-alkynyl, C₆-C₂₀-aryl, heteroaryl, heterocyclyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, wherein alkyl, alkenyl, alkynyl or the aliphatic moieties in aralkyl, aralkenyl or aralkynyl are uninterrupted or interrupted by O, S, NR¹⁴ or combinations thereof and/or may carry one or more substituents selected from C₄-C₂₀-cycloalkyl, C₅-C₂₀-cycloalkenyl, C₆-C₂₀-cycloalkynyl, heterocyclyl, halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and S(═O)₂O⁻Z⁺ and wherein aryl, the aryl moiety of aralkyl, aralkenyl, or aralkynyl, heteroaryl, heterocyclyl, cycloalkyl, cycloalkenyl or cycloalkynyl are unsubstituted or may carry one or more substituents selected from halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵, S(═O)₂O⁻Z⁺, C₁-C₂₀-alkyl, C₂-C₂₀-alkenyl, C₂-C₂₀-alkynyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, heterocyclyl, C₆-C₂₀-aryl, C₆-C₂₀-aryl which carries one or more substituents selected from C₁-C₂₀-alkyl and OR²⁵, maleic anhydridyl and maleimidyl, wherein the 2 last mentioned residues are unsubstituted or may carry substituents selected from C₁-C₂₀-alkyl, C₆-C₂₀-aryl and phenyl-NR²⁵R²⁶;
or
R¹⁷ and R¹⁸ may form together with the nitrogen atom to which they are attached a 5-, 6- or 7-membered, saturated or unsaturated heterocycle which may have 1 or 2 further heteroatoms selected from O, S and N as ring members and wherein the heterocycle is unsubstituted or may carry one or more substituents R^{x1};
where
each R^{x1} is selected from C₁-C₂₀-alkyl which is unsubstituted or may carry one or more substituents and phenyl, which is unsubstituted or may carry one or more substituents R^{x3}, in addition two residues R^{x1} bonded to adjacent carbon atoms may form together with the carbon atoms to which they are bonded a 4-, 5-, 6- or 7-membered saturated or unsaturated carbocyclic ring or an aromatic ring selected from benzene, naphthalene, anthracene and 9H-fluorene,
where the carbocyclic and the aromatic ring are unsubstituted or carry one or more substituents R^{x3},
and/or two residues R^{x1} present on the same carbon atom may be C₁-C₂₀-alkylidene which is unsubstituted or carry one or more substituents R^{x2}, where
R^{x2} is selected from halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and
S(═O)₂O⁻Z⁺,
R^{x3} is selected from C₁-C₁₀-alkyl, fluoren-9-ylidenemethyl, halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and S(═O)₂O⁻Z⁺;
or
R¹⁷ and R²⁰ may form together with the nitrogen atom to which R¹⁷ is attached and the carbon atoms of the benzene ring to which R²⁰ and N—R¹⁷ are attached an unsubstituted or substituted 5-, 6- or 7-membered ring which may have 1 or 2 further heteroatoms selected from O, S and N as ring members and wherein the heterocycle is unsubstituted or may carry one or more substituents R^{x4};
or
R¹⁷ and R²² may form together with the nitrogen atom to which R¹⁷ is attached and the carbon atoms of the benzene ring to which R²² and N—R¹⁷ are attached an unsubstituted or substituted 5-, 6- or 7-membered ring, which may have 1 or 2 further heteroatoms selected from O, S and N as ring members and wherein the heterocycle is unsubstituted or may carry one or more substituents R^{x4};
and/or
R¹⁸ and R¹⁹ may form with the nitrogen atom to which R¹⁸ is attached and the carbon atoms of the benzene ring to which R¹⁹ and N—R¹⁸ are attached an unsubstituted or substituted 5-, 6- or 7-membered ring which may have 1 or 2 further heteroatoms selected from O, S and N as ring members and wherein the heterocycle is unsubstituted or may carry one or more substituents R^{x4};
where
each R^{x4} is selected from C₁-C₂₀-alkyl which is unsubstituted or may carry one or more substituents R^{x5} and phenyl, which is unsubstituted or carry one or more substituents R^{x6},
in addition two residues R^{x4} bonded to adjacent carbon atoms may form together with the carbon atoms to which they are bonded a 4-, 5-, 6- or 7-membered saturated or unsaturated carbocyclic ring or an aromatic ring selected from benzene, naphthalene, anthracene and 9H-fluorene, where the carbocyclic or the aromatic ring are unsubstituted or may carry one or more substituents R^{x6},
and/or two residues R^{x4} present on the same C atom may be C₁-C₂₀-alkylidene which is unsubstituted or carry one or more substituents R^{x5};
where
each R^{x5} has one of the meanings given for R^{x2}, and
each R^{x6} has one of the meaning given for R^{x3} and where in addition two residues R^{x6} bonded to adjacent carbon atoms may form together with the carbon atoms to which they are bonded a benzene or naphthalene ring;
R¹⁵, R¹⁶, R¹⁹, R²⁰, R²¹, R²², R²³ and R²⁴ are independently selected from hydrogen, NR²⁵R²⁶, OR²⁵, SR²⁵, NR²⁵—NR²⁶R²⁷, NR²⁵—OR²⁶, O—CO—R²⁵, O—CO—OR²⁵, O—CO—NR²⁵R²⁶, NR²⁵—CO—R²⁶, NR²⁵—CO—OR²⁶, NR²⁵—CO—NR²⁶R²⁷, CO—R²⁵, CO—OR²⁵, CO—NR²⁵R²⁶, CO—SR²⁵, CO—NR²⁵—NR²⁶R²⁷, CO—NR²⁵—OR²⁶, CO—O—CO—R²⁵, CO—O—CO—OR²⁵, CO—O—CO—NR²⁵R²⁶, CO—NR²⁵—CO—R²⁶, CO—NR²⁵—CO—OR²⁶, C₁-C₂₀-alkyl, C₂-C₂₀-alkenyl, C₂-C₂₀-alkynyl, C₆-C₂₀-aryl, heteroaryl, heterocyclyl, C₇-C₂₀-aralkyl, C₈-C₂₀-aralkenyl, C₈-C₂₀-aralkynyl, C₄-C₂₀-cycloalkyl, C₅-C₂₀-cycloalkenyl and C₆-C₂₀cycloalkynyl, wherein alkyl is uninterrupted or interrupted by O, S, NR¹⁴ or combinations thereof, and wherein alkyl, the alkyl moiety of aralkyl, alkenyl, the alkenyl moiety of aralkenyl, alkynyl and the alkynyl moiety of aralkynyl may carry substituents selected from C₄-C₂₀-cycloalkyl, halogen, S—R¹⁴, O—R¹⁴, CO—OR¹⁴, O—CO—R¹⁴, NR¹⁴R¹⁴′, CONR¹⁴R¹⁴′, NR¹⁴—CO—R¹⁴′, S(═O)₂OR¹⁴ and S(═O)₂O⁻Z⁺,
where aryl, the aryl moiety of aralkyl, aralkenyl and aralkynyl, heteroaryl, heterocyclyl, cycloalkyl, cycloalkenyl and cycloalkynyl may carry substituents selected from C₁-C₂₀-alkyl, C₂-C₂₀-alkenyl, C₂-C₂₀-alkynyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, halogen, S—R¹⁴, O—R¹⁴, CO—OR¹⁴, O—CO—R¹⁴, NR¹⁴R¹⁴′, CONR¹⁴R¹⁴′, NR¹⁴—CO—R¹⁴′, S(═O)₂OR¹⁴ and S(═O)₂O⁻Z⁺, where R¹⁴′ has one of the meanings given for R¹⁴ and where R¹⁴, R²⁵, R²⁶, R²⁷ and Z are as defined above.

According to a specific aspect of this embodiment, D is a residue selected from the residues of the formulas D.1 and D.2, where

R¹⁷ and R¹⁸ are independently selected from C₁-C₂₀-alkyl, C₂-C₂₀-alkenyl, C₂-C₂₀-alkynyl, C₆-C₂₀-aryl, heteroaryl, heterocyclyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, wherein alkyl, alkenyl, alkynyl or the aliphatic moieties in aralkyl, aralkenyl or aralkynyl are uninterrupted or interrupted by O, S, NR¹⁴ or combinations thereof and/or may carry one or more substituents selected from C₄-C₂₀-cycloalkyl, C₅-C₂₀-cycloalkenyl, C₆-C₂₀-cycloalkynyl, heterocyclyl, halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and S(═O)₂O⁻Z⁺ and wherein aryl, the aryl moiety of aralkyl, aralkenyl, or aralkynyl, heteroaryl, heterocyclyl, cycloalkyl, cycloalkenyl or cycloalkynyl are unsubstituted or may carry one or more substituents selected from halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵, S(═O)₂O⁻Z⁺, C₁-C₂₀-alkyl, C₂-C₂₀-alkenyl, C₂-C₂₀-alkynyl, C₇-C₂₀-aralkyl, C₈-C₂₀-aralkenyl, C₈-C₂₀-aralkynyl, C₄-C₂₀-cycloalkyl, C₅-C₂₀-cycloalkenyl, C₆-C₂₀-cycloalkynyl, heterocyclyl, C₆-C₂₀-aryl, C₆-C₂₀-aryl which carries one or more substituents selected from C₁-C₂₀-alkyl and OR²⁵, maleic anhydridyl and maleimidyl, wherein the 2 last mentioned residues are unsubstituted or may carry substituents selected from C₁-C₂₀-alkyl, C₆-C₂₀-aryl and phenyl-NR²⁵R²⁶;
or
R¹⁷ and R¹⁸ may form together with the nitrogen atom to which they are attached a 5-, 6- or 7-membered, saturated or unsaturated heterocycle which may have 1 or 2 further heteroatoms selected from O, S and N as ring members and wherein the heterocycle is unsubstituted or may carry one or more substituents R^{x1},
where
each R^{x1} is selected from C₁-C₂₀-alkyl which is unsubstituted or may carry one or more substituents and phenyl, which is unsubstituted or may carry one or more substituents R^{x3}, in addition two residues R^{x1} bonded to adjacent carbon atoms may form together with the carbon atoms to which they are bonded a 4-, 5-, 6- or 7-membered saturated or unsaturated carbocyclic ring or an aromatic ring selected from benzene, naphthalene, anthracene and 9H-fluorene,
where the carbocyclic and the aromatic ring are unsubstituted or carry one or more substituents R^{x3},
and/or two residues R^{x1} present on the same carbon atom may be C₁-C₂₀-alkylidene which is unsubstituted or carry one or more substituents R^{x2}, where
R^{x2} is selected from halogen, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and S(═O)₂O⁻Z⁺,
R^{x3} is selected from C₁-C₁₀-alkyl, halogen, fluoren-9-ylidenemethyl, S—R²⁵, O—R²⁵, CO—OR²⁵, O—CO—R²⁵, NR²⁵R²⁶, CONR²⁵R²⁶, NR²⁵—CO—R²⁶, S(═O)₂OR²⁵ and S(═O)₂O⁻Z⁺;
or
R¹⁷ and R²², R¹⁷ and R²⁰ and/or R¹⁸ and R¹⁹ may form together with the nitrogen atom to which they are attached a 5-, 6- or 7-membered, saturated or unsaturated heterocycle which may have 1 or 2 further heteroatoms selected from O, S and N as ring members and wherein the heterocycle may be unsubstituted or may carry one or more substituents R^{x4}, where
each R^{x4} is selected from C₁-C₂₀-alkyl which is unsubstituted or may carry one or more substituents R^{x5} and phenyl, which is unsubstituted or carry one or more substituents R^{x6},
in addition two residues R^{x4} bonded to adjacent carbon atoms may form together with the carbon atoms to which they are bonded a 4-, 5-, 6- or 7-membered saturated or unsaturated carbocyclic ring or an aromatic ring selected from benzene, naphthalene, anthracene and 9H-fluorene, where the carbocyclic or the aromatic ring are unsubstituted or may carry one or more substituents R^{x6},
and/or two residues R^{x4} present on the same C atom may be C₁-C₂₀-alkylidene which is unsubstituted or carry one or more substituents R^{x5};
where
each R^{x5} has one of the meanings given for R^{x2}, and
each R^{x6} has one of the meaning given for R^{x3}.

According to a specific aspect of this embodiment, D.1 is selected from residues of the formulae D.1-a, D.1-b, D.1-c, D.1-c, D.1-d, D.1-e, D.1-f, D.1-g, D.1-h, D.1-i, D.1-k, D.1-l, D.1-m, D.1-n, D.1-o, D.1-p, D.1-q, D.1-r and D.1-s, preferably D.1-a

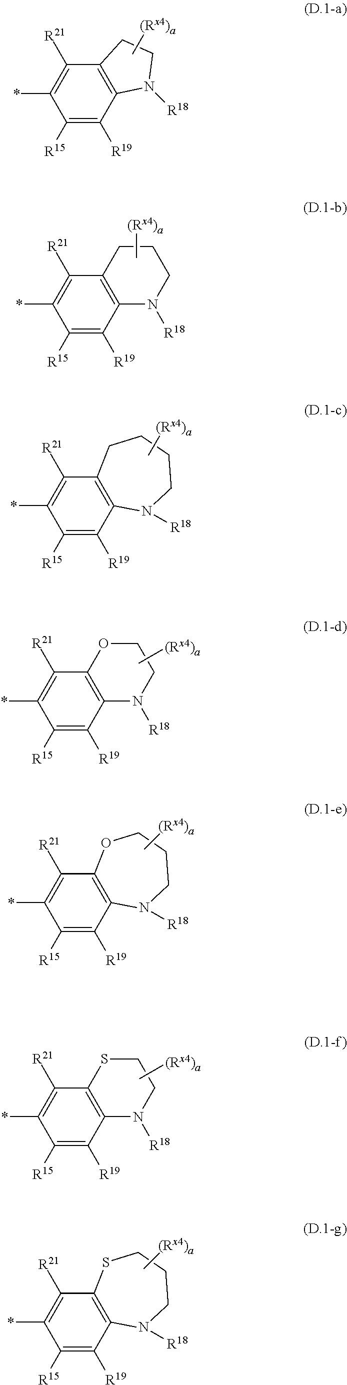

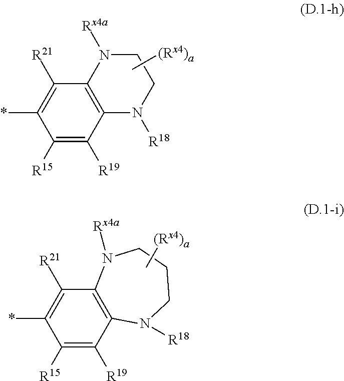

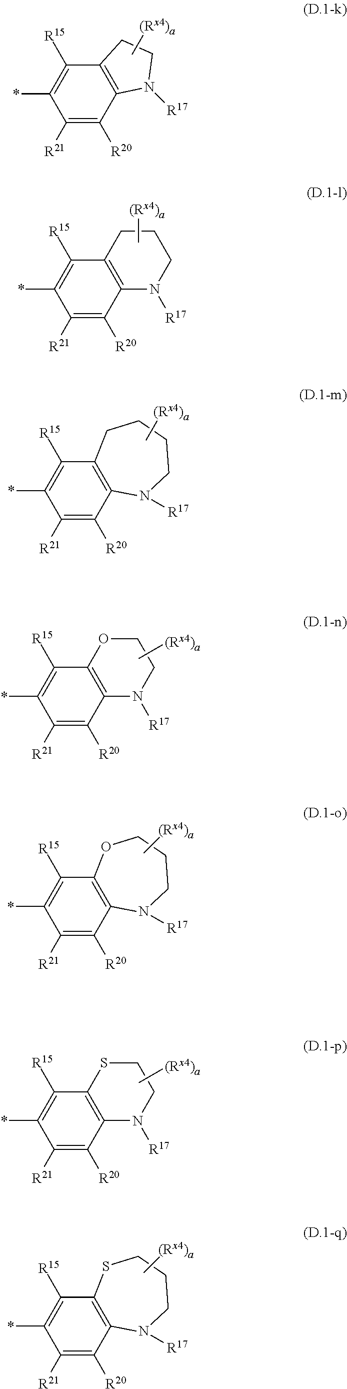

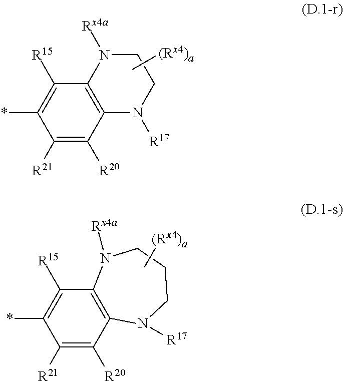

wherein
* is the point of attachment to the remainder of the molecule,
R¹⁵ and R²¹ have one of the meanings given above, especially a preferred one;
R¹⁷, R¹⁸, R¹⁹ and R²⁰, if present, have one of the meanings given above, especially a preferred one;
R^{x4} is as defined above;
R^{x4a} is hydrogen or has one of the meanings given for R^{x4}; and
a is 0, 1, 2, 3, 4, 5, 6, 7 or 8.

According to a further specific aspect of this embodiment D1 is selected from residues of the formulae D.1-t, D.1-u, D.1-v, D.1-w, D.1-x, D.1-y and D.1-z

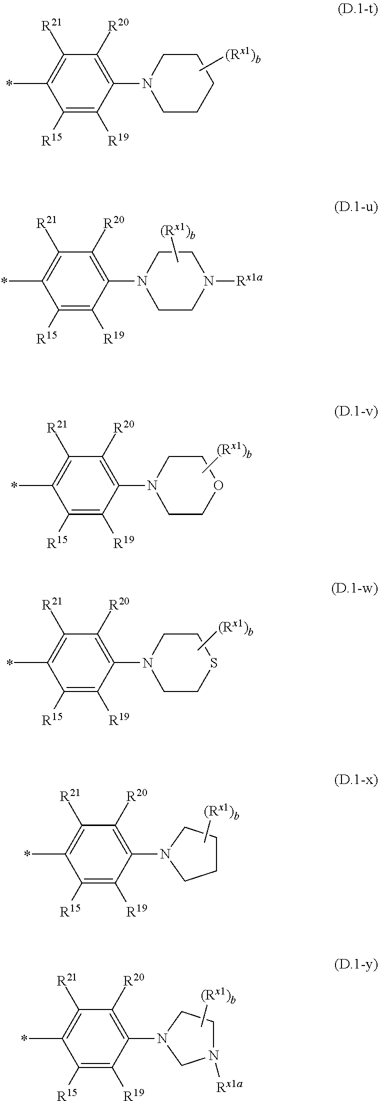

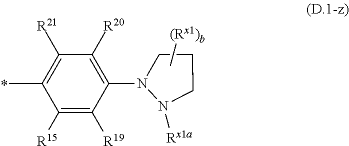

where
* is the point of attachment to the remainder of the molecule,
R¹⁵, R¹⁹, R²⁰ and R²¹ have one of the meanings given above, especially a preferred one;
R^{x1} is as defined above;
R^{x1a} is hydrogen or has one of the meanings given for R^{x1}; and
b is 0, 1, 2, 3, 4, 5, 6, 7, 8, 9 or 10.

According to a specific aspect of this embodiment, D.2 is selected from residues of the formulae D.2-a, D.2-b, D.2-c, D.2-d, D.2-e, D.2-f, D.2-g, D.2-h, D.2-i,

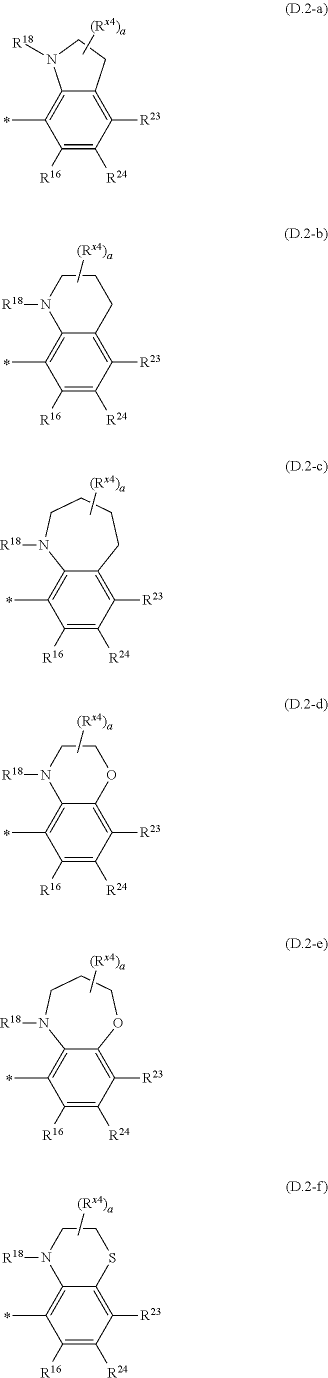

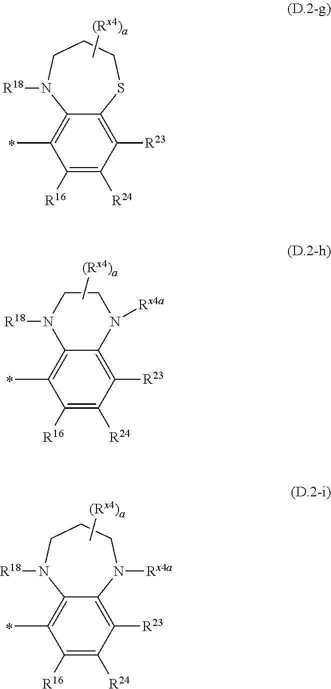

wherein
R¹⁶, R¹⁸, R²³ and R²⁴ have one of the meanings given above, especially a preferred one;
R^{x4} is as defined above;
R^{x4a} is hydrogen or has one of the meanings given for R^{x4}; and
a is 0, 1, 2, 3, 4, 5 or 6.

According to a further specific aspect of this embodiment, D.2 is selected from residues of the formulae D.2-a, D.2-b, D.2-c, D.2-d, D.2-e, D.2-f, D.2-g, D.2-h, D.2-i, D.2-k, D.2-l, D.2-m, D.2-n, D.2-o, D.2-p and D.2-q,

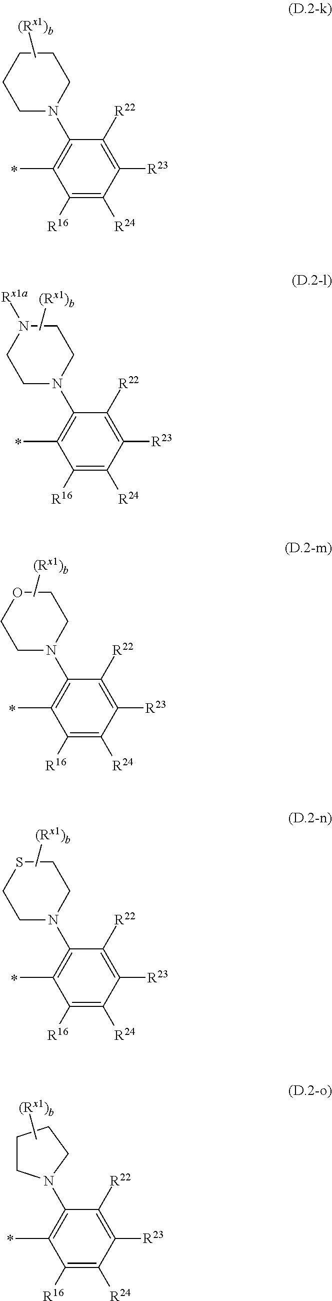

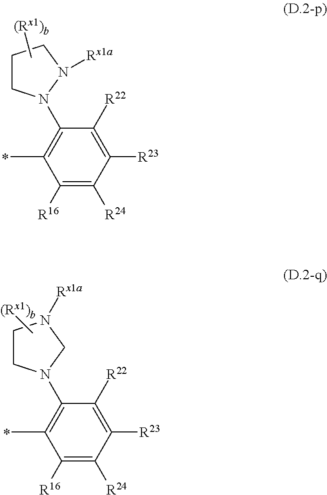

wherein
R¹⁶, R²², R²³ and R²⁴ have one of the meanings given above, especially a preferred one;
R^{x1} is as defined above;
R^{x1a} is hydrogen or has one of the meanings given for R^{x1}; and
b is 0, 1, 2, 3, 4, 5, 6, 7, 8, 9 or 10.

According to a specific aspect of this embodiment R¹⁷ and R¹⁸ are independently of each other selected from C₁-C₈-alkyl, C₂-C₈-alkenyl, C₆-C₂₀-aryl, heteroaryl, C₇-C₂₀-aralkyl, C₈-C₂₀-aralkenyl, C₈-C₁₀-aralkynyl and C₅-C₁₂-cycloalkyl, where alkyl or alkenyl may be unsubstituted or may carry 1, 2 or 3 substituents selected from tetrahydrofuranyl, halogen, S—R¹⁴, O—R¹⁴, CO—OR¹⁴, O—CO—R¹⁴, NR¹⁴R¹⁴′, CONR¹⁴R¹⁴′ and NR¹⁴—CO—R¹⁴′, where aryl, heteroaryl, the aryl moiety of aralkyl, aralkenyl and aralkynyl and cycloalkyl are unsubstituted or may carry substituents selected from C₁-C₈-alkyl, C₂-C₈-alkenyl and C₈-C₂₀-aralkenyl; or

R¹⁷ and R²⁰ may form together with the nitrogen atom to which R¹⁷ is attached and the carbon atoms of the benzene ring to which R²⁰ and N—R¹⁷ are attached a 5-, 6- or 7-membered, saturated or unsaturated heterocycle which may have 1 further heteroatom selected from O, S and N as ring member and wherein the heterocycle may be unsubstituted or may carry one or more substituents R^{X4} selected from C₁-C₂₀-alkyl and phenyl,
in addition two residues R^{x4} bonded to adjacent carbon atoms may form together with the carbon atoms to which they are bonded a 4-, 5-, 6- or 7-membered saturated or unsaturated carbocyclic ring or an aromatic ring selected from benzene and 9H-fluorene where the carbocyclic and the aromatic ring are unsubstituted or carry one or more substituents selected from C₁-C₈-alkyl and fluoren-9-ylidenemethyl, and/or two residues R^{x4} present on the same carbon atom may be C₁-C₂₀-alkylidene;
R¹⁵ is selected from hydrogen, NR²⁵R²⁶, OR²⁵, SR²⁵, O—CO—R²⁵ and NR²⁵—CO—R²⁶; and
R¹⁹, R²⁰ and R²¹ are hydrogen, wherein R¹⁴′ has one of the meanings given for R¹⁴ and
R¹⁴, R²⁵, R²⁶, R²⁷ and Z are as defined above.

According to a more specific aspect of this embodiment, D is a residue of the formula D.1. In particular D is a residue D.1, where

R¹⁷ and R¹⁸ are independently of each other selected from C₁-C₈-alkyl, phenyl which is unsubstituted or carries 1 or 2 substituents selected from C₁-C₈-alkyl, C₁-C₄-alkoxy, 2-phenylvinyl, 2,2-diphenyl-vinyl and triphenylvinyl, 9H-fluoren-2-yl, which is unsubstituted or carries 1, 2 or 3 substituents selected from C₁-C₆-alkyl, and pyrenyl, which is unsubstituted or carries 1 or 2 substituents selected from C₁-C₆-alkyl;
or
R¹⁷ and R¹⁸ together with the nitrogen atom to which they are attached are morpholinyl;
or
R¹⁷ and R²⁰ form together with the nitrogen atom to which R¹⁷ is attached and the carbon atoms of the benzene ring to which R²⁰ and N—R¹⁷ are attached a 5- or 6-membered, nitrogen heterocycle which is unsubstituted or carries 2 residues R^{x4}, where two residues R^{X4} on two adjacent carbon atoms form together with the carbon atoms they are bonded to a 4-, 5-, 6-, or 7-membered saturated ring or a benzene ring,
R¹⁵ is hydrogen, C₁-C₂₀-alkyl or OR²⁵ where R²⁵ is as defined above, preferably R²⁵ is C₁-C₁₄-alkyl; and
R¹⁹, R²⁰ and R²¹ are each hydrogen.

According to a further more specific aspect of this embodiment, D is a residue of the formula D.1, where R¹⁷ and R¹⁸ together with the nitrogen atom to which they are attached are thiomorpholinyl, piperidinyl, piperazinyl, pyrrolidinyl, pyrazolidinyl or imidazolidinyl.

According to an even more specific aspect of this embodiment D is a residue of the formula D.1, where R¹⁵, R¹⁹, R²⁰ and R²¹ are each hydrogen and R¹⁷ and R¹⁸ are independently of each other selected from C₁-C₆-alkyl.

According to a further more specific aspect of this embodiment D is a residue of the formula D.1 selected from residues of the formulae D.1-1 and D.1-2

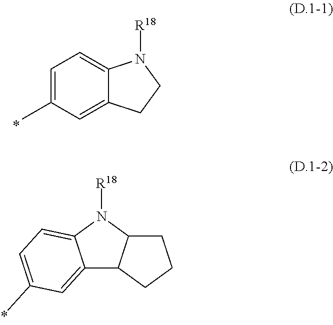

wherein
* denotes the point of attachment to the remainder of the molecule and
R¹⁸ is phenyl which is substituted by 2-phenylvinyl or 2,2-diphenylvinyl, 9H-fluoren-2-yl or 9,9-di(C₁-C₈-alkyl)-9H-fluoren-2-yl.

In particular, R¹⁸ is phenyl which carries in the 4-position one residue selected from 2-phenylvinyl and 2,2-diphenylvinyl, or R¹⁸ is 9H-fluoren-2-yl, 9,9-dimethyl-9H-fluoren-2-yl, 9,9-diethyl-9H-fluoren-2-yl, 9,9-di(n-propyl)-9H-fluoren-2-yl or 9,9-di(n-butyl)-9H-fluoren-2-yl.

Examples of suitable donors D are:

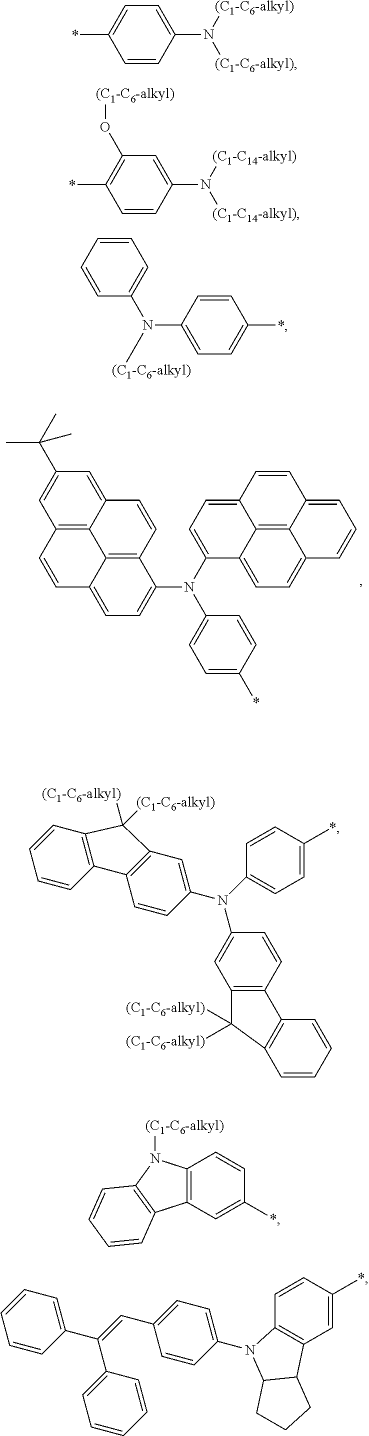

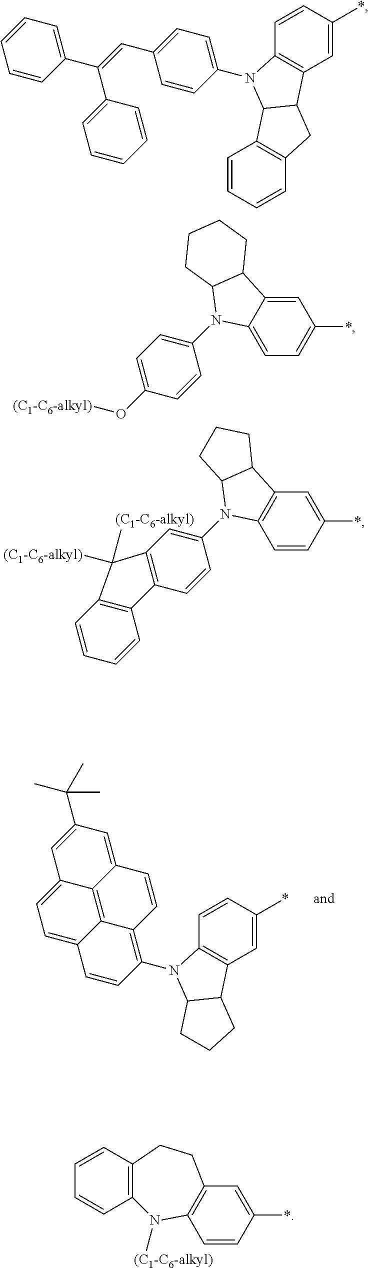

A further suitable donor D is

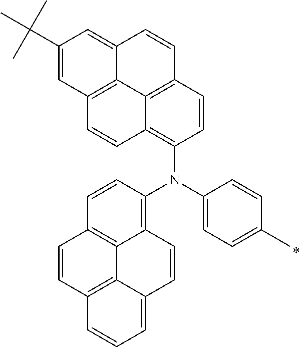 [SMILES: Cc1ccc(N(c2ccc3ccc4cccc5ccc2c3c45)c2ccc3ccc4cc(C(C)(C)C)cc5ccc2c3c45)cc1]

Especially preferred donors D are

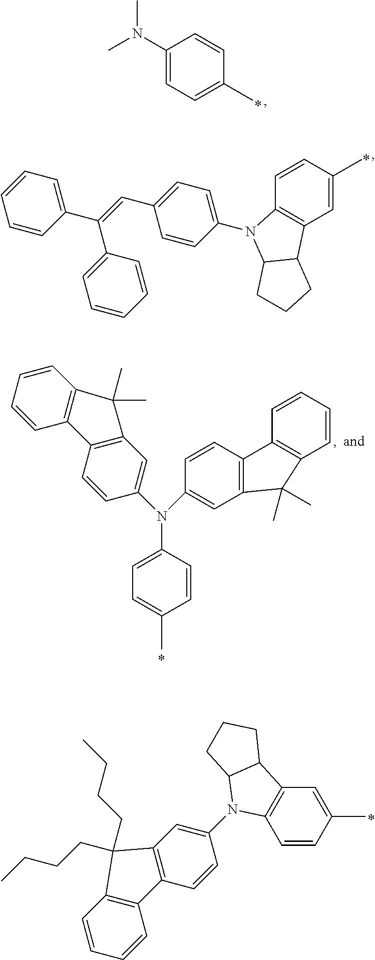

Another specific embodiment of the invention relates to an electrode layer sensitized with a compound of the formula (I), photoelectric conversion elements comprising said electrode layer, compounds of the formula (I), where in the compound of the formula (I), A is selected from the residues of the formulae A.1.1a, A.1.1b, A.2, A.3, A.4 and A.5

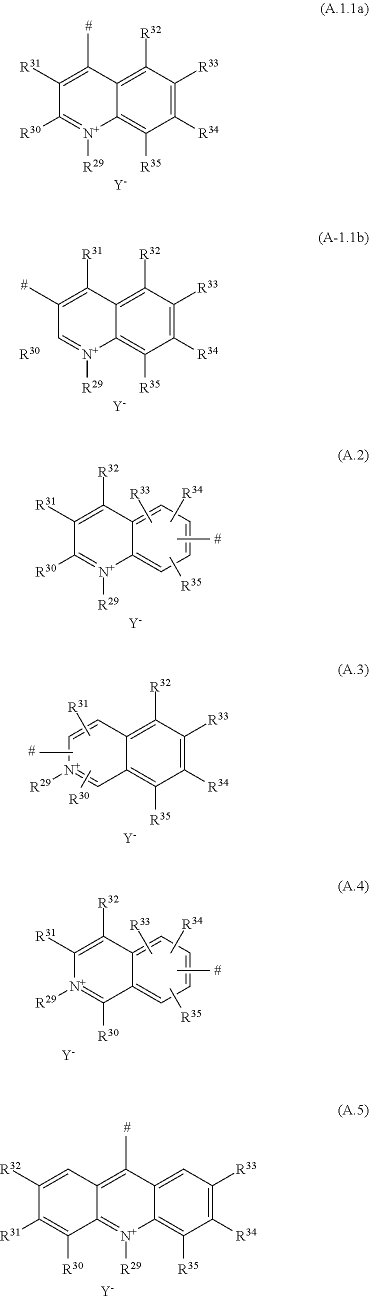

where
# denotes the bond to the remaining compound of formula I
Y⁻, R²⁹, R³⁰, R³¹, R³², R³³, R³⁴ and R³⁵ are as defined above.

According to a specific aspect of this embodiment, A is a residue of the formulae A.1.1a, A.1.1b, A.2, A.3 or A.4,

where
R²⁹ is selected from a residue G, C₁-C₂₀-alkyl which is uninterrupted or interrupted by O, S, CO, NR¹⁴ or combinations thereof, C₆-C₂₀-aryl, heteroaryl, C₇-C₂₀-aralkyl, C₆-C₂₀-aryl substituted by 1, 2 or 3 C₁-C₈-alkyl, and C₇-C₂₀-aralkyl wherein the aryl moiety of aralkyl is substituted by 1, 2 or 3 C₁-C₈-alkyl;
R³⁰ is selected from a residue G, hydrogen, C₁-C₂₀-alkyl wherein alkyl is uninterrupted or interrupted by O, S, CO, NR¹⁴ or combinations thereof, C₆-C₂₀-aryl, heteroaryl, and C₆-C₂₀-aryl wherein the aryl moiety of aralkyl is substituted by 1, 2 or 3 C₁-C₈-alkyl;
R³¹ is selected from hydrogen and a residue of the formula D*

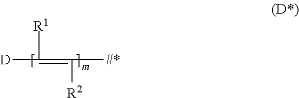

where #* denotes the point of attachment to the remainder of the molecule, m is 1, 2, 3, 4, 5 or 6, and D, R¹ and R² are as defined above;
R³², R³³, R³⁴ and R³⁵ are independently selected from hydrogen or C₁-C₂₀-alkyl wherein alkyl is uninterrupted or interrupted by O, S, NR¹⁴ or combinations thereof, C₆-C₂₀-aryl, heteroaryl, and C₆-C₂₀-aryl wherein the aryl moiety of aralkyl is substituted by 1, 2 or 3 C₁-C₈-alkyl; and
G is selected from —R²⁸—COOH, —R²⁸—COO⁻Z⁺; —R²⁸—SO₃H, —R²⁸—SO₃Z⁺; —R²⁸—OP(O)(O⁻Z⁺)₂, —R²⁸—OP(O)(OH)₂ and —R²⁸—OP(O)(OH)O⁻Z⁺, where R²⁸ is a direct bond, C₁-C₂₀-alkylene, C₂-C₄-alkenylene or C₆-C₁₀-arylene and Z⁺ is N(R¹⁴)₄⁺, or an alkali metal cation, where R¹⁴ is as defined above; and
Y⁻ is as defined above.

According to a specific aspect of this embodiment, R²⁹ is a residue G, C₁-C₈-alkyl or C₁-C₈-alkyl which is interrupted by one or two heteroatoms or heteroatomic groups selected from O, S, CO and NR¹⁴; in particular a residue G;

R³⁹ is hydrogen, a residue G, C₁-C₈-alkyl or C₁-C₈-alkyl which is interrupted by one or two heteroatoms or heteroatomic groups selected from O, S, CO and NR¹⁴;
R³¹ is hydrogen;
R³², R³³, R³⁴ and R³⁵ are independently of each other selected from hydrogen, C₁-C₈-alkyl and C₁-C₈-alkyl which is interrupted by one or two heteroatoms selected from O, S and NR¹⁴;
G is —R²⁸—COOH or —R²⁸—COO⁻Z⁺; where R²⁸ is a direct bond, C₁-C₁₀-alkylene, C₂-C₄-alkenylene or C₆-C₁₀-arylene and Z⁺ is an alkali metal cation such as Na⁺, K⁺, Li⁺ or Rb⁺ or N(R¹⁴)₄⁺, with each R¹⁴ being independently of each other selected form hydrogen, phenyl, and C₁-C₂₀ alkyl, wherein two R¹⁴ substituents optionally form a ring; and Y⁻ is as defined above or has one of the preferred meanings given below.

According to a more specific aspect of this embodiment, A is a residue of the formula A.1.1a. According to an even more specific aspect of this embodiment, A is a residue of the formula A.1.1a, in which R³⁰, R³¹, R³², R³³, R³⁴, and R³⁵ are each hydrogen and R²⁹ is a residue G.

According to a particularly specific aspect of this embodiment, A is a residue of the formula A.1.1a,

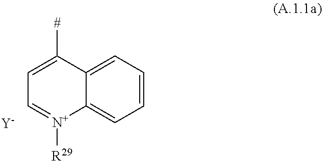

where
# denotes the point of attachment to the remainder of the molecule,
R²⁹ is —R²⁸—CONH—OH,
where R²⁸ is a direct bond, C₁-C₄-alkylene, C₂-C₄-alkenylene or phenylene;
Y⁻ is as defined above and has preferably one of the preferred meanings.

According to a further particularly specific aspect of this embodiment, A is a residue of the formula A.1.1a,

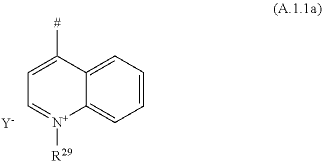

where
# denotes the point of attachment to the remainder of the molecule,
R²⁹ is —R²⁸—COOH or —R²⁸—COO⁻Z⁺,
where R²⁸ is a direct bond, C₁-C₄-alkylene, C₂-C₄-alkenylene or phenylene; and Z⁺ is N(R¹⁴)₄⁺, Li⁺, Na⁺ or K⁺;
R¹⁴ is hydrogen or C₁-C₂₀-alkyl; and
Y⁻ is as defined above and has preferably one of the preferred meanings.

Examples of preferred acceptors A are:

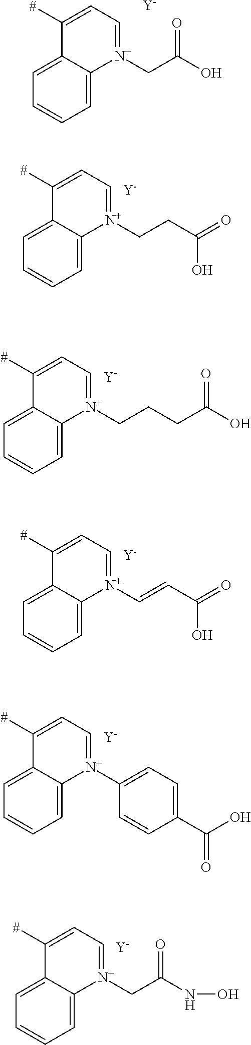

where # denotes the point of attachment to the remainder of the molecule and Y⁻ is as defined above and has preferably one of the preferred meanings.

In particular, in the residue of the formula A.1.1a, R²⁸ is C₁-C₄-alkylene, especially —CH₂— or —CH₂—CH₂—. R²⁹ is in particular R²⁸—COOH with R²⁸ being C₁-C₂-alkylene and r is as defined above and has preferably one of the preferred meanings.

A preferred aspect of the invention relates to an electrode layer sensitized with a compound of the formula (I), photoelectric conversion elements comprising said electrode layer, compounds of the formula (I) and their use, where in the compound of the formula (I) Y⁻ is an anion providing a conjugated π (“pi”)-electron system.

A conjugated π (“pi”)-electron system is a system of connected p-orbitals with delocalized electrons in compounds with alternating single and multiple bonds, which in general may lower the overall energy of the molecule and increase stability. Lone pairs, residues or carbenium ions may be part of the system. The respective compound may be cyclic or acyclic.

Preferred anions Y⁻ providing a conjugated π (“pi”)-electron system are:

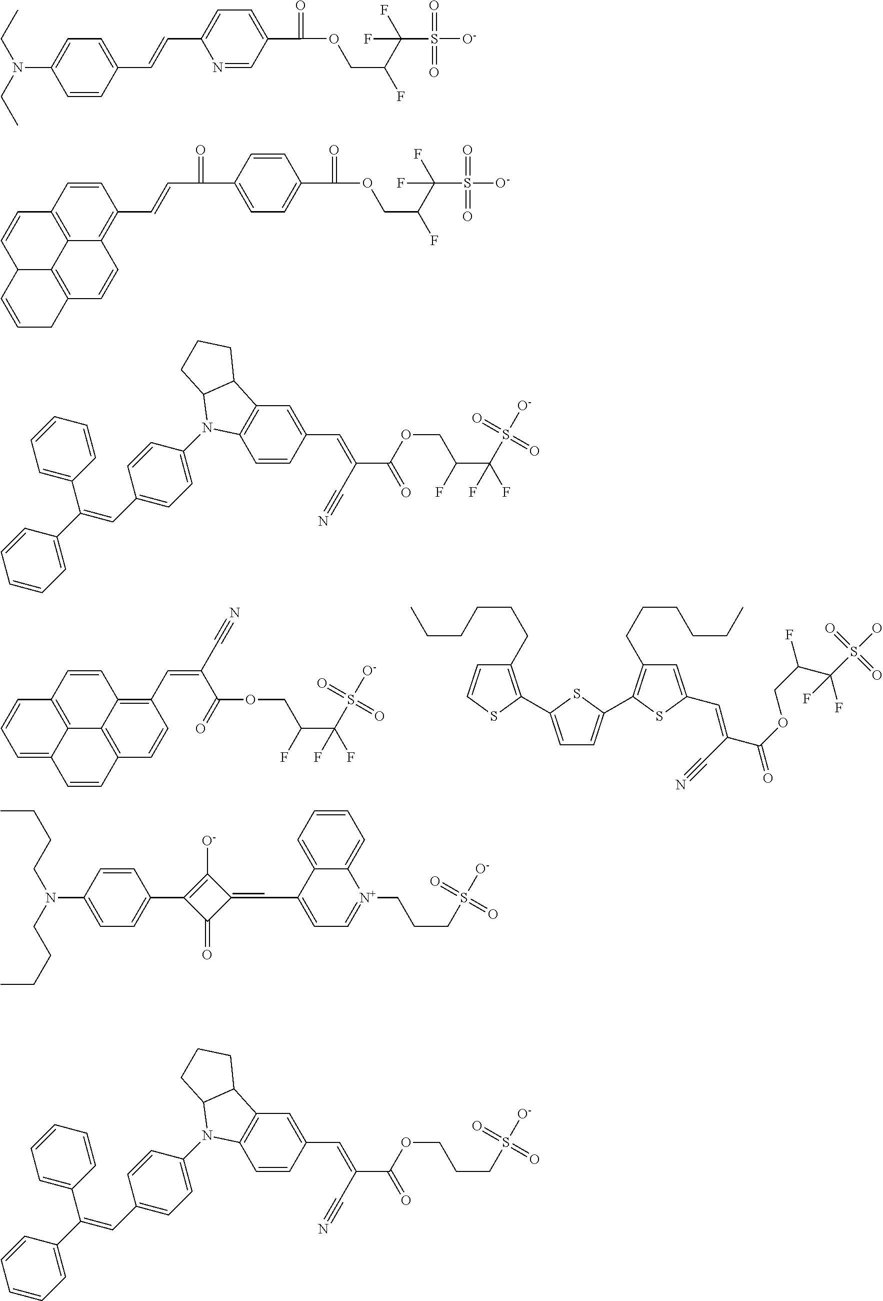

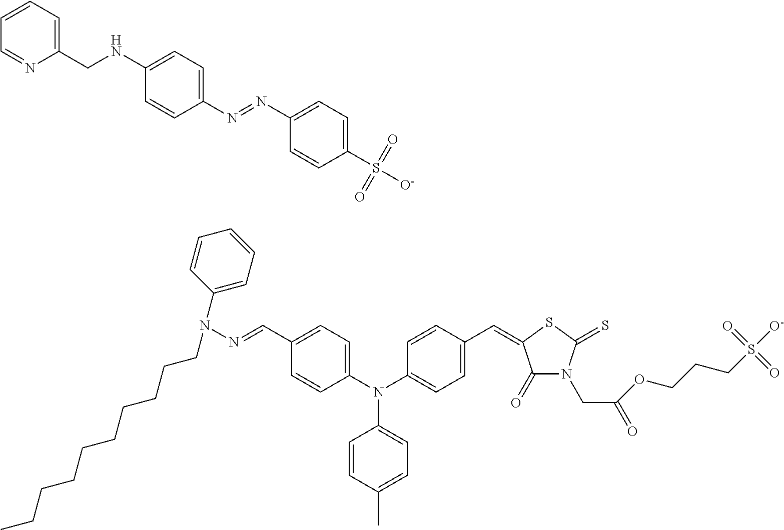 [SMILES: O=S(=O)([O-])c1ccc(/N=N/c2ccc(NCc3ccccn3)cc2)cc1 ; CCCCCCCCCCN(/N=C/c1ccc(N(c2ccc(C)cc2)c2ccc(/C=C3/SC(=S)N(CC(=O)OCCCS(=O)(=O)[O-])C3=O)cc2)cc1)c1ccccc1]

Another preferred aspect of the invention relates to an electrode layer sensitized with a compound of the formula (I), photoelectric conversion elements comprising said electrode layer, compounds of the formula (I) and their use, where in the compound of the formula (I), Y⁻ is a metal complex anion.

A metal complex anion is an anion comprising one or more metal cations, preferably one or more transition metal cations, and one or more ligands. Preferably the one or more transition metal cations are selected from the group consisting of Ru, Pt, Ir, Rh, Re, Os, Fe, W, Cr, Mo, Ni, Co, Mn, Zn, Cu and combinations thereof, more preferably selected from the group consisting of Ru, Os, Fe and combinations thereof, most preferred is Ru.

The one or more ligands are selected from the group of cationic ligands, anionic ligands, neutral ligands and combinations thereof so that the resulting metal complex anion bears a negative charge.

A preferred metal complex anion is described by the following formula:

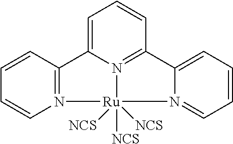

A further preferred aspect of the invention relates to an electrode layer sensitized with a compound of the formula (I), photoelectric conversion elements comprising said electrode layer, compounds of the formula (I) and the use, where in the compound of formula (I) Y⁻ is an anion comprising a moiety selected from the group consisting of —SO₃⁻, —COO⁻, —O—S(═O)₂O⁻, —P(═O)(OH)(O⁻), —P(═O)(OH)(O⁻) and —SCN⁻.

A further preferred aspect of the invention relates to an electrode layer sensitized with a compound of the formula (I), photoelectric conversion elements comprising said electrode layer, compounds of the formula (I) and their use, where in the compound of formula (I) Y⁻ is an anion of formula (II)

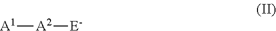

wherein
A¹ is a group providing a conjugated π (“pi”)-electron system;
A² is an unsubstituted alkyl chain having 1 to 24 carbon atoms or a substituted alkyl chain having 1 to 24 carbon atoms including substituents, wherein in said alkyl or substituted alkyl chain optionally one or more functional groups, in particular one or more ester groups, are located between respective C atoms;
E⁻ is a moiety selected from the group consisting of —SO₃⁻, —COO⁻, —O—S(═O)₂O⁻, —P(═O)(OH)(O⁻) and —P(═O)(OH)(O⁻).

A preferred aspect of the invention relates to an electrode layer sensitized with a compound of the formula (I), photoelectric conversion elements comprising said electrode layer, compounds of the formula (I) and their use, where in the compound of the formula (I) Y⁻ is an anion of formula (111)

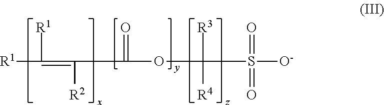

wherein
x, y are independently of each other selected from the group consisting of 0 and 1;
z is independently selected from the group consisting of 0, 1, 2, 3, 4, 5, 6, 7, 8 and 9;
R¹ is defined as in claim 1 with the proviso that at least one of R¹ is selected from the group consisting of unsubstituted C₁-C₂₀-alkyl wherein alkyl is uninterrupted or interrupted by O, S, CO, NR¹⁴ or combinations thereof, substituted C₁-C₂₀-alkyl wherein alkyl is uninterrupted or interrupted by O, S, CO, NR¹⁴ or combinations thereof, unsubstituted C₁-C₂₀-cycloalkyl wherein alkyl is uninterrupted or interrupted by O, S, CO, NR¹⁴ or combinations thereof, substituted C₁-C₂₀-cycloalkyl wherein alkyl is uninterrupted or interrupted by O, S, CO, NR¹⁴ or combinations thereof, unsubstituted C₆-C₂₀-aryl, substituted C₆-C₂₀-aryl, unsubstituted C₆-C₂₀-heteroaryl, substituted C₆-C₂₀-heteroaryl;
R² is independently of each other selected from the group consisting of H, NO₂, CN, COR′, COOR′, SO₂R′ and SO₃R′;
wherein each R′ is independently selected from the group consisting of unsubstituted aryl, substituted aryl, unsubstituted alkyl having 1 to 10 carbon atoms, substituted alkyl having 1 to 10 carbon atoms including substituents, unsubstituted cycloalkyl having 5 to 7 carbon atoms, and substituted cycloalkyl having 5 to 10 carbon atoms including substituents, wherein in said alkyl or cycloalkyl groups one oxygen atom or two nonadjacent oxygen atoms may be inserted between respective C atoms;
   R³, R⁴ are independently of each other selected from the group consisting of H, F, Cl, Br and I.

According to a preferred aspect of this invention, in formula (III) one or more of R¹ is annealed with one or more further aromatic rings or connected with one or more further aromatic or heteroaromatic rings through one atom or through a single bond, wherein each of the one or more further aromatic or heteroaromatic rings is independently of each other either unsubstituted or substituted.

Preferred compounds of formula (I) are:

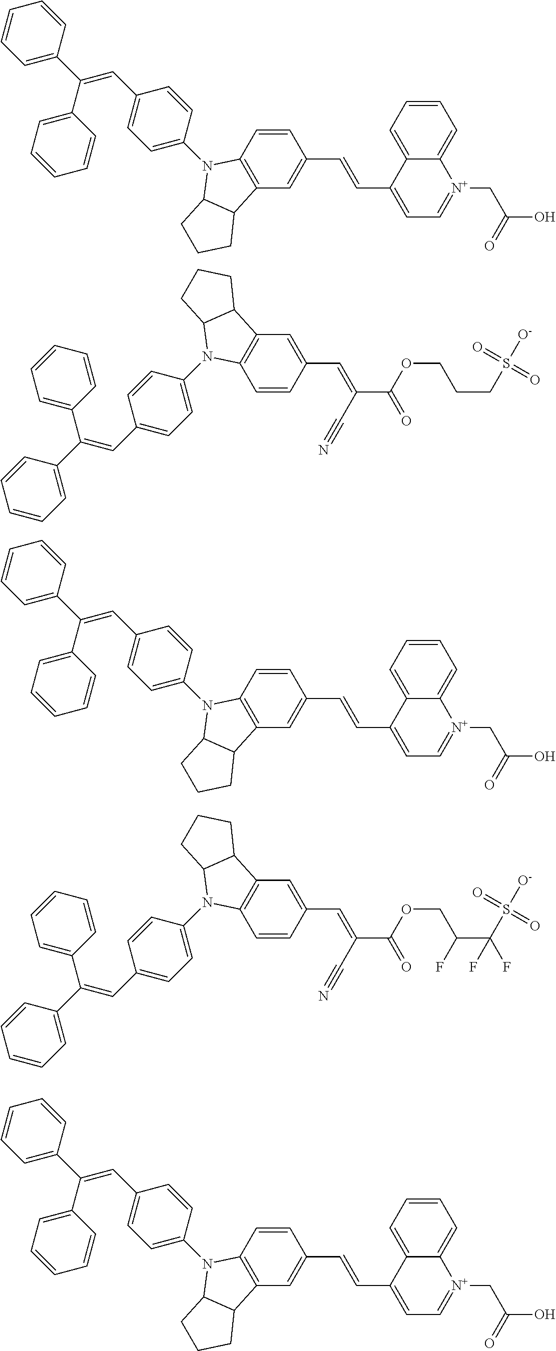 [SMILES: O=C(O)C[n+]1ccc(/C=C/c2ccc3c(c2)C2CCCC2N3c2ccc(C=C(c3ccccc3)c3ccccc3)cc2)c2ccccc21 ; N#C/C(=C\c1ccc2c(c1)C1CCCC1N2c1ccc(C=C(c2ccccc2)c2ccccc2)cc1)C(=O)OCCCS(=O)(=O)[O-] ; O=C(O)C[n+]1ccc(/C=C/c2ccc3c(c2)C2CCCC2N3c2ccc(C=C(c3ccccc3)c3ccccc3)cc2)c2ccccc21 ; N#C/C(=C\c1ccc2c(c1)C1CCCC1N2c1ccc(C=C(c2ccccc2)c2ccccc2)cc1)C(=O)OCC(F)C(F)(F)S(=O)(=O)[O-] ; O=C(O)C[n+]1ccc(/C=C/c2ccc3c(c2)C2CCCC2N3c2ccc(C=C(c3ccccc3)c3ccccc3)cc2)c2ccccc21]

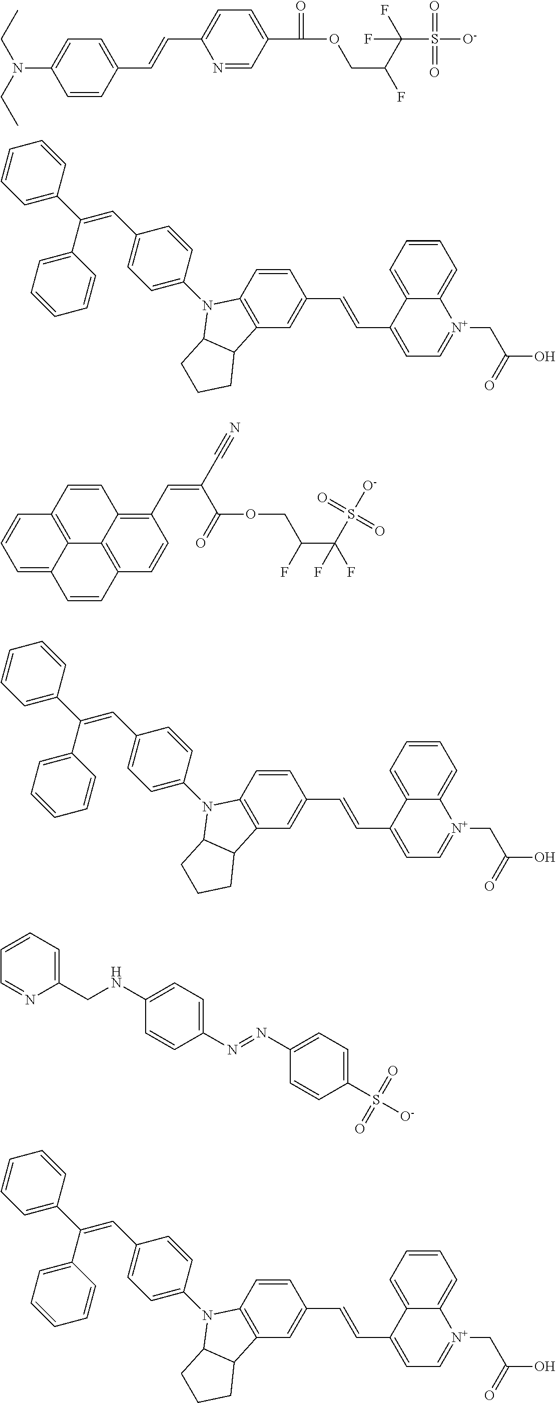 [SMILES: CCN(CC)c1ccc(/C=C/c2ccc(C(=O)OCC(F)C(F)(F)S(=O)(=O)[O-])cn2)cc1 ; O=C(O)C[n+]1ccc(/C=C/c2ccc3c(c2)C2CCCC2N3c2ccc(C=C(c3ccccc3)c3ccccc3)cc2)c2ccccc21 ; N#C/C(=C/c1ccc2ccc3cccc4ccc1c2c34)C(=O)OCC(F)C(F)(F)S(=O)(=O)[O-] ; O=C(O)C[n+]1ccc(/C=C/c2ccc3c(c2)C2CCCC2N3c2ccc(C=C(c3ccccc3)c3ccccc3)cc2)c2ccccc21 ; O=S(=O)([O-])c1ccc(/N=N/c2ccc(NCc3ccccn3)cc2)cc1 ; O=C(O)C[n+]1ccc(/C=C/c2ccc3c(c2)C2CCCC2N3c2ccc(C=C(c3ccccc3)c3ccccc3)cc2)c2ccccc21]

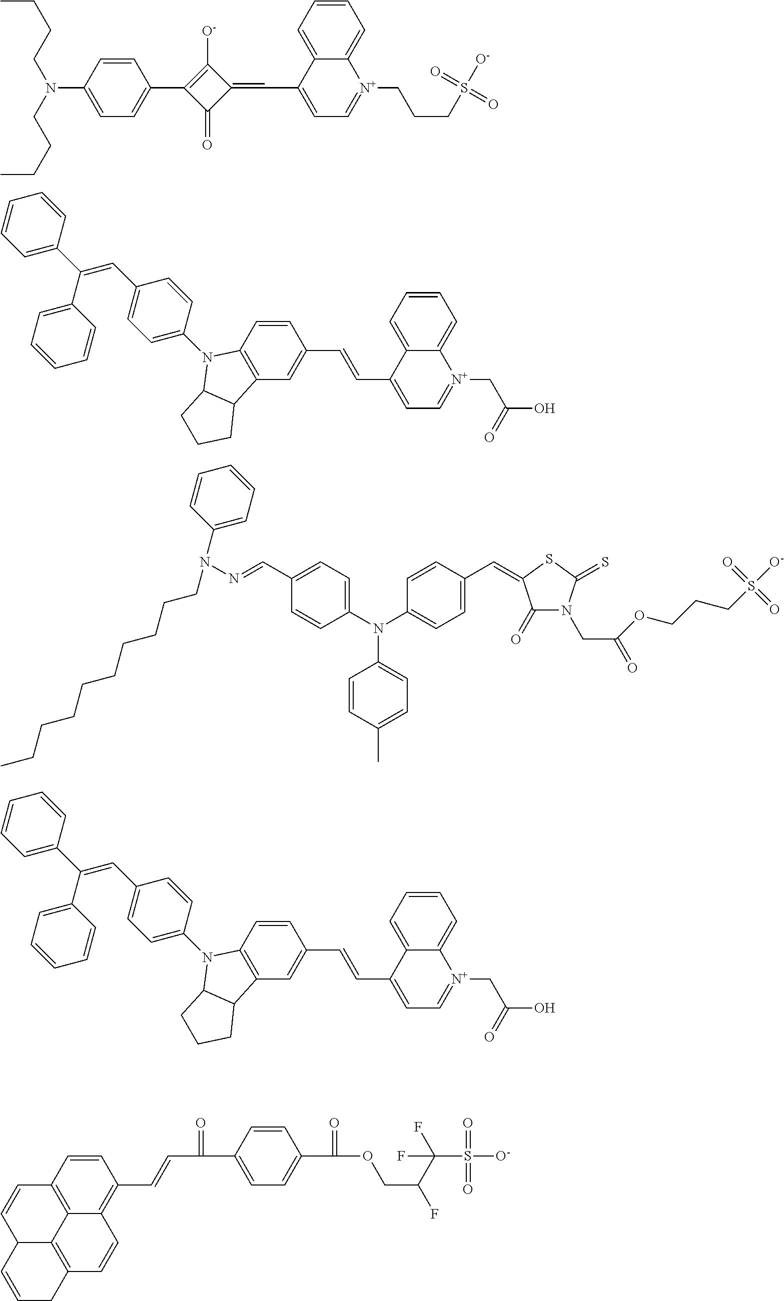 [SMILES: CCCCN(CCCC)c1ccc(C2=C([O-])C(=Cc3cc[n+](CCCS(=O)(=O)[O-])c4ccccc34)C2=O)cc1 ; O=C(O)C[n+]1ccc(/C=C/c2ccc3c(c2)C2CCCC2N3c2ccc(C=C(c3ccccc3)c3ccccc3)cc2)c2ccccc21 ; CCCCCCCCCCN(/N=C/c1ccc(N(c2ccc(C)cc2)c2ccc(/C=C3/SC(=S)N(CC(=O)OCCCS(=O)(=O)[O-])C3=O)cc2)cc1)c1ccccc1 ; O=C(O)C[n+]1ccc(/C=C/c2ccc3c(c2)C2CCCC2N3c2ccc(C=C(c3ccccc3)c3ccccc3)cc2)c2ccccc21 ; O=C(/C=C/c1ccc2c3c4c(ccc13)CC=CC4C=C2)c1ccc(C(=O)OCC(F)C(F)(F)S(=O)(=O)[O-])cc1]

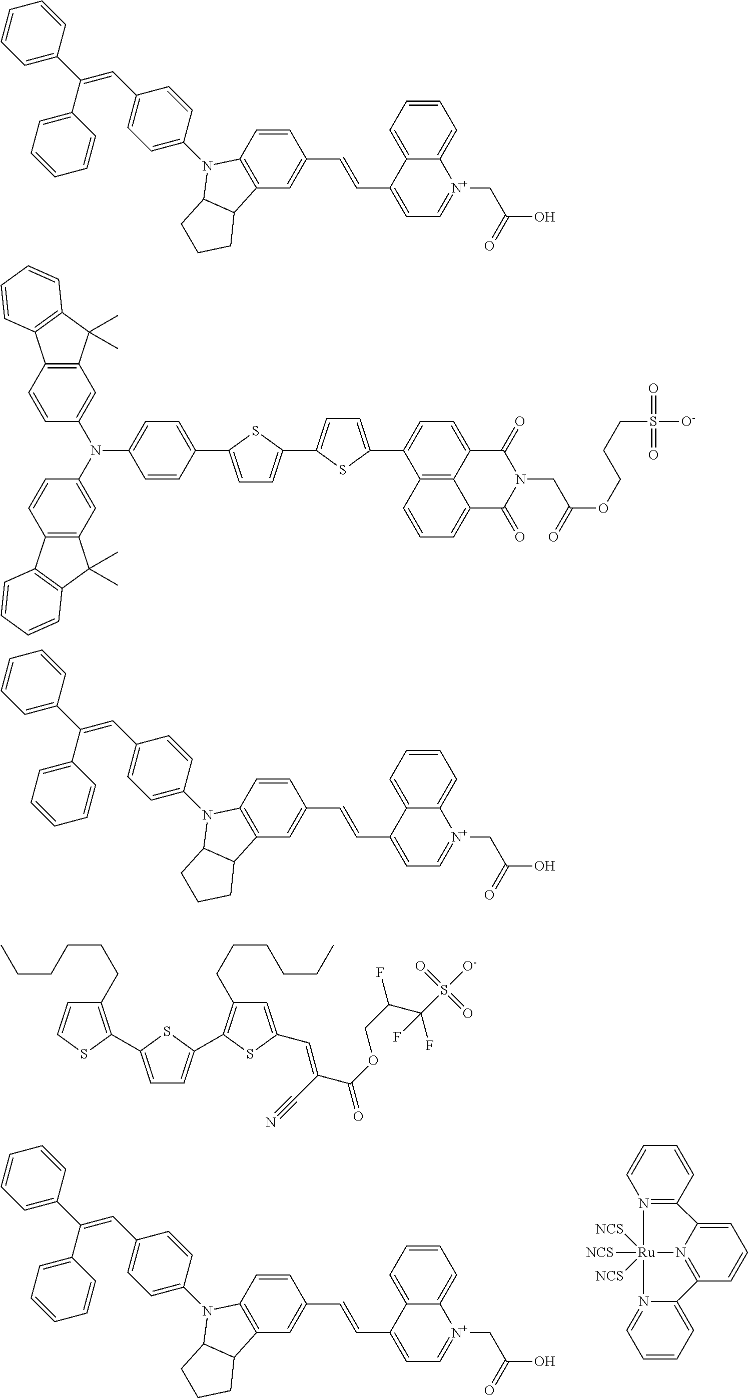

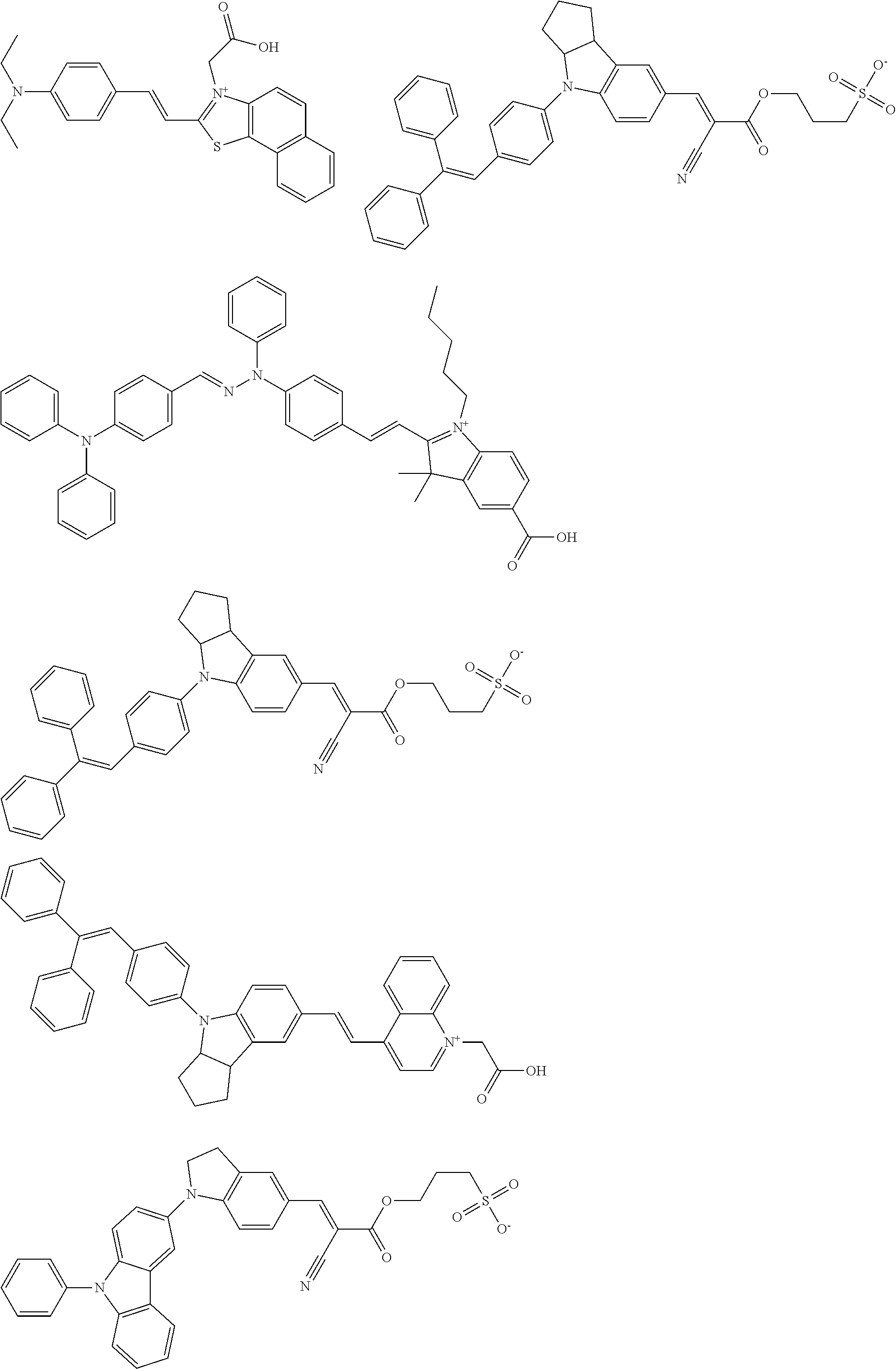 [SMILES: CCN(CC)c1ccc(/C=C/c2sc3c4ccccc4ccc3[n+]2CC(=O)O)cc1 ; N#C/C(=C\c1ccc2c(c1)C1CCCC1N2c1ccc(C=C(c2ccccc2)c2ccccc2)cc1)C(=O)OCCCS(=O)(=O)[O-] ; CCCCC[N+]1=C(/C=C/c2ccc(N(/N=C/c3ccc(N(c4ccccc4)c4ccccc4)cc3)c3ccccc3)cc2)C(C)(C)c2cc(C(=O)O)ccc21 ; N#C/C(=C\c1ccc2c(c1)C1CCCC1N2c1ccc(C=C(c2ccccc2)c2ccccc2)cc1)C(=O)OCCCS(=O)(=O)[O-] ; O=C(O)C[n+]1ccc(/C=C/c2ccc3c(c2)C2CCCC2N3c2ccc(C=C(c3ccccc3)c3ccccc3)cc2)c2ccccc21 ; N#C/C(=C\c1ccc2c(c1)CCN2c1ccc2c(c1)c1ccccc1n2-c1ccccc1)C(=O)OCCCS(=O)(=O)[O-]]

The compounds of the formula (I) can be prepared by condensation of the corresponding carbonyl compound and quinolinium, isoquinolinium, pyridinium, benzothiazolium, indolium, acridinium or benzoxazolium salt as described below or in the experimental part.

Scheme 1 illustrates the preparation of compounds of the formula (I), where n is zero or 1.

In case of n=0;

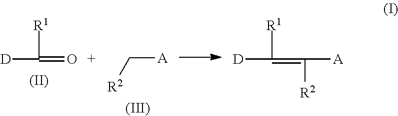

In case of n=1;

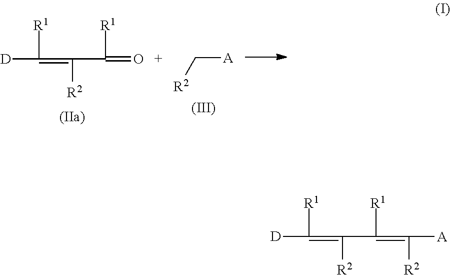

In scheme 1, D, A, R¹, R² and n are as defined above.

For instance, the reaction conditions of the condensation of the quaternary salts (III) with carbonyl compounds (II) or (IIa) are reflux in ethanol in the presence of piperidine or pyrrolidine (see for instance, J. Chem. Soc. 1961, 5074, Dyes & Pigments 2003, 58, 227), or heating in acetic anhydride (see for instance, Indian J. Chem. 1968, 6, 235.), or heating in acetic acid in a presence of ammonium acetate.

After condensation reactions, the counter anion can be placed from inorganic anion e.g. bromide via counter anion exchange reaction.

Before condensation, the group G may be protected. Then after the condensation reaction, the protection group can be removed. A group G comprising COOH or COO⁻Z⁺ can be protected by, for example, t-butyl group. Then after condensation reactions, the COO-t-butyl group can be converted into COOH or COO⁻Z⁺.

Compounds of formula (I) can also be prepared by condensation of the corresponding quinoline, isoquinoline, pyridine, benzothiazole, indole, acridine or benzoxazole derivatives with carbonyl compounds, followed by quaternization to the corresponding quinolinium, isoquinolinium, pyridinium, benzothiazolium, indolium, acridinium or benzoxazolium salt.

For instance, the starting materials are partly items of commerce or can be obtained according to methods known in the art.

The oxide semiconductor fine particles are, for instance, made of TiO₂, SnO₂, WO₃, ZnO, Nb₂O₅, Fe₂O₃, ZrO₂, MgO, WO₃, ZnO, CdS, ZnS, PbS, Bi₂S₃, CdSe, CdTe or combinations thereof. Preferably, the oxide semiconductor fine particles are made of TiO₂.

According to a specific aspect of this invention, the electrode layer comprises a dye of formula (I) or a mixture of dyes of formula (I) as the only dye(s).

Preferred is a porous film made of oxide semiconductor fine particles which is sensitized with a dye of formula (I) and one or more further dyes.

Examples of further dyes are metal complex dyes (preferably the metal is Ru, Pt, Ir, Rh, Re, Os, Fe, W, Cr, Mo, Ni, Co, Mn, Zn or Cu, more preferably Ru, Os or Fe, most preferably Ru) and/or organic dyes selected from the group consisting of indoline, coumarin, cyanine, merocyanine, hemicyanine, methin, azo, quinone, quinonimine, diketo-pyrrolo-pyrrole, quinacridone, squaraine, triphenylmethane, perylene, indigo, xanthene, eosin, rhodamine and combinations thereof. As further dyes, methine dye are preferred.

The molar ratio of a further dye, if present, to a dye of formula (I) usually is 1:19 to 19:1, preferably 1:9 to 9:1, more preferably 1:5 to 5:1, most preferably 1:3 to 3:1.

For example, the dye is adsorbed together with an additive, preferably a co-adsorbent.

Examples of such additives are co-adsorbents selected from the group consisting of a steroid (preferably deoxycholic acid, dehydrodeoxcholic acid, chenodeoxycholic acid, cholic acid methyl ester, cholic acid sodium salt or combinations thereof), a crown ether, a cyclodextrine, a calixarene, a polyethyleneoxide, hydroxamic acid, hydroxamic acid derivative and combinations thereof, especially hydroxamic acid and hydroxiamic acid derivative

The molar ratio of such an additive to a dye of formula (I) usually is 1000:1 to 1:100, preferably 100:1 to 1:10, most preferably 10:1 to 1:2.

For example, such an additive is not a dye.

The present invention also pertains to a photoelectric conversion device comprising an electrode layer as defined herein.

Such photoelectric conversion devices usually comprise

(a) a transparent conductive electrode substrate layer,
(b) an electrode layer comprising a porous film made of oxide semiconductor fine particles sensitized with
(c) a dye of formula (I),
(d) a counter electrode layer, and
(e) an electrolyte layer (e.g. filled between the working electrode layer b and the counter electrode layer d).

The component (c) can also be a combination of a dye of formula (I) and one or more further dyes.

Preferably, the transparent conductive electrode substrate layer (a) contains (e.g. consists of)

(a-1) a transparent insulating layer and
(a-2) a transparent conductive layer.

The transparent conductive layer (a-2) is usually between the transparent insulating layer (a-1) and the electrode layer (b).

Examples of the transparent insulating layer (a-1) include glass substrates of soda glass, fused quartz glass, crystalline quartz glass, synthetic quartz glass; heat resistant resin sheets such as a flexible film; metal sheets, transparent plastic sheets made of polyethylene terephthalate (PET), polyethylene naphthalate (PEN), polycarbonate (PC), polyether sulfone (PES); a polished plate of a ceramic, such as titanium oxide or alumina.

Examples of transparent conductive layer (a-2) are conductive metal oxides such as ITO (indium-tin compounded oxide), IZO (indium-zinc compounded oxide), FTO (fluorine-doped tin oxide), zinc oxide doped with boron, gallium or aluminum, and niobium-doped titanium oxide. The thickness of the transparent conductive layer (a-2) is usually 0.1 to 5 μm (micrometer). The surface resistance is usually below 40 ohms/sq, preferably below 20 ohms/sq.

To improve the conductivity of the transparent conductive layer (a-2), it is possible to form a metal wiring layer on it, made of for instance silver, platinum, aluminum, nickel or titanium. The area ratio of the metal wiring layer is generally within the range that does not significantly reduce the light transmittance of the transparent conductive electrode substrate layer (a). When such a metal wiring layer is used, the metal wiring layer may be provided as a grid-like, stripe-like, or comb-like pattern.

The electrode layer (b) is usually between the transparent conductive electrode substrate layer (a) and the electrolyte layer (e).

The porous film of oxide semiconductor fine particles of the electrode layer (b) can be prepared by a hydrothermal process, a sol/gel process or high temperature hydrolysis in gas phase. The fine particles usually have an average particle diameter of from 1 nm to 1000 nm. Particles with different size can be blended and can be used as either single or multi-layered porous film. The porous film of the oxide semiconductor layer (b) has usually a thickness of from 0.5 to 50 μm (micrometer).

If desired, it is possible to form a blocking layer on the electrode layer (b) (usually between the surface of the electrode layer (b) and the dye (c)) and/or between the electrode layer (b) and the transparent conductive electrode substrate layer (a) to improve the performance of the electrode layer (b). An example of forming a blocking layer is immersing the electrode layer (b) into a solution of metal alkoxides such as titanium ethoxide, titanium isopropoxide and titanium butoxide, chlorides such as titanium chloride, tin chloride and zinc chloride, nitrides and sulfides and then drying or sintering the substrate. For instance, the blocking layer is made of a metal oxide (e.g. TiO₂, SiO₂, Al₂O₃, ZrO₂, MgO, SnO₂, ZnO, Eu₂O₃, and Nb₂O₅ or combinations thereof) or a polymer (e.g. poly(phenylene oxide-co-2-allylphenylene oxide) or poly(methylsiloxane)). Details of the preparation of such layers are described in, for example, Electrochimica Acta, 1995, 40, 643; J. Phys. Chem. B, 2003, 107, 14394; J. Am. Chem. Soc., 2003, 125, 475; Chem. Lett, 2006, 35, 252; J. Phys. Chem. B, 2006, 110, 19191; J. Phys. Chem. B, 2001, 105, 1422. The blocking layer may be applied to prevent undesired reaction. The blocking is usually dense and compact, and is usually thinner than the electrode layer (b).

Preferably, the counter electrode layer (d) contains (e.g. consists of)

(d-1) a conductive layer and
(d-2) an insulating layer.

The conductive layer (d-1) is usually between the insulating layer (d-2) and the electrolyte layer (e).

For instance, the conductive layer (d-1) contains a conductive carbon (e.g. graphite, single walled carbon nanotubes, multiwalled carbon nanotubes, carbon nanofibers, carbon fibers, graphene or carbon black), a conductive metal (e.g. gold or platinum), a metal oxide (e.g. ITO (indium-tin compounded oxide), IZO (indium-zinc compounded oxide), FTO (fluorine-doped tinoxide), zinc oxide doped with boron, gallium or aluminum, and niobium-doped titanium oxide) or mixtures thereof.

Furthermore, the conductive layer (d-1) may be one obtained by forming a layer of platinum, carbon or the like (generally with a thickness of from 0.5 to 2,000 nm), on a thin film of a conductive oxide semiconductor, such as ITO, FTO, or the like (generally with a thickness of from 0.1 to 5 μm (micrometer)). The layer of platinum, carbon or the like is usually between the electrolyte layer (e) and the insulating layer (d-2).

Examples of the insulating layer (d-2) includes glass substrates of soda glass, fused quartz glass, crystalline quartz glass, synthetic quartz glass; heat resistant resin sheets such as a flexible film; metal sheets, transparent plastic sheets made of polyethylene terephthalate (PET), polyethylene naphthalate (PEN), polycarbonate (PC), polyether sulfone (PES); a polished plate of a ceramic, such as titanium oxide or alumina.

The dye (c) is usually disposed on the electrode layer (b) on that surface of the electrode layer (b) facing the electrolyte layer (e).

For adsorption of the dye (c) to the electrode layer (b), the electrode layer (b) may be immersed into a solution or a dispersion liquid of the dye. A concentration of the dye solution or dye dispersion liquid is not limited to, but preferably from 1 μM (micromol) to 1 M, and is preferably 10 μM (micromol) to 0.1 M. The time period for the dye adsorption is preferably from 10 seconds to 1000 hours or less, more preferably from 1 minute to 200 hours or less, most preferably from 1 to 10 hours. The temperature for dye adsorption is preferably from room temperature to the boiling temperature of the solvent or the dispersion liquid. The adsorption may be carried out dipping, immersing or immersing with stirring. As the stirring method, a stirrer, supersonic dispersion, a ball mill, a paint conditioner, a sand mill or the like is employed, while the stirring method shall not be limited thereto.

The solvent for dissolving or dispersing the dye (c) includes water, alcohol solvents such as methanol, ethanol, isopropyl alcohol, t-butyl alcohol, ethylene glycol and propylene glycol, ether solvents such as dioxane, diethyl ether, dimethoxyethane, tetrahydrofuran, dioxolane, t-butyl methyl ether, ethylene glycol dialkyl ether, propylene glycol monomethyl ether acetate and propylene glycol methyl ether, ketone solvents such as acetone, amide solvents such as N,N-dimethylformamide, N,N-dimethylacetamide and N-methylpyrrolidone, nitrile solvents such as acetonitrile, methoxy acetonitrile, methoxy propionitrile, propionitrile and benzonitrile, carbonate solvents such as ethylene carbonate, propylene carbonate and diethyl carbonate, heterocyclic compounds such as 3-methyl-2-oxazolidinone, dimethyl sulfoxide, sulfolane and gamma-butyrolactone, halogenated hydrocarbon solvents such as dichloromethane, chloroform, dichloroethane, trichloroethane, trichloroethylene, chlorobenzene, o-dichlorobenzene, 1-chloronaphthalene, bromoform, bromobenzene, methyl iodide, iodobenzene and fluorobenzene and hydrocarbon solvents such as benzene, toluene, o-xylene, m-xylene, p-xylene, ethylbenzene, cumene, n-pentane, n-hexane, n-octane, cyclohexane, methylcyclohexane, 1,5-hexadiene and cyclohexadiene. These may be used solely or in the form of a mixture containing two or more solvents. As a solvent, supercritical solvent such as supercritical carbon dioxide may be used.

As dye (c) a dye of formula (I) may be adsorbed on the electrode layer (b) solely or in combination with one or more further dyes. The dyes adsorbed together are not limited to dyes of formula (I). Two or more dyes may be adsorbed on the electrode layer (b) one by one or all together by dissolving the dyes in a solvent. It is preferable to use the dyes with different absorption peaks in different wavelengths to absorb wide range of light wavelengths and generate higher current. The ratio of two or more dyes adsorbed on the electrode layer (b) is not limited but preferably each dye has molar ratio of more than 10%.

For adsorption of the dye (c), an additive may be used in combination. The additive may be any one of an agent that has a function presumably for controlling dye adsorption. The additive includes a condensation agent such as thiol or a hydroxyl compound and a co-adsorbent. These may be used solely or a mixture of them. The molar ratio of the additive to the dye is preferably 0.01 to 1,000, more preferably 0.1 to 100.

For instance, the dye-adsorbed electrode layer may be treated with amines such as 4-tert-butyl pyridine. As a treatment method, immersing the dye-sensitized electrode layer into amine solution which may be diluted with a solvent such as acetonitrile or ethanol can be employed.

In the above manner, the electrode layer of the present invention can be obtained.

When the electrolyte layer (e) is in the form of solution, quasi-solid or solid, the electrolyte layer (e) usually contains,

(e-1) electrolyte compound,
(e-2) solvent and/or ionic liquid, and
preferably (e-3) other additives.

Examples of the electrolyte compound (e-1) include a combination of a metal iodide such as lithium iodide, sodium iodide, potassium iodide, cesium iodide or calcium iodide with iodine, a combination of a quaternary ammonium iodide such as tetraalkylammonium iodide, pyridium iodide or imidazolium iodide with iodine, a combination of a metal bromide such as lithium bromide, sodium bromide, potassium bromide, cesium bromide or calcium bromide with bromine, a combination of a quaternary ammonium bromide such as tetraalkylammonium bromide or pyridinium bromide with bromine, metal complexes such as ferrocyanic acid salt-ferricyanic acid salt or ferrocene-ferricynium ion, sulfur compounds such as sodium polysulfide and alkylthiolalkyldisulfide, a viologen dye, hydroquinone-quinone and a combination of a nitroxide residue such as 2,2,6,6-tetramethyl-1-piperidinyloxy (TEMPO) and oxoammonium salt. It is possible to prepare electrolyte compounds (e-1) by partially converting nitroxide residue into the oxoammonium salt in situ by adding oxidizing agent (e.g. NOBF₄).

The above electrolyte compounds (e-1) may be used solely or in the form of a mixture. As an electrolyte compound (e-1), there may be used a molten salt that is in a molten state at room temperature. When such a molten salt is used, particularly, it is not necessary to use a solvent.

The electrolyte compound (e-1) concentration in the electrolyte solution is preferably 0.05 to 20 M, more preferably 0.1 to 15 M.

For instance, the solvent (e-2) is nitrile solvents such as acetonitrile, methoxy acetonitrile, methoxy propionitrile, propionitrile and benzonitrile, carbonate solvents such as ethylene carbonate, propylene carbonate and diethyl carbonate, alcohol solvents such as methanol, ethanol, isopropyl alcohol, t-butyl alcohol, ethylene glycol and propylene glycol, ether solvents such as dioxane, diethyl ether, dimethoxyethane, tetrahydrofuran, dioxolane, t-butyl methyl ether, ethylene glycol dialkyl ether, propylene glycol monomethyl ether acetate and propylene glycol methyl ether, water, ketone solvents such as acetone, amide solvents such as N,N-dimethylformamide, N,N-dimethylacetamide and N-methylpyrrolidone, heterocyclic compounds such as 3-methyl-2-oxazolidinone, dimethyl sulfoxide, sulfolane and gamma-butyrolactone, halogenated hydrocarbon solvents such as dichloromethane, chloroform, dichloroethane, trichloroethane, trichloroethylene, chlorobenzene, o-dichlorobenzene, 1-chloronaphthalene, bromoform, bromobenzene, methyl iodide, iodobenzene and fluorobenzene and hydrocarbon solvents such as benzene, toluene, o-xylene, m-xylene, p-xylene, ethylbenzene, cumene, n-pentane, n-hexane, n-octane, cyclohexane, methylcyclohexane, 1,5-hexadiene and cyclohexadiene or combinations of the above mentioned solvents and the ionic liquid is a quaternary imidazolium salt, a quaternary pyridinium salt, a quaternary ammonium salt or combinations thereof, preferably the anion of the salt is BF₄⁻, PF₆⁻, F(HF)₂⁻, F(HF)₃⁻, bis(trifluoromethanesulfonyl)imide [(CF₃SO₂)₂N⁻], N(CN)₂⁻, C(CN)₃⁻, B(CN)₄⁻, SCN⁻, SeCN⁻, I⁻, IO₃⁻ or combinations thereof.

For example, a photoelectric conversion device comprises a solvent (e.g. without an ionic liquid). For instance, a photoelectric conversion device comprises an ionic liquid (e.g. without a solvent).

Examples of further additives (e-3) are lithium salts (especially 0.05 to 2.0 M, preferably 0.1 to 0.7 M) (e.g. LiClO₄, LiSO₃CF₃ or Li(CF₃SO₂)N); pyridines (especially 0.005 to 2.0 M, preferably 0.02 to 0.7M) (e.g. pyridine, tert-butylpyridine or polyvinylpyridine), gelling agents (especially 0.1 to 50 wt. %, preferably 1.0 to 10 wt. % based on the weight of the component e) (e.g. polyvinylidene fluoride, polyvinylidene fluoride-hexafluoropropylene copolymer, polyethylene oxide derivatives, polyacrylonitrile derivatives or amino acid derivatives), nano particles (especially 0.1 to 50 wt. %, preferably 1.0 to 10 wt. % based on the weight of the component e) (e.g. conductive nano particles, in particular single-wall carbon nanotubes, multi-wall carbon nanotubes or combinations thereof, carbon fibers, carbon black, polyaniline-carbon black composite TiO₂, SiO₂ or SnO₂); and combinations thereof.

In the present invention, an inorganic solid compound such as CuI, CuSCN, CuInSe₂, Cu(In,Ga)Se₂, CuGaSe₂, Cu₂O, CuS, CuGaS₂, CuInS₂, CuAlSe₂, GaP, NiO, CoO, FeO, Bi₂O₃, MoO₂, Cr₂O₃, CsSnI₃ or the like, an organic hole-transporting material or an electron-transporting material can be used in place of the electrolyte layer (e). Examples of organic hole-transporting materials are p-type semiconductors based on polymers such as polythiophene and polyaryl amines, or on amorphous, reversibly oxidizable nonpolymeric organic compounds such as the spirobifluorenes. These solid p-type semiconductors may be used both in the undoped and doped form. These compounds may be used alone or in admixture of two or more.

The instant electrode layer, photoelectric conversion devices and DSC can be prepared as outlined in U.S. Pat. No. 4,927,721, U.S. Pat. No. 5,084,365, U.S. Pat. No. 5,350,644 and U.S. Pat. No. 5,525,440 or in analogy thereto.

The present invention also refers to a dye sensitized solar cell comprising a photoelectric conversion device as described herein.

Moreover, the present invention relates to an organic electronic device, in particular an organic light-emitting diode (OLED) or an organic field-effect transistor (OFET), comprising a photoelectric conversion device as described herein.

The present invention also refers to the use of a compound of formula (I) as defined herein as a dye in a dye sensitized solar cell.

The present invention further refers to a compound of formula (I) as defined herein. Preferred compounds of formula (I) have the preferred structures as described above.

The present invention is now illustrated in further detail by the following examples. However, the purpose of the following examples is only illustrative and is not intended to limit the present invention to them.

### EXAMPLE A-1

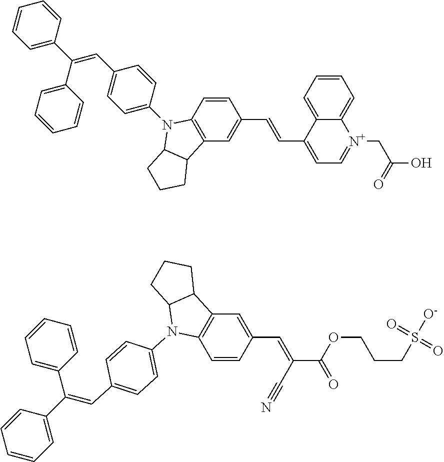 [SMILES: O=C(O)C[n+]1ccc(/C=C/c2ccc3c(c2)C2CCCC2N3c2ccc(C=C(c3ccccc3)c3ccccc3)cc2)c2ccccc21 ; N#C/C(=C\c1ccc2c(c1)C1CCCC1N2c1ccc(C=C(c2ccccc2)c2ccccc2)cc1)C(=O)OCCCS(=O)(=O)[O-]]

### A-1-1:

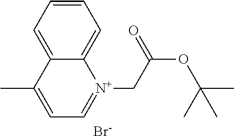 [SMILES: Cc1cc[n+](CC(=O)OC(C)(C)C)c2ccccc12 ; [Br-]]

7.17 g (50.1 mmol) of 4-methylquinoline and 10.4 ml (70.4 mmol) of t-butyl bromoacetate were added to 150 ml of toluene and stirred overnight at 80° C. under N₂. The precipitate was collected by filtration, washed by toluene and dried, yielding 13.6 g of the title compound of example A-1-1 as beige solid. The crude was used without further purification in the next step.

### A-1-2:

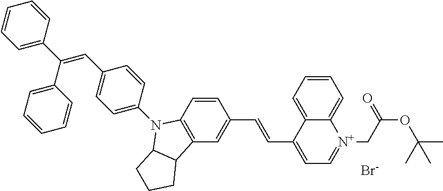 [SMILES: CC(C)(C)OC(=O)C[n+]1ccc(/C=C/c2ccc3c(c2)C2CCCC2N3c2ccc(C=C(c3ccccc3)c3ccccc3)cc2)c2ccccc21 ; [Br-]]

2.35 g (5.33 mmol) of 4-[4-(2,2-diphenylethenyl)phenyl]-1,2,3,3a,4,8b-hexahydro-cyclopent[b]indole-7-carboxaldehyde and 1.80 g (5.33 mmol) of example A-1-1 were added to 30 ml of acetic anhydride and stirred overnight at 80° C. under N₂. The solvent was removed under vacuum. The residue was purified by flash chromatography on silica gel with CH₂Cl₂ and methanol (10:1) as eluent, yielding 3.76 g (4.93 mmol; 93%) of the title compound of example A-1-2 as a blue solid. The structure is confirmed by the ¹H-NMR spectrum (CDCl₃). δ [ppm]: 1.47 (s, 9H), 1.63-2.20 (m, 6H), 3.87 (t, 1H), 4.92 (t, 1H), 5.95 (s, 2H), 6.94 (t, 2H), 7.02-7.11 (m, 4H), 7.24-7.45 (m, 7H), 7.56-7.87 (m, 11H), 8.01 (t, 1H), 8.08 (t, 1H), 8.60 (t, 1H), 10.03 (d, 1H).

### A-1-3:

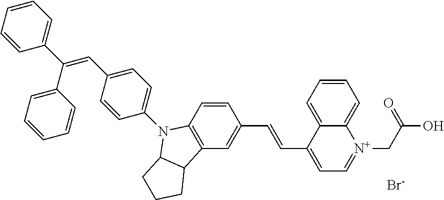 [SMILES: O=C(O)C[n+]1ccc(/C=C/c2ccc3c(c2)C2CCCC2N3c2ccc(C=C(c3ccccc3)c3ccccc3)cc2)c2ccccc21 ; [Br-]]

4.78 g (6.27 mmol) of example A-1-2 was dissolved in 30 ml of CH₂Cl₂. To the solution was added dropwise 60 ml of mixture of trifluoroacetic acid and CH₂Cl₂ (1:1) with cooled by an ice bath. The reaction mixture was stirred at r.t. for 3 hours. The solvent was removed under vacuum. The residue was purified by flash chromatography on silica gel with CH₂Cl₂ and methanol (5:1) as eluent, yielding 3.25 g (4.61 mmol: 74%) of the title compound of example A-1-3 as a blue solid. The structure is confirmed by the ¹H-NMR spectrum (DMSO-d₆). δ [ppm]: 1.25-2.12 (m, 6H), 3.84 (t, 1H), 4.96 (t, 1H), 5.78 (s, 2H), 6.95-7.60 (m, 17H), 7.90-8.25 (m, 6H), 8.40 (d, 1H), 9.03-9.10 (m, 2H).

### A-1-4:

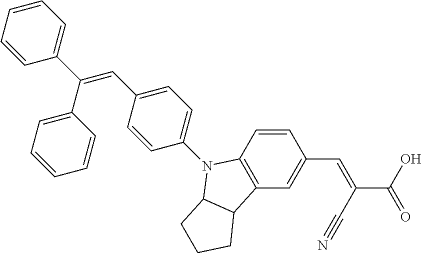 [SMILES: N#C/C(=C\c1ccc2c(c1)C1CCCC1N2c1ccc(C=C(c2ccccc2)c2ccccc2)cc1)C(=O)O]

1.32 g (3 mmol) of 4-[4-(2,2-diphenylethenyl)phenyl]-1,2,3,3a,4,8b-hexahydro-cyclopent[b]indole-7-carboxaldehyde, 0.77 g (9 mmol) of cyanoacetic acid were added to 20 ml of acetonitrile. To the mixture 5 drops of piperidine was added and stirred overnight with reflux under N₂. The reaction mixture was poured into water, giving a precipitate. The precipitate was collected by filtration and washed by water. The solid was dried and purified by flash chromatography on silica gel with CH₂Cl₂ and methanol (10:1) as eluent, yielding 1.42 g (2.8 mmol: 92%) of the title compound of example A-1-4 as an orange solid. The structure is confirmed by the ¹H-NMR spectrum (CDCl₃). δ [ppm]: 1.40-2.13 (m, 6H), 3.82 (t, 1H), 4.90 (t, 1H), 6.82 (d, 1H), 6.95 (s, 1H), 7.02-7.40 (m, 14H), 7.60 (d, 1H), 7.98 (s, 1H), 8.06 (s, 1H).

### A-1-5:

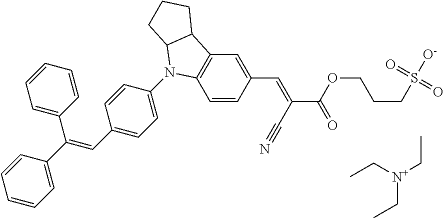

3.32 g (6 mmol) of example A-1-4, 2.20 g (18 mmol) of propanesultone and 0.73 g (7.2 mmol) of triethylamine were added to 100 ml of dry acetonitrile, and stirred overnight with reflux under N₂. The solvent was removed under vacuum. The residue was purified by flash chromatography on silica gel with CH₂Cl₂ and methanol (5:1) as eluent, yielding 2.97 g (4.1 mmol; 68%) of the title compound of example A-1-5 as a reddish orange solid. The structure is confirmed by the ¹H-NMR spectrum (DMSO-d₆). δ [ppm]: 1.14 (t, 9H), 1.25-2.10 (m, 8H), 3.81 (t, 1H), 4.27 (t, 2H), 5.01 (t, 1H), 6.88 (d, 1H), 7.02-7.48 (m, 15H), 7.75 (d, 1H), 7.91 (s, 1H), 8.08 (s, 1H).

### A-1:

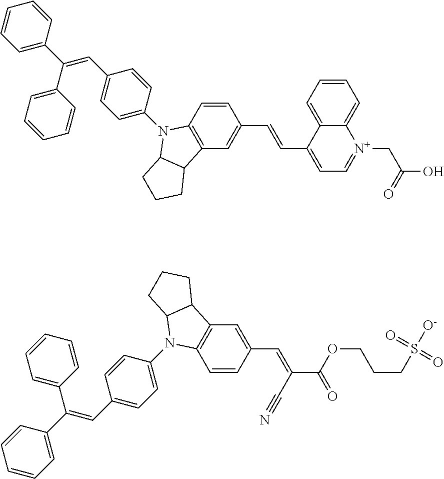 [SMILES: O=C(O)C[n+]1ccc(/C=C/c2ccc3c(c2)C2CCCC2N3c2ccc(C=C(c3ccccc3)c3ccccc3)cc2)c2ccccc21 ; N#C/C(=C\c1ccc2c(c1)C1CCCC1N2c1ccc(C=C(c2ccccc2)c2ccccc2)cc1)C(=O)OCCCS(=O)(=O)[O-]]

212 mg (0.3 mmol) of example A-1-3 and 146 mg (0.2 mmol) of example A-1-5 were added to 20 ml of CH₂Cl₂ and stirred at r.t. for 30 min. To the solution 20 ml of 1N HCl was added and vigorously stirred at r.t. for 1 hour. The CH₂Cl₂ was removed under vacuum, giving a precipitate. The precipitate was collected by filtration and washed by water and dried under vacuum, yielding 240 mg (0.19 mmol; 95%) of the title compound of example A-1 as a dark blue solid. The structure is confirmed by the ¹H-NMR spectrum (DMSO-d₆). δ [ppm]: 1.25-2.10 (m, 14H), 3.77-3.91 (m, 2H), 4.27 (t, 2H), 4.95-5.05 (m, 2H), 5.78 (s, 2H), 6.86-8.23 (m, 39H), 8.38 (d, 1H), 9.03-9.08 (m, 2H). Solution spectrum of example A-1 is measured in ethanol between 350 nm to 900 nm and three peaks are observed. Following are peak position, λₚₑₐₖ, and extinction coefficient, ε, of each peaks: Abs.1(582 nm, 51600M⁻¹cm⁻¹), Abs.2(373 nm, 31300M⁻¹cm⁻¹), Abs.3(459 nm, 52500M⁻¹cm⁻¹)

### EXAMPLES A-2 TO A-14

The compounds of examples A-2 to A-14 are obtained according to the method described in example A-1, using the corresponding educts. Reference compound Ref-1 is obtained according to the method described in example A-1-3. The structures and physical data of products are listed in Table 1.

TABLE 1

| Exam | | |
|---|---|---|
| ple | Structure | Physical properties |
| A-2 | 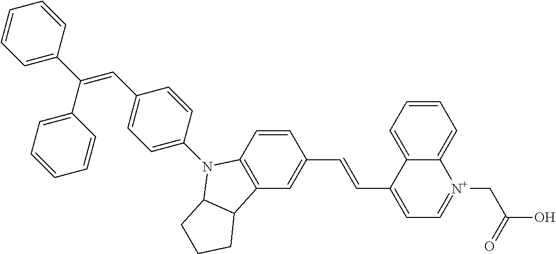 [SMILES: O=C(O)C[n+]1ccc(/C=C/c2ccc3c(c2)C2CCCC2N3c2ccc(C=C(c3ccccc3)c3ccccc3)cc2)c2ccccc21] 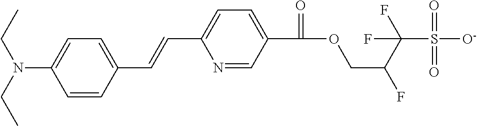 [SMILES: CCN(CC)c1ccc(/C=C/c2ccc(C(=O)OCC(F)C(F)(F)S(=O)(=O)[O-])cn2)cc1] | ¹H-NMR spectrum (DMSO-d₆). δ [ppm]: 1.08 (t, 6H), 1.23-2.12 (m, 6H), 3.83 (t, 1H), 4.50-4.62 (m, 1H), 4.81-5.00 (m, 2H), 5.20-5.43 (m, 1H), 5.52 (s, 2H), 6.65-8.38 (m, 32H), 8.98- 9.08 (m, 3H), 4H hidden by H₂O signal around 3.3. Abs (λₚₑₐₖ, ε) Abs. 1 (584 nm, 61500M⁻¹cm⁻¹) Abs. 2 (374 nm, 38200M⁻¹cm⁻¹) |
| A-3 | 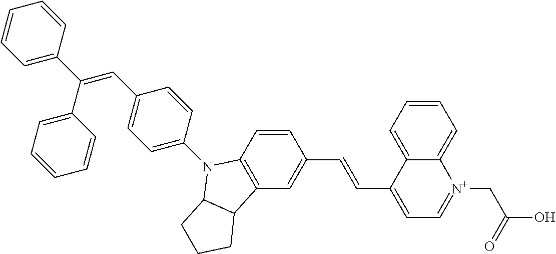 [SMILES: O=C(O)C[n+]1ccc(/C=C/c2ccc3c(c2)C2CCCC2N3c2ccc(C=C(c3ccccc3)c3ccccc3)cc2)c2ccccc21] 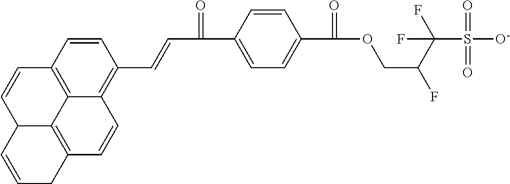 [SMILES: O=C(/C=C/c1ccc2c3c4c(ccc13)CC=CC4C=C2)c1ccc(C(=O)OCC(F)C(F)(F)S(=O)(=O)[O-])cc1] | ¹H-NMR spectrum (DMSO-d₆). δ [ppm]: 1.25-2.10 (m, 6H), 3.85 (t, 1H), 4.52-4.68 (m, 1H), 4.88-5.02 (m, 2H), 5.24-5.45 (m, 1H), 5.76 (s, 2H), 6.95- 7.60 (m, 15H), 7.90- 8.40 (m, 19H), 8.63 (d, 1H), 8.83 (d, 1H), 8.91(d, 1H), 9.02- 9.09 (m, 2H). Abs. (λₚₑₐₖ, ε) in DCM Abs. 1 (655 nm, 40600M⁻¹cm⁻¹) Abs. 2 (385 nm, 29100M⁻¹cm⁻¹) |
| A-4 | 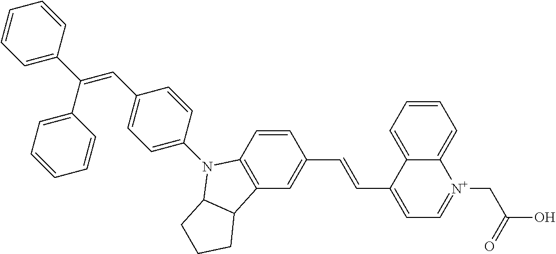 [SMILES: O=C(O)C[n+]1ccc(/C=C/c2ccc3c(c2)C2CCCC2N3c2ccc(C=C(c3ccccc3)c3ccccc3)cc2)c2ccccc21] 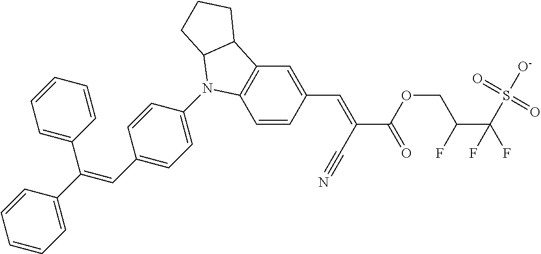 [SMILES: N#C/C(=C\c1ccc2c(c1)C1CCCC1N2c1ccc(C=C(c2ccccc2)c2ccccc2)cc1)C(=O)OCC(F)C(F)(F)S(=O)(=O)[O-]] | ¹H-NMR spectrum (DMSO-d₆). δ [ppm]: 1.23-2.10 (m, 12H), 3.78-3.92 (m, 2H), 4.40-4.53 (m, 1H), 4.75-4.90 (m, 1H), 4.95-5.06 (m, 2H), 5.10-5.32 (m, 1H), 5.70 (s, 2H), 6.85-8.22 (m, 42H), 8.39 (d, 1H), 9.03- 9.08 (m, 2H). Abs. (λₚₑₐₖ, ε, Abs. 1 (577 nm, 40900M⁻¹ cm⁻¹) Abs. 2 (370 nm, 27100M⁻¹cm⁻¹) Abs. 3 (461 nm, 57500M⁻¹cm⁻¹) |
| A-5 | 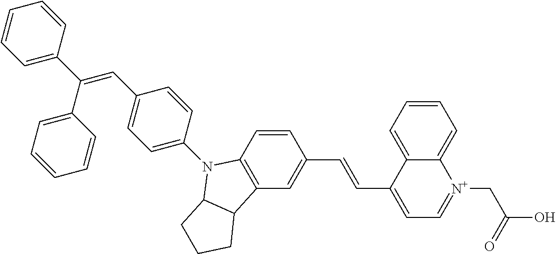 [SMILES: O=C(O)C[n+]1ccc(/C=C/c2ccc3c(c2)C2CCCC2N3c2ccc(C=C(c3ccccc3)c3ccccc3)cc2)c2ccccc21] 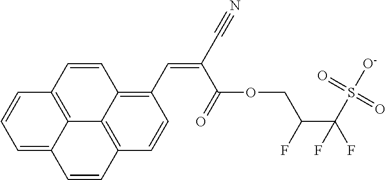 [SMILES: N#C/C(=C/c1ccc2ccc3cccc4ccc1c2c34)C(=O)OCC(F)C(F)(F)S(=O)(=O)[O-]] | ¹H-NMR spectrum (DMSO-d₆). δ [ppm]: 1.28-2.12 (m, 6H), 3.88 (t, 1H), 4.57-4.70 (m, 1H), 4.93-5.08 (m, 2H), 5.30-5.53 (m, 3H), 6.96-7.59 (m, 15H), 7.92-8.50 (m, 15H), 8.75 (d, 1H), 8.99- 9.07 (m, 2H), 9.46 (s, 1H). Abs. (λₚₑₐₖ, ε) Abs. 1 (579 nm, 45600M⁻¹cm⁻¹) Abs. 2 (376 nm, 40400M⁻¹cm⁻¹) |
| A-6 | 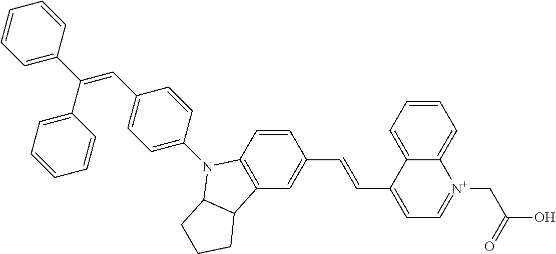 [SMILES: O=C(O)C[n+]1ccc(/C=C/c2ccc3c(c2)C2CCCC2N3c2ccc(C=C(c3ccccc3)c3ccccc3)cc2)c2ccccc21] 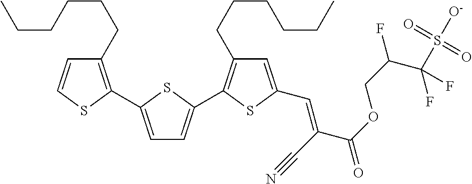 [SMILES: CCCCCCc1ccsc1-c1ccc(-c2sc(/C=C(\C#N)C(=O)OCC(F)C(F)(F)S(=O)(=O)[O-])cc2CCCCCC)s1] | ¹H-NMR spectrum (DMSO-d₆). δ [ppm]: 0.78-2.12 (m, 28H), 2.70-2.83 (m, 4H), 4.84 (t, 1H), 4.42-4.56 (m, 1H), 4.78-5.00 (m, 2H), 5.13-5.32 (m, 1H), 5.68 (s, 2H), 6.95- 8.52 (m, 30H), 9.02- 9.08 (m, 2H). Abs. (λₚₑₐₖ, ε) Abs. 1 (583 nm, 34400M⁻¹cm⁻¹) Abs. 2 (377 nm, 29000M⁻¹cm⁻¹) |
| A-7 | 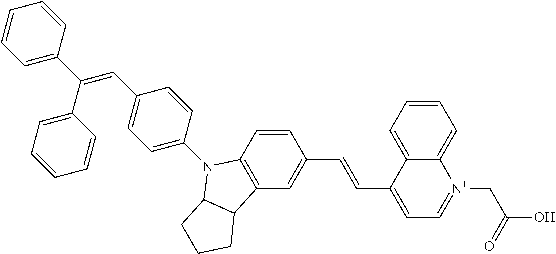 [SMILES: O=C(O)C[n+]1ccc(/C=C/c2ccc3c(c2)C2CCCC2N3c2ccc(C=C(c3ccccc3)c3ccccc3)cc2)c2ccccc21] 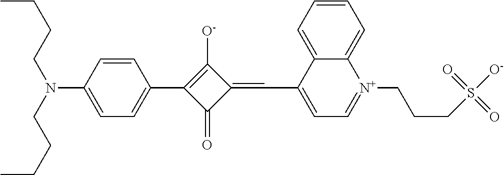 [SMILES: CCCCN(CCCC)c1ccc(C2=C([O-])C(=Cc3cc[n+](CCCS(=O)(=O)[O-])c4ccccc34)C2=O)cc1] | ¹H-NMR spectrum (DMSO-d₆). δ [ppm]: 0.90 (t, 6H), 1.20-2.20 (m, 16H), 3.85 (t, 1H), 4.79 (t, 2H), 4.97 (t, 1H), 5.78 (s, 1H), 6.66-6.72 (m, 3H), 6.94-8.23 (m, 25H), 8.33 (d, 1H), 8.39 (d, 1H), 8.57 (d, 1H), 8.73 (d, 1H), 9.03-9.08 (m, 2H), 9.27 (d, 1H), 4H hidden by H₂O signal around 3.3. Abs. (λₚₑₐₖ, ε) Abs. 1 (583 nm, 64300M⁻¹cm⁻¹) Abs. 2 (370 nm, 35300M⁻¹cm⁻¹) Abs. 3 (648 nm, 74200M⁻¹cm⁻¹) |
| A-8 | 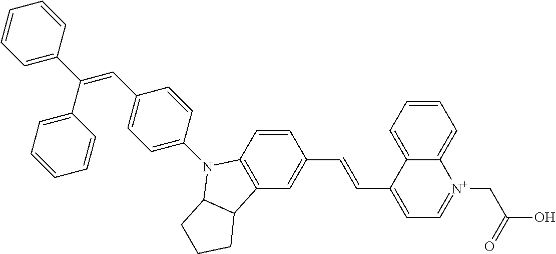 [SMILES: O=C(O)C[n+]1ccc(/C=C/c2ccc3c(c2)C2CCCC2N3c2ccc(C=C(c3ccccc3)c3ccccc3)cc2)c2ccccc21] 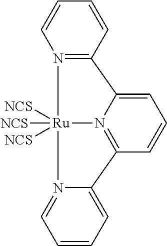 | ¹H-NMR spectrum (DMSO-d₆). δ [ppm]: 1.25-2.10 (m, 6H), 3.85 (t, 1H), 4.96 (t, 1H) 5.68 (s, 2H), 6.95-8.60 (m, 33H), 8.83 (d, 2H), 9.02- 9.08 (m, 2H). Abs. (λₚₑₐₖ, ε) in DCM Abs. 1 (638 nm, 50800M⁻¹cm⁻¹) Abs. 2 (380 nm, 26700M⁻¹cm⁻¹) Abs. 3 (316 nm, 34400M⁻¹cm⁻¹) |
| A-9 | 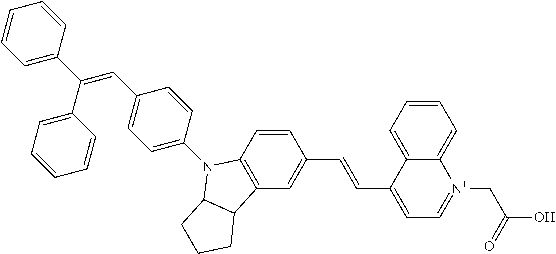 [SMILES: O=C(O)C[n+]1ccc(/C=C/c2ccc3c(c2)C2CCCC2N3c2ccc(C=C(c3ccccc3)c3ccccc3)cc2)c2ccccc21] 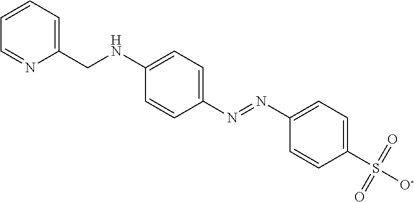 [SMILES: O=S(=O)([O-])c1ccc(/N=N/c2ccc(NCc3ccccn3)cc2)cc1] | ¹H-NMR spectrum (DMSO-d₆). δ [ppm]: 1.28-2.12 (m, 6H), 3.85 (t, 1H), 4.57 (s, 2H), 4.97 (t, 1H), 5.78 (s, 2H), 6.73 (d, 2H), 6.96-8.25 (m, 33H), 8.38 (d, 1H), 9.60 (d, 1H), 9.03- 9.08 (m, 2H). Abs. (λₚₑₐₖ, ε) Abs. 1 (583 nm, 38500M⁻¹cm⁻¹) Abs. 2 (374 nm, 29700M⁻¹cm⁻¹) |
| A-10 | 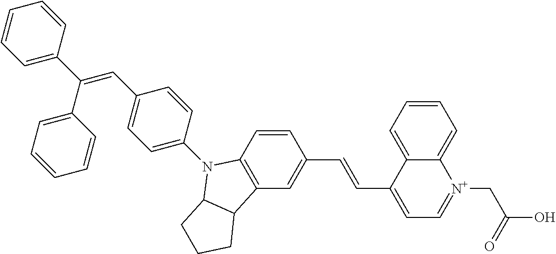 [SMILES: O=C(O)C[n+]1ccc(/C=C/c2ccc3c(c2)C2CCCC2N3c2ccc(C=C(c3ccccc3)c3ccccc3)cc2)c2ccccc21] 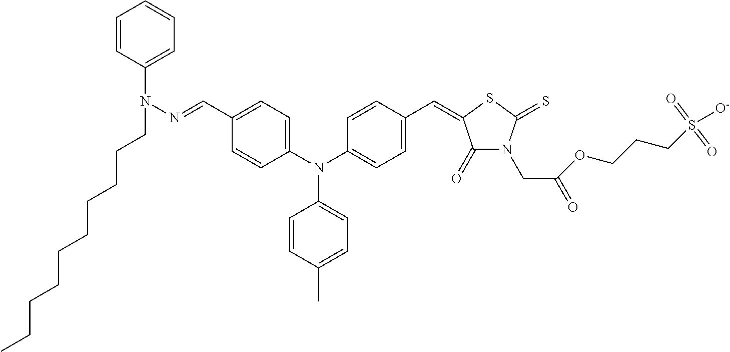 [SMILES: CCCCCCCCCCN(/N=C/c1ccc(N(c2ccc(C)cc2)c2ccc(/C=C3/SC(=S)N(CC(=O)OCCCS(=O)(=O)[O-])C3=O)cc2)cc1)c1ccccc1] | ¹H-NMR spectrum (DMSO-d₆). δ [ppm]: 0.78-0.88 (m, 3H), 1.17-2.45 (m, 29H), 3.83 (t, 1H), 3.95-4.07 (m, 2H), 4.17 (t, 2H), 4.80 (s, 2H), 4.97 (t, 1H), 5.77 (s, 2H), 6.90-8.24 (m, 42H), 8.37 (d, 1H), 9.02-9.06 (m, 2H). Abs. (λₚₑₐₖ, ε) Abs. 1 (533 nm, 52200M⁻¹cm⁻¹) Abs. 2 (372 nm, 53300M⁻¹cm⁻¹) Abs. 3 (504 nm, 59300M⁻¹cm⁻¹) |
| A-11 | 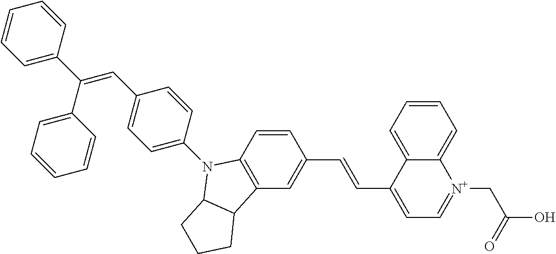 [SMILES: O=C(O)C[n+]1ccc(/C=C/c2ccc3c(c2)C2CCCC2N3c2ccc(C=C(c3ccccc3)c3ccccc3)cc2)c2ccccc21] 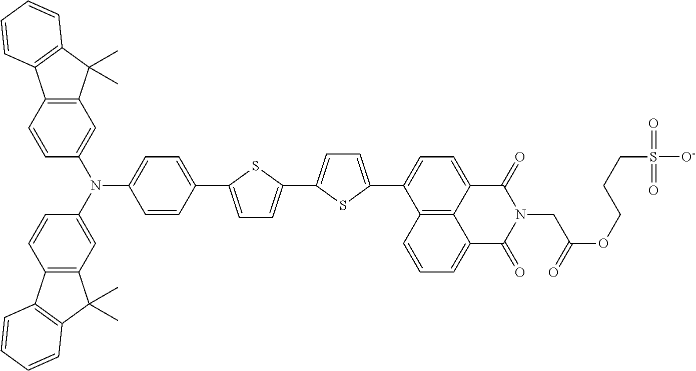 [SMILES: CC1(C)c2ccccc2-c2ccc(N(c3ccc(-c4ccc(-c5ccc(-c6ccc7c8c(cccc68)C(=O)N(CC(=O)OCCCS(=O)(=O)[O-])C7=O)s5)s4)cc3)c3ccc4c(c3)C(C)(C)c3ccccc3-4)cc21] | ¹H-NMR spectrum (DMSO-d₆). δ [ppm]: 1.23-2.10 (m, 20H), 2.40-2.47 (m, 2H), 3.84 (t, 1H), 4.17 (t, 2H), 4.83 (s, 2H), 4.96 (t, 1H), 5.77 (s, 2H), 6.94-8.23 (m, 47H), 8.38 (d, 1H), 8.55 (d, 1H), 8.62 (d, 1H), 8.78 (d, 1H), 9.03-9.08 (m, 2H). Abs. (λₚₑₐₖ, ε) Abs. 1 (584 nm, 51500M⁻¹cm⁻¹) Abs. 2 (371 nm, 91400M⁻¹cm⁻¹) |
| A-12 | 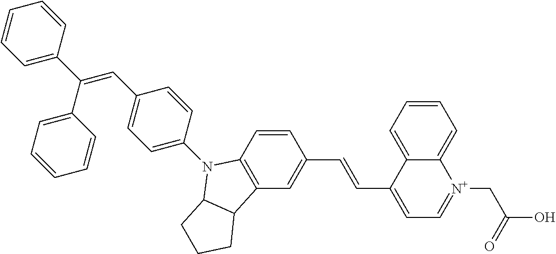 [SMILES: O=C(O)C[n+]1ccc(/C=C/c2ccc3c(c2)C2CCCC2N3c2ccc(C=C(c3ccccc3)c3ccccc3)cc2)c2ccccc21] 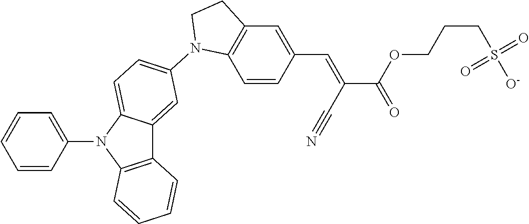 [SMILES: N#C/C(=C\c1ccc2c(c1)CCN2c1ccc2c(c1)c1ccccc1n2-c1ccccc1)C(=O)OCCCS(=O)(=O)[O-]] | ¹H-NMR spectrum (DMSO-d₆). δ [ppm]: 1.23-2.10 (m, 8H), 2.45-2.55 (m, 2H), 3.84 (t, 1H), 4.23-4.31 (m, 2H), 4.96 (t, 1H), 5.78 (s, 2H), 6.93-8.30 (m, 39H), 8.38 (d, 1H), 9.03-9.08 (m, 2H), 2H hidden by H₂O signal around 3.3. Abs. (λₚₑₐₖ, ε) Abs. 1 (583 nm, 42800M⁻¹cm⁻¹) Abs. 2 (376 nm, 39800M⁻¹cm⁻¹) Abs. 3 (451 nm, 43800M⁻¹cm⁻¹) |
| A-13 | 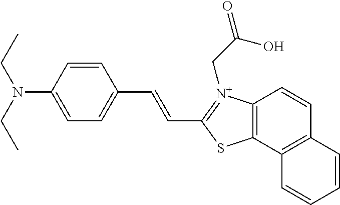 [SMILES: CCN(CC)c1ccc(/C=C/c2sc3c4ccccc4ccc3[n+]2CC(=O)O)cc1] 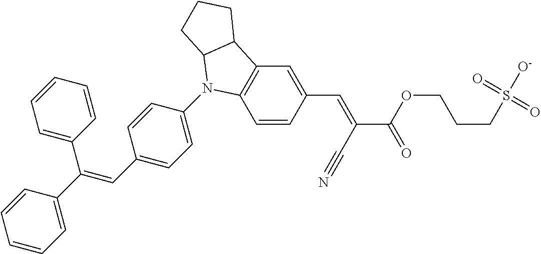 [SMILES: N#C/C(=C\c1ccc2c(c1)C1CCCC1N2c1ccc(C=C(c2ccccc2)c2ccccc2)cc1)C(=O)OCCCS(=O)(=O)[O-]] | ¹H-NMR spectrum (DMSO-d₆). δ [ppm]: 1.13 (t, 6H), 1.23-2.05 (m, 8H), 2.45-2.55 (m, 2H), 3.81 (t, 1H), 4.25 (t, 2H), 4.99 (t, 1H), 5.75 (brs 2H), 6.80 (d, 2H), 6.88 (d, 1H), 7.02- 8.62 (m, 27H). Abs. (λₚₑₐₖ, ε) Abs. 1 (528 nm, 54300M⁻¹cm⁻¹) Abs. 2 (463 nm, 83700M⁻¹cm⁻¹) |
| A-14 Ref-1 (A-1- 3) | 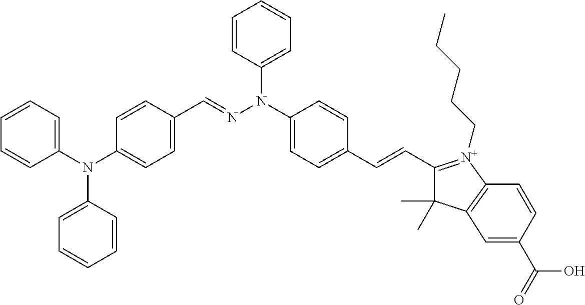 [SMILES: CCCCC[N+]1=C(/C=C/c2ccc(N(/N=C/c3ccc(N(c4ccccc4)c4ccccc4)cc3)c3ccccc3)cc2)C(C)(C)c2cc(C(=O)O)ccc21] 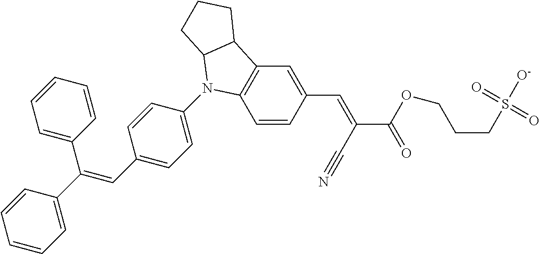 [SMILES: N#C/C(=C\c1ccc2c(c1)C1CCCC1N2c1ccc(C=C(c2ccccc2)c2ccccc2)cc1)C(=O)OCCCS(=O)(=O)[O-]] | ¹H-NMR spectrum (DMSO-d₆). δ [ppm]: 0.91 (t, 3H), 1.20-2.07 (m, 20H), 2.45-2.55 (m, 2H), 3.84 (t, 1H), 4.30 (t, 2H), 4.57 (t, 2H), 5.03 (t, 1H), 6.90-8.53 (m, 48H). Abs. (λₚₑₐₖ, ε) Abs. 1 (583 nm, 51900M⁻¹cm⁻¹) Abs. 2 (372 nm, 29600M⁻¹cm⁻¹) |

### EXAMPLE D-1

### Preparation of DSC Device

FTO (tin oxide doped with fluorine) glass substrates (<12 ohms/sq, A11DU80, supplied by AGC Fabritech Co., Ltd.) were used as the base material, which were successively treated with glass cleaner, Semico Clean (Furuuchi Chemical Corporation), fully deionized water and acetone, in each case for 5 min in an ultrasonic bath, then baked for 10 minutes in isopropanol and dried in a nitrogen flow.

A spray pyrolysis method was used to produce the solid TiO₂ buffer layer. Titanium oxide paste (PST-18NR, supplied by Catalysts&Chemicals Ind. Co., Ltd.) was applied onto the FTO glass substrate by screen printing method. After being dried for 5 minutes at 120° C., a working electrode layer having a thickness of 1.6 μm (micrometer) was obtained by applying heat treatment in air at 450° C. for 30 minutes and 500° C. for 30 minutes. Obtained working electrode is then treated with TiCl₄, as described by M. Grätzel et al., for example, in Grätzel M. et al., Adv. Mater. 2006, 18, 1202. After sintering the sample was cooled to 60 to 80° C. The sample was then treated with additive (B-1) shown below (EP10167649.2). 5 mM of (B-1) in ethanol was prepared and the intermediate was immersed for 20 minutes, washed in a bath of pure ethanol, briefly dried in a nitrogen stream and subsequently immersed in a 0.5 mM solution of dye (A-1) in a mixture solvent of acetonitrile+t-butyl alcohol (1:1) for 1 hour so as to adsorb the dye. After removal from the solution, the specimen was subsequently washed in acetnitrile and dried in a nitrogen flow.

A p-type semiconductor solution was spin-coated on next. To this end a 0.165M spiro-MeOTAD and 10 mM LiN(SO₂CF₃)₂ (Wako Pure Chemical Industries, Ltd.) solution in chlorobenzene was employed. 20 μl/cm² of this solution was applied onto the specimen and allowed to act for 60 s. The supernatant solution was then spun off for 30 s at 2000 revolutions per minute. The substrate was stored overnight under ambient conditions. Thus, the HTM was oxidized and for this reason the conductivity increased.

As the metal back electrode, Ag was evaporated by thermal metal evaporation in a vacuum at a rate of 0.5 nm/s in a pressure of 1×10⁻⁵ mbar, so that an approximately 100 nm thick Ag layer was obtained.

In order to determine the photo-electric power conversion efficiency η (“eta”) of the above photoelectric conversion device, the respective current/voltage characteristic such as short-circuit current density J_{sc}, open-circuit voltage V_{oc} and fill factor F.F. was obtained with a Source Meter Model 2400 (Keithley Instruments Inc.) under the illumination of an artificial sunlight (AM 1.5, 100 mW/cm² intensity) generated by a solar simulator (Peccell Technologies, Inc).

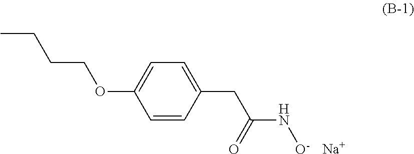 [SMILES: CCCCOc1ccc(CC(=O)N[O-])cc1 ; [Na+]]

### EXAMPLES D-2 TO D-8

DSC device was prepared and evaluated in the same manner as described in the example D-1 except that the compound (A-1) was replaced with a compound (A-2)-(A-6), (A-10) and (A-12).

### COMPARATIVE EXAMPLE D-9

DSC device was prepared and evaluated in the same manner as described in the example D-1 except that the compound (A-1) was replaced with a compound (Ref-1). Compound (Ref-1) is not according to the invention and serves as comparison compound. Compound (Ref-1) only differs in the counter anion from compounds according to the invention.

TABLE 2
Solid DSC performance

| | | IPCE at | Jsc | Voc | F. F. | η (“eta”) |
|---|---|---|---|---|---|---|
| Example | Compound | 450 nm [%] | [mA/cm²] | [mV] | [%] | [%] |
| D-1 | A-1 | 73.6 | 15.1 | 704 | 43 | 4.5 |
| D-2 | A-2 | 43.3 | 11.3 | 731 | 57 | 4.8 |
| D-3 | A-3 | 46.9 | 11.6 | 627 | 57 | 4.2 |
| D-4 | A-4 | 59.4 | 14.5 | 715 | 51 | 5.3 |
| D-5 | A-5 | 55.0 | 14.1 | 678 | 50 | 4.8 |
| D-6 | A-6 | 67.0 | 14.0 | 703 | 53 | 5.2 |
| D-7 | A-10 | 53.6 | 13.9 | 688 | 40 | 3.9 |
| D-8 | A-12 | 67.8 | 14.0 | 703 | 44 | 4.3 |
| D-9 | Ref-1 | 24.6 | 11.9 | 663 | 47 | 3.7 |
| | (A-1-3) | | | | | |

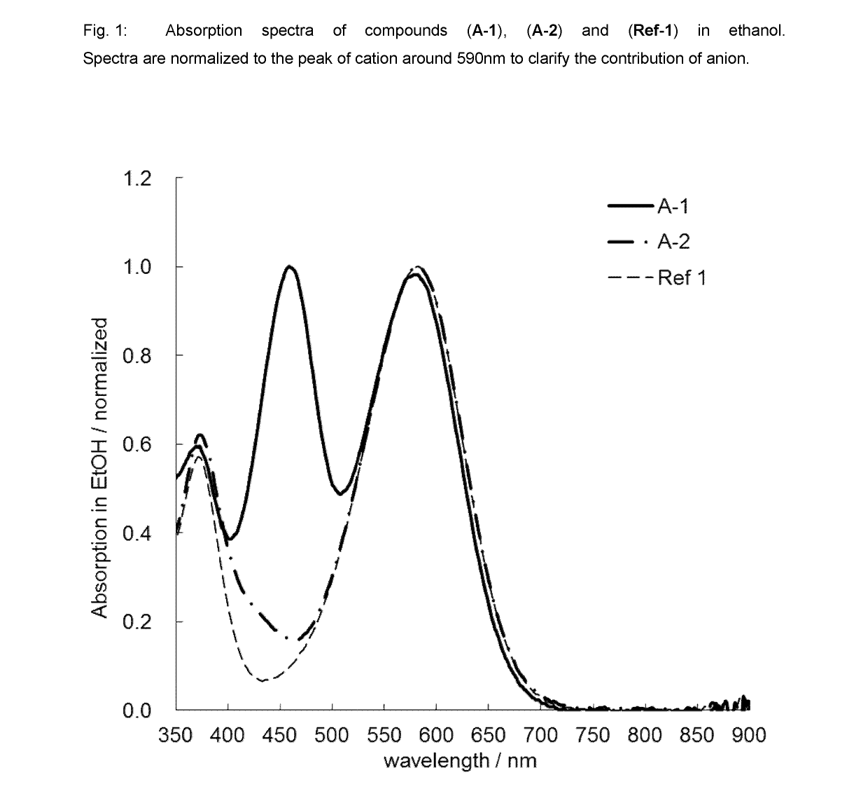

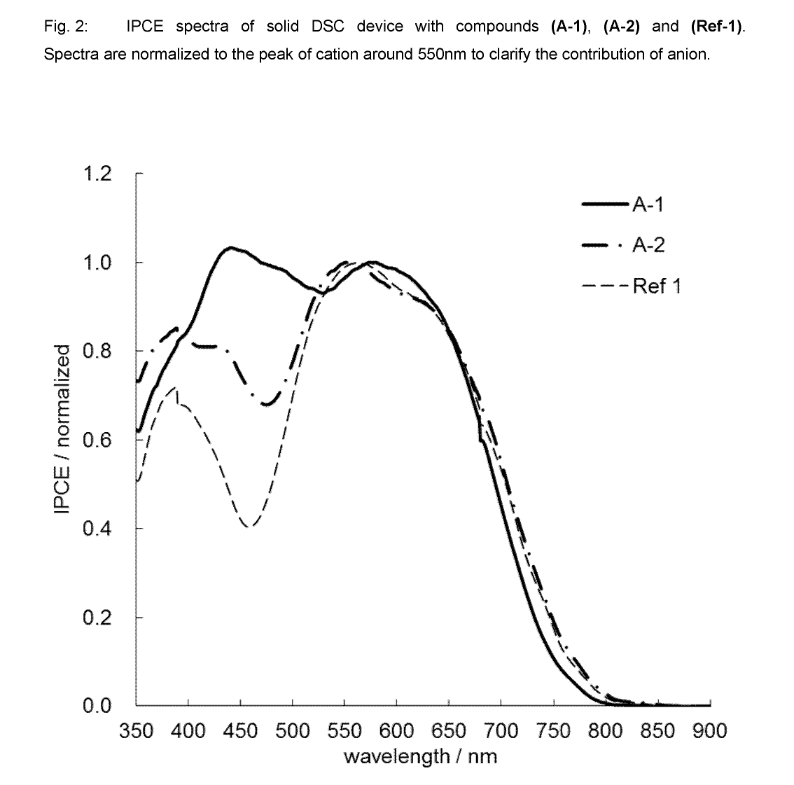

As can be seen from Table 2, FIG. 1 and FIG. 2, compounds of the present invention show a photon to current conversion that can be attributed to the absorption of the respective anion. As a result, the valley of absorption and IPCE around 450 nm is effectively covered and higher conversion efficiency is obtained.

1.-15. (canceled)

16. An electrode layer comprising a porous film made of oxide semiconductor fine particles sensitized with a dye of formula (I), 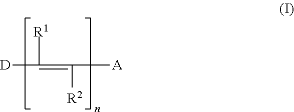
where
n is 1, 2, 3, 4, 5 or 6;
R¹ and R² are independently of each other selected from hydrogen, unsubstituted C₁-C₂₀-alkyl wherein alkyl is uninterrupted or interrupted by O, S, CO, NR¹⁴ or combinations thereof, substituted C₁-C₂₀-alkyl wherein alkyl is uninterrupted or interrupted by O, S, CO, NR¹⁴ or combinations thereof, unsubstituted C₁-C₂₀-cycloalkyl wherein alkyl is uninterrupted or interrupted by O, S, CO, NR¹⁴ or combinations thereof, substituted C₁-C₂₀-cycloalkyl wherein alkyl is uninterrupted or interrupted by O, S, CO, NR¹⁴ or combinations thereof, unsubstituted C₆-C₂₀-aryl, substituted C₆-C₂₀-aryl, unsubstituted C₆-C₂₀-heteroaryl, substituted C₆-C₂₀-heteroaryl; or
R¹ can additionally be a residue of formula D;
each D is independently selected from the group consisting of residues of formulae D.1 and D.2 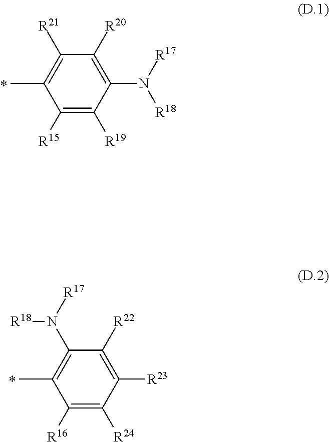
where
* [symbol] denotes the bond to the remaining compound of formula (I);
R¹⁷ and R¹⁸ are independently of each other selected from unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof, where R¹⁴ is hydrogen, C₁-C₂₀-alkyl or C₆-C₁₀-aryl;
or
R¹⁷ and R¹⁸ form together with the nitrogen atom to which they are attached an unsubstituted or substituted 5-, 6- or 7-membered ring;
or
R¹⁷ and R²⁰ form together with the nitrogen atom to which R¹⁷ is attached and the carbon atoms of the benzene ring to which R²⁰ and N—R¹⁷ are attached an unsubstituted or substituted 5-, 6- or 7-membered ring;
or
R¹⁷ and R²² form together with the nitrogen atom to which R¹⁷ is attached and the carbon atoms of the benzene ring to which R²² and N—R¹⁷ are attached an unsubstituted or substituted 5-, 6- or 7-membered ring;
and/or
R¹⁸ and R¹⁹ form with the nitrogen atom to which R¹⁸ is attached and the carbon atoms of the benzene ring to which R¹⁹ and N—R¹⁸ are attached an unsubstituted or substituted 5-, 6- or 7-membered ring;
R¹⁵, R¹⁶, R¹⁹, R²⁰, R²¹, R²², R²³ and R²⁴ are independently of each other selected from the group consisting of hydrogen, NR²⁵R²⁶, OR²⁵, SR²⁵, NR²⁵—NR²⁶R²⁷, NR²⁵—OR²⁶, O—CO—R²⁵, O—CO—OR²⁵, O—CO—NR²⁵R²⁶, NR²⁵—CO—R²⁶, NR²⁵—CO—OR²⁶, NR²⁵—CO—NR²⁶R²⁷, CO—R²⁵, CO—OR²⁵, CO—NR²⁵R²⁶, S—CO—R²⁵, CO—SR²⁵, CO—NR²⁵—NR²⁶R²⁷, CO—NR²⁵—OR²⁶, CO—O—CO—R²⁵, CO—O—CO—OR²⁵, CO—O—CO—NR²⁵R²⁶, CO—NR²⁵—CO—R²⁶, CO—NR²⁵—CO—OR²⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl,
wherein alkyl, alkenyl, alkynyl or the aliphatic moieties in aralkyl, aralkenyl or aralkynyl are uninterrupted or interrupted by O, S, CO, NR¹⁴ or combinations thereof;
R²⁵, R²⁶ and R²⁷ are independently of each other selected from hydrogen, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl,
wherein alkyl, alkenyl, alkynyl or the aliphatic moieties in aralkyl, aralkenyl or aralkynyl are uninterrupted or interrupted by O, S, CO, NR¹⁴ or combinations thereof;
A is a residue of formulae A.1, A.2, A.3, A.4, A.5, A.6 or A.7 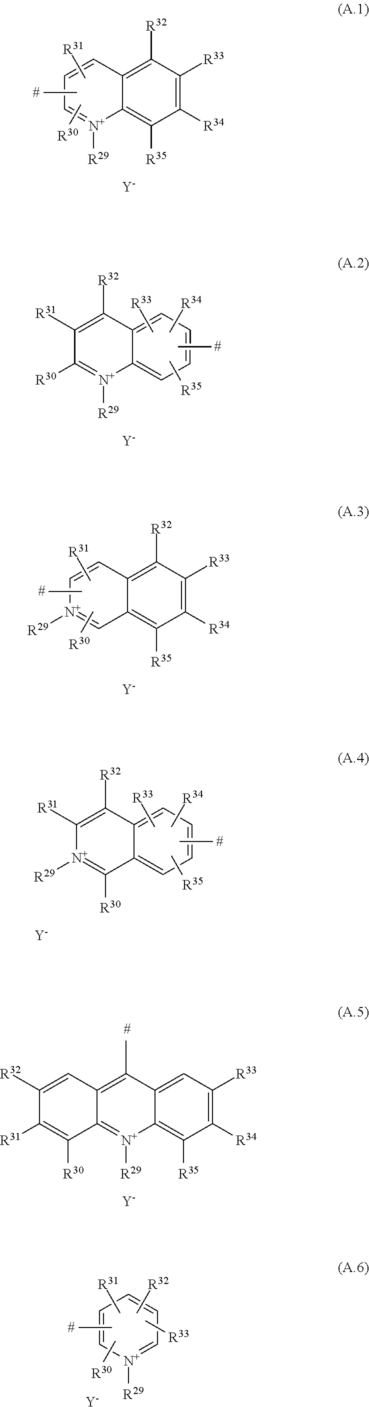 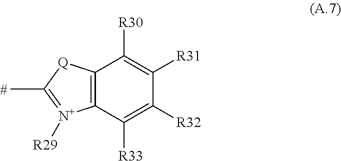
where
# [symbol] denotes the bond to the remaining compound of formula I
R²⁹ is a residue G, hydrogen, halogen, OR³⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R³⁰, R³¹, R³² and R³³ are independently of each other selected from a residue G, hydrogen, halogen, OR³⁶, NO₂, CN, COR′, COOR′, SO₂R′ and SO₃R′, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R′ is independently selected from the group consisting of unsubstituted aryl, substituted aryl, unsubstituted alkyl having 1 to 10 carbon atoms, substituted alkyl having 1 to 10 carbon atoms including substituents, unsubstituted cycloalkyl having 5 to 7 carbon atoms, and substituted cycloalkyl having 5 to 10 carbon atoms including substituents, wherein in said alkyl or cycloalkyl groups one oxygen atom or two nonadjacent oxygen atoms may be inserted between respective C atoms;
wherein optionally in (A.7) R³⁰ and R³¹ together with the carbon atoms to which they are attached or R³² and R³³ together with the carbon atoms to which they are attached form an unsubstituted or substituted 5-, 6- or 7-membered ring;
with the proviso that at least one of the residues R²⁹, R³⁰, R³¹, R³², R³³, R³⁴ and R³⁵ is a residue G,
where
R³⁶ is unsubstituted or substituted C₁-C₂₀-alkyl, unsubstituted or substituted C₆-C₂₀-aryl, unsubstituted or substituted heteroaryl, wherein alkyl is uninterrupted or interrupted by O, S, CO, NR¹⁴ or combination thereof;
Q is —S—, —C(R³⁴)(R³⁵)—, —O—;
R³⁴ and R³⁵ are independently of each other selected from a residue G, hydrogen, halogen, OR³⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₉₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
G is selected from —R²⁸—COOH, —R²⁸—COO⁻Z⁺, —R²⁸—CO(C═O)OH, —R²⁸—CO(C═O)O⁻Z⁺, —R²⁸—S(═O)₂OH, —R²⁸—S(═O)₂O⁻Z⁺, —R²—O—S(═O)₂OH, —R²⁸—O—S(═O)₂O⁻Z⁺, —R²⁸—P(═O)(OH)₂, —R²⁸—P(═O)(O⁻Z⁺)₂, —R²⁸—P(═O)(OH)(O⁻Z⁺), —R²⁸—O—P(═O)(OH)₂, —R²⁸—O—P(═O)(O⁻Z⁺)₂, —R²⁸—O—P(═O)(OH)(O⁻Z⁺), —R²⁸—CO—NH—OH, —R²⁸—S(═O)₂NH—OH, —R²⁸—NR¹⁴—S(═O)₂OH and —R²⁸—NR¹⁴—S(═O)₂O⁻Z⁺;
where
R²⁸ is a direct bond, C₁-C₂₀-alkylene, C₂-C₄-alkenylene or C₆-C₁₀-arylene;
Z⁺ is an organic or inorganic cation equivalent; and
Y⁻ is an anion capable of absorbing electromagnetic radiation having a wavelength in the range of from 400 nm to 1000 nm.

17. The electrode layer according to claim 16, wherein in formula (I)
Y⁻ is an anion providing a conjugated π-electron system.

18. The electrode layer according to claim 16, wherein in formula (I)
Y⁻ is a metal complex anion.

19. The electrode layer according to claim 16, wherein in formula (I)
Y⁻ is an anion comprising a moiety selected from the group consisting of —SO₃⁻, —COO⁻, —O—S(═O)₂O⁻, —P(═O)(OH)(O⁻), —P(═O)(OH)(O⁻) and —SCN⁻.

20. The electrode layer according to claim 16, wherein in formula (I)
Y⁻ is an anion of formula (II) 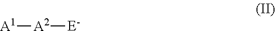
wherein
A¹ is a group providing a conjugated π-electron system;
A² is an unsubstituted alkyl chain having 1 to 24 carbon atoms or a substituted alkyl chain having 1 to 24 carbon atoms including substituents, wherein in said alkyl or substituted alkyl chain optionally one or more functional groups are located between respective C atoms;
E⁻ is a moiety selected from the group consisting of —SO₃⁻, —COO⁻, —P(═O)(OH)(O⁻) and —P(═O)(OH)(O⁻).

21. The electrode layer according to claim 16 wherein in formula (I)
Y⁻ is an anion of formula (III) 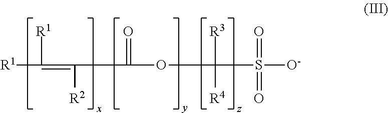
wherein
x, y are independently of each other selected from the group consisting of 0 and 1;
z is independently selected from the group consisting of 0, 1, 2, 3, 4, 5, 6, 7, 8 and 9;
R1 is defined as in claim 16 with the proviso that at least one of R1 is selected from the group consisting of unsubstituted C₁-C₂₀-alkyl wherein alkyl is uninterrupted or interrupted by O, S, CO, NR¹⁴ or combinations thereof, substituted C₁-C₂₀-alkyl wherein alkyl is uninterrupted or interrupted by O, S, CO, NR¹⁴ or combinations thereof, unsubstituted C₁-C₂₀-cycloalkyl wherein alkyl is uninterrupted or interrupted by O, S, CO, NR¹⁴ or combinations thereof, substituted C₁-C₂₀-cycloalkyl wherein alkyl is uninterrupted or interrupted by O, S, CO, NR¹⁴ or combinations thereof, unsubstituted C₆-C₂₀-aryl, substituted C₆-C₂₀-aryl, unsubstituted C₆-C₂₀-heteroaryl, substituted C₆-C₂₀-heteroaryl;
R² is independently of each other selected from the group consisting of H, NO₂, CN, COR′, COOR′, SO₂R′ and SO₃R′;
wherein each R′ is independently selected from the group consisting of unsubstituted aryl, substituted aryl, unsubstituted alkyl having 1 to 10 carbon atoms, substituted alkyl having 1 to 10 carbon atoms including substituents, unsubstituted cycloalkyl having 5 to 7 carbon atoms, and substituted cycloalkyl having 5 to 10 carbon atoms including substituents, wherein in said alkyl or cycloalkyl groups one oxygen atom or two nonadjacent oxygen atoms may be inserted between respective C atoms;
R³, R⁴ are independently of each other selected from the group consisting of H, F, Cl, Br and I.

22. The electrode layer according to claim 21, wherein in formula (III) one or more of R¹ is annealed with one or more further aromatic rings or connected with one or more further aromatic or heteroaromatic rings through one atom or through a single bond, wherein each of the one or more further aromatic or heteroaromatic rings is independently of each other either unsubstituted or substituted.

23. The electrode layer according to claim 16, wherein the oxide semiconductor fine particles are made of TiO₂, SnO₂, WO₃, ZnO, Nb₂O₅, Fe₂O₃, ZrO₂, MgO, WO₃, ZnO, CdS, ZnS, PbS, Bi₂S₃, CdSe, CdTe or combinations thereof.

24. The electrode layer as claimed in claim 16, wherein the porous film made of oxide semiconductor fine particles is sensitized with a dye of formula (I) and one or more further dyes selected from the group consisting of metal complex dyes and organic dyes.

25. The electrode layer as claimed in claim 16, wherein the dye is adsorbed together with one or more additives selected from the group consisting of adsorbents, steroids, crown ethers, cyclodextrines, calixarenes, polyethyleneoxides, hydroxamic acids, hydroxamic acid salts and combinations thereof.

26. A photoelectric conversion device comprising the electrode layer as defined in claim 16.

27. A dye sensitized solar cell comprising a photoelectric conversion device as defined in claim 26.

28. An organic electronic device, in particular an organic light-emitting diode (OLED) or an organic field-effect transistor (OFET), comprising the photoelectric conversion device of claim 26.

29. A dye in a dye sensitized solar cell comprising a compound of formula (I) 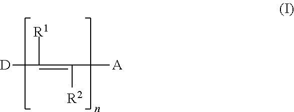
where
n is 1, 2, 3, 4, 5 or 6;
R¹ and R² are independently of each other selected from hydrogen, unsubstituted C₁-C₂₀-alkyl wherein alkyl is uninterrupted or interrupted by O, S, CO, NR¹⁴ or combinations thereof, substituted C₁-C₂₀-alkyl wherein alkyl is uninterrupted or interrupted by O, S, CO, NR¹⁴ or combinations thereof, unsubstituted C₁-C₂₀-cycloalkyl wherein alkyl is uninterrupted or interrupted by O, S, CO, NR¹⁴ or combinations thereof, substituted C₁-C₂₀-cycloalkyl wherein alkyl is uninterrupted or interrupted by O, S, CO, NR¹⁴ or combinations thereof, unsubstituted C₆-C₂₀-aryl, substituted C₆-C₂₀-aryl, unsubstituted C₆-C₂₀-heteroaryl, substituted C₆-C₂₀-heteroaryl; or
R¹ can additionally be a residue of formula D;
each D is independently selected from the group consisting of residues of formulae D.1 and D.2 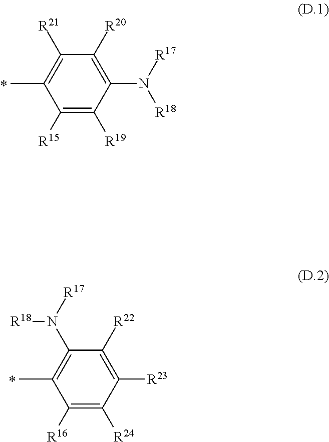
where
* [symbol] denotes the bond to the remaining compound of formula (I);
R¹⁷ and R¹⁸ are independently of each other selected from unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof, where R¹⁴ is hydrogen, C₁-C₂₀-alkyl or C₆-C₁₀-aryl;
or
R¹⁷ and R¹⁸ form together with the nitrogen atom to which they are attached an unsubstituted or substituted 5-, 6- or 7-membered ring;
or
R¹⁷ and R²⁰ form together with the nitrogen atom to which R¹⁷ is attached and the carbon atoms of the benzene ring to which R²⁰ and N—R¹⁷ are attached an unsubstituted or substituted 5-, 6- or 7-membered ring;
or
R¹⁷ and R²² form together with the nitrogen atom to which R¹⁷ is attached and the carbon atoms of the benzene ring to which R²² and N—R¹⁷ are attached an unsubstituted or substituted 5-, 6- or 7-membered ring;
and/or
R¹⁸ and R¹⁹ form with the nitrogen atom to which R¹⁸ is attached and the carbon atoms of the benzene ring to which R¹⁹ and N—R¹⁸ are attached an unsubstituted or substituted 5-, 6- or 7-membered ring;
R¹⁵, R¹⁶, R¹⁹, R²⁰, R²¹, R²², R²³ and R²⁴ are independently of each other selected from the group consisting of hydrogen, NR²⁵R²⁶, OR²⁵, SR²⁵, NR²⁵—NR²⁶R²⁷, NR²⁵—OR²⁶, O—CO—R²⁵, O—CO—OR²⁵, O—CO—NR²⁵R²⁶, NR²⁵—CO—R²⁶, NR²⁵—CO—OR²⁶, NR²⁵—CO—NR²⁶R²⁷, CO—R²⁵, CO—OR²⁵, CO—NR²⁵R²⁶, S—CO—R²⁵, CO—SR²⁵, CO—NR²⁵—NR²⁶R²⁷, CO—NR²⁵—OR²⁶, CO—O—CO—R²⁵, CO—O—CO—OR²⁵, CO—O—CO—NR²⁵R²⁶, CO—NR²⁵—CO—R²⁶, CO—NR²⁵—CO—OR²⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl,
wherein alkyl, alkenyl, alkynyl or the aliphatic moieties in aralkyl, aralkenyl or aralkynyl are uninterrupted or interrupted by O, S, CO, NR¹⁴ or combinations thereof;
R²⁵, R²⁶ and R²⁷ are independently of each other selected from hydrogen, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl,
wherein alkyl, alkenyl, alkynyl or the aliphatic moieties in aralkyl, aralkenyl or aralkynyl are uninterrupted or interrupted by O, S, CO, NR¹⁴ or combinations thereof;
A is a residue of formulae A.1, A.2, A.3, A.4, A.5, A.6 or A.7 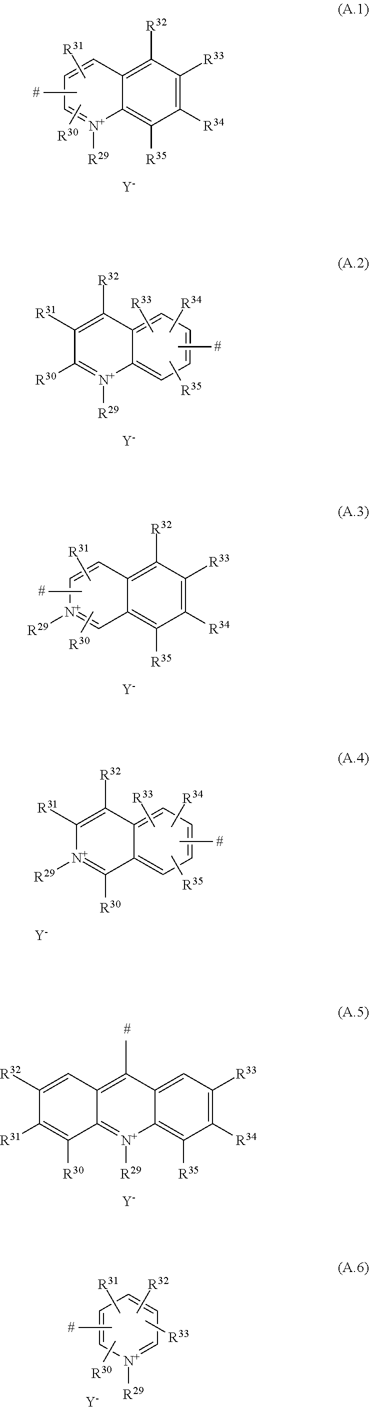 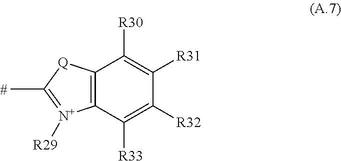
where
# [symbol] denotes the bond to the remaining compound of formula I
R²⁹ is a residue G, hydrogen, halogen, OR³⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R³⁰, R³¹, R³² and R³³ are independently of each other selected from a residue G, hydrogen, halogen, OR³⁶, NO₂, CN, COR′, COOR′, SO₂R′ and SO₃R′, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R′ is independently selected from the group consisting of unsubstituted aryl, substituted aryl, unsubstituted alkyl having 1 to 10 carbon atoms, substituted alkyl having 1 to 10 carbon atoms including substituents, unsubstituted cycloalkyl having 5 to 7 carbon atoms, and substituted cycloalkyl having 5 to 10 carbon atoms including substituents, wherein in said alkyl or cycloalkyl groups one oxygen atom or two nonadjacent oxygen atoms may be inserted between respective C atoms;
wherein optionally in (A.7) R³⁰ and R³¹ together with the carbon atoms to which they are attached or R³² and R³³ together with the carbon atoms to which they are attached form an unsubstituted or substituted 5-, 6- or 7-membered ring;
with the proviso that at least one of the residues R²⁹, R³⁰, R³¹, R³², R³³, R³⁴ and R³⁵ is a residue G,
where
R³⁶ is unsubstituted or substituted C₁-C₂₀-alkyl, unsubstituted or substituted C₆-C₂₀-aryl, unsubstituted or substituted heteroaryl, wherein alkyl is uninterrupted or interrupted by O, S, CO, NR¹⁴ or combination thereof;
Q is —S—, —C(R³⁴)(R³⁵)—, —O—;
R³⁴ and R³⁵ are independently of each other selected from a residue G, hydrogen, halogen, OR³⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
G is selected from —R²⁸—COOH, —R²⁸—COO⁻Z⁺, —R²⁸—CO(C═O)OH, —R²⁸—CO(C═O)O⁻Z⁺, —R²⁸—S(═O)₂OH, —R²⁸—S(═O)₂O⁻Z⁺, —R²—O—S(═O)₂OH, —R²⁸—O—S(═O)₂O⁻Z⁺, —R²⁸—P(═O)(OH)₂, —R²⁸—P(═O)(O⁻Z⁺)₂, —R²⁸—P(═O)(OH)(O⁻Z⁺), —R²⁸—O—P(═O)(OH)₂, —R²⁸—O—P(═O)(O⁻Z⁺)₂, —R²⁸—O—P(═O)(OH)(O⁻Z⁺), —R²⁸—CO—NH—OH, —R²⁸—S(═O)₂NH—OH, —R²⁸—NR¹⁴—S(═O)₂OH and —R²⁸—NR¹⁴—S(═O)₂O⁻Z⁺;
where
R²⁸ is a direct bond, C₁-C₂₀-alkylene, C₂-C₄-alkenylene or C₆-C₁₀-arylene;
Z⁺ is an organic or inorganic cation equivalent; and
Y⁻ is an anion capable of absorbing electromagnetic radiation having a wavelength in the range of from 400 nm to 1000 nm.

30. A compound of formula (I) 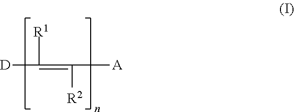
where
n is 1, 2, 3, 4, 5 or 6;
R¹ and R² are independently of each other selected from hydrogen, unsubstituted C₁-C₂₀-alkyl wherein alkyl is uninterrupted or interrupted by O, S, CO, NR¹⁴ or combinations thereof, substituted C₁-C₂₀-alkyl wherein alkyl is uninterrupted or interrupted by O, S, CO, NR¹⁴ or combinations thereof, unsubstituted C₁-C₂₀-cycloalkyl wherein alkyl is uninterrupted or interrupted by O, S, CO, NR¹⁴ or combinations thereof, substituted C₁-C₂₀-cycloalkyl wherein alkyl is uninterrupted or interrupted by O, S, CO, NR¹⁴ or combinations thereof, unsubstituted C₆-C₂₀-aryl, substituted C₆-C₂₀-aryl, unsubstituted C₆-C₂₀-heteroaryl, substituted C₆-C₂₀-heteroaryl; or
R¹ can additionally be a residue of formula D;
each D is independently selected from the group consisting of residues of formulae D.1 and D.2 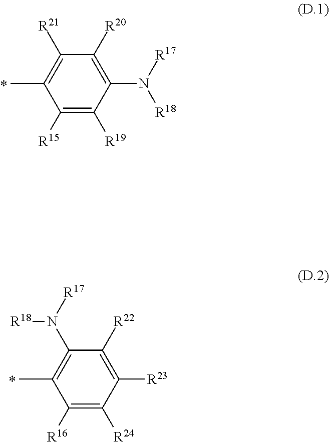
where
* [symbol] denotes the bond to the remaining compound of formula (I);
R¹⁷ and R¹⁸ are independently of each other selected from unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof, where R¹⁴ is hydrogen, C₁-C₂₀-alkyl or C₆-C₁₀-aryl;
or
R¹⁷ and R¹⁸ form together with the nitrogen atom to which they are attached an unsubstituted or substituted 5-, 6- or 7-membered ring;
or
R¹⁷ and R²⁰ form together with the nitrogen atom to which R¹⁷ is attached and the carbon atoms of the benzene ring to which R²⁰ and N—R¹⁷ are attached an unsubstituted or substituted 5-, 6- or 7-membered ring;
or
R¹⁷ and R²² form together with the nitrogen atom to which R¹⁷ is attached and the carbon atoms of the benzene ring to which R²² and N—R¹⁷ are attached an unsubstituted or substituted 5-, 6- or 7-membered ring;
and/or
R¹⁸ and R¹⁹ form with the nitrogen atom to which R¹⁸ is attached and the carbon atoms of the benzene ring to which R¹⁹ and N—R¹⁸ are attached an unsubstituted or substituted 5-, 6- or 7-membered ring;
R¹⁵, R¹⁶, R¹⁹, R²⁰, R²¹, R²², R²³ and R²⁴ are independently of each other selected from the group consisting of hydrogen, NR²⁵R²⁶, OR²⁵, SR²⁵, NR²⁵—NR²⁶R²⁷, NR²⁵—OR²⁶, O—CO—R²⁵, O—CO—OR²⁵, O—CO—NR²⁵R²⁶, NR²⁵—CO—R²⁶, NR²⁵—CO—OR²⁶, NR²⁵—CO—NR²⁶R²⁷, CO—R²⁵, CO—OR²⁵, CO—NR²⁵R²⁶, S—CO—R²⁵, CO—SR²⁵, CO—NR²⁵—NR²⁶R²⁷, CO—NR²⁵—OR²⁶, CO—O—CO—R²⁵, CO—O—CO—OR²⁵, CO—O—CO—NR²⁵R²⁶, CO—NR²⁵—CO—R²⁶, CO—NR^{2′}—CO—OR²⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl,
wherein alkyl, alkenyl, alkynyl or the aliphatic moieties in aralkyl, aralkenyl or aralkynyl are uninterrupted or interrupted by O, S, CO, NR¹⁴ or combinations thereof;
R²⁵, R²⁶ and R²⁷ are independently of each other selected from hydrogen, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₄-C₂₀-cycloalkyl, unsubstituted or substituted C₅-C₂₀-cycloalkenyl and unsubstituted or substituted C₆-C₂₀-cycloalkynyl,
wherein alkyl, alkenyl, alkynyl or the aliphatic moieties in aralkyl, aralkenyl or aralkynyl are uninterrupted or interrupted by O, S, CO, NR¹⁴ or combinations thereof;
A is a residue of formulae A.1, A.2, A.3, A.4, A.5, A.6 or A.7 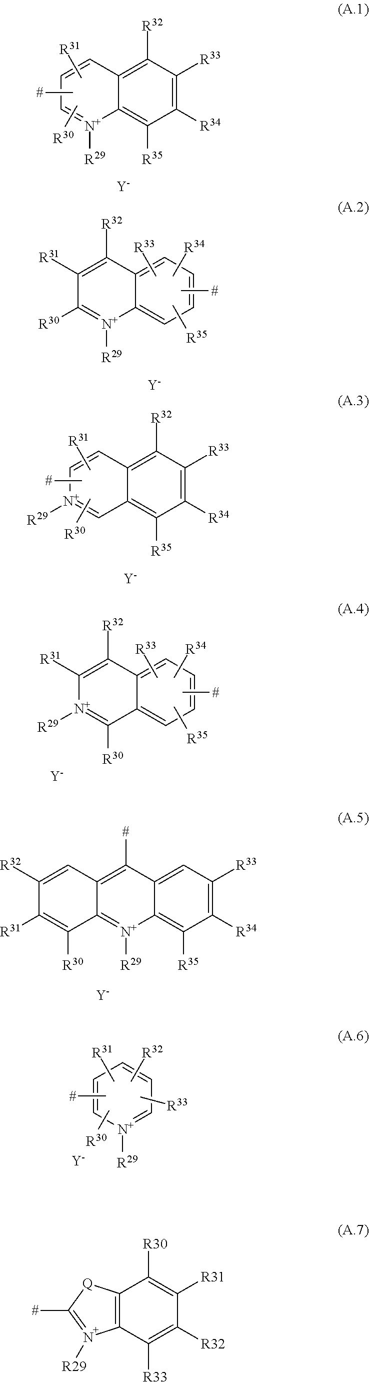
where
# [symbol] denotes the bond to the remaining compound of formula I
R²⁹ is a residue G, hydrogen, halogen, OR³⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R³⁰, R³¹, R³² and R³³ are independently of each other selected from a residue G, hydrogen, halogen, OR³⁶, NO₂, CN, COR′, COOR′, SO₂R′ and SO₃R′, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
R′ is independently selected from the group consisting of unsubstituted aryl, substituted aryl, unsubstituted alkyl having 1 to 10 carbon atoms, substituted alkyl having 1 to 10 carbon atoms including substituents, unsubstituted cycloalkyl having 5 to 7 carbon atoms, and substituted cycloalkyl having 5 to 10 carbon atoms including substituents, wherein in said alkyl or cycloalkyl groups one oxygen atom or two nonadjacent oxygen atoms may be inserted between respective C atoms;
wherein optionally in (A.7) R³⁰ and R³¹ together with the carbon atoms to which they are attached or R³² and R³³ together with the carbon atoms to which they are attached form an unsubstituted or substituted 5-, 6- or 7-membered ring;
with the proviso that at least one of the residues R²⁹, R³⁰, R³¹, R³², R³³, R³⁴ and R³⁵ is a residue G,
where
R³⁶ is unsubstituted or substituted C₁-C₂₀-alkyl, unsubstituted or substituted C₆-C₂₀-aryl, unsubstituted or substituted heteroaryl, wherein alkyl is uninterrupted or interrupted by O, S, CO, NR¹⁴ or combination thereof;
Q is —S—, —C(R³⁴)(R³⁵)—, —O—;
R³⁴ and R³⁵ are independently of each other selected from a residue G, hydrogen, halogen, OR³⁶, unsubstituted or substituted C₁-C₂₀-alkyl, unsubstituted or substituted C₂-C₂₀-alkenyl, unsubstituted or substituted C₂-C₂₀-alkynyl, unsubstituted or substituted C₇-C₂₀-aralkyl, unsubstituted or substituted C₈-C₂₀-aralkenyl, unsubstituted or substituted C₈-C₂₀-aralkynyl, unsubstituted or substituted C₆-C₂₀-aryl, unsubstituted or substituted heteroaryl, unsubstituted or substituted heterocyclyl, unsubstituted or substituted C₅-C₂₀-cycloalkyl, unsubstituted or substituted C₅-C₂₀-cycloalkenyl and unsubstituted or substituted C₆-C₂₀-cycloalkynyl, wherein alkyl, alkenyl, alkynyl or the aliphatic moieties in aralkyl, aralkenyl or aralkynyl are uninterrupted or interrupted by O, S, CO, NR¹⁴ or combinations thereof;
G is selected from —R²⁸—COOH, —R²⁸—COO⁻Z⁺, —R²⁸—CO(C═O)OH, —R²⁸—CO(C═O)O⁻Z⁺, —R²⁸—S(═O)₂OH, —R²⁸—S(═O)₂O⁻Z⁺, —R²—O—S(═O)₂OH, —R²⁸—O—S(═O)₂O⁻Z⁺, —R²⁸—P(═O)(OH)₂, —R²⁸—P(═O)(O⁻Z⁺)₂, —R²⁸—P(═O)(OH)(O⁻Z⁺), —R²⁸—O—P(═O)(OH)₂, —R²⁸—O—P(═O)(O⁻Z⁺)₂, —R²⁸—O—P(═O)(OH)(O⁻Z⁺), —R²⁸—CO—NH—OH, —R²⁸—S(═O)₂NH—OH, —R²⁸—NR¹⁴—S(═O)₂OH and —R²⁸—NR¹⁴—S(═O)₂O⁻Z⁺;
where
R²⁸ is a direct bond, C₁-C₂₀-alkylene, C₂-C₄-alkenylene or C₆-C₁₀-arylene;
Z⁺ is an organic or inorganic cation equivalent; and
Y⁻ is an anion capable of absorbing electromagnetic radiation having a wavelength in the range of from 400 nm to 1000 nm.

31. The electrode layer according to claim 18, wherein
Y⁻ is selected from the group consisting of Ru, Pt, Ir, Rh, Re, Os, Fe, W, Cr, Mo, Ni, Co, Mn, Zn, Cu and combinations thereof.

32. The electrode layer according to claim 18, wherein
Y⁻ is a selected from the group consisting of Ru, Os, Fe and combinations thereof.

33. The electrode layer according to claim 18, wherein
Y⁻ is Ru.

34. The electrode layer as claimed in claim 16, wherein the porous film made of oxide semiconductor fine particles is sensitized with a dye of formula (I) and one or more further dyes selected from the group consisting of indoline, coumarin, cyanine, merocyanine, hemicyanine, methin, azo, quinone, quinonimine, diketo-pyrrolo-pyrrole, quinacridone, squaraine, triphenylmethane, perylene, indigo, xanthene, eosin, rhodamine and combinations thereof.
